(19) United States
(12) Patent Application Publication
(10) Pub. No.: US 2013/0084706 A1
(43) Pub. Date: Apr. 4, 2013

(54) Plasma-Tuning Rods in Surface Wave Antenna (SWA) Sources

(71) Applicants: Jianping Zhao, Austin, TX (US); Lee Chen, Cedar Creek, TX (US); Merritt Funk, Austin, TX (US); Toshihiko Iwao, Tokyo (JP); Peter L.G. Ventzek, Austin, TX (US)

(72) Inventors: Jianping Zhao, Austin, TX (US); Lee Chen, Cedar Creek, TX (US); Merritt Funk, Austin, TX (US); Toshihiko Iwao, Tokyo (JP); Peter L.G. Ventzek, Austin, TX (US)

(73) Assignee: Tokyo Electron Limited, Tokyo (JP)

(21) Appl. No.: 13/249,418

(22) Filed: Sep. 30, 2011

(51) Int. Cl. H01L 21/311; H01L 21/3065

(52) U.S. Cl. 438/710; 156/345.26; 257/E21.252

(57) ABSTRACT

The invention provides a plurality of Surface Wave Antenna (SWA) plasma sources. The SWA plasma sources can comprise one or more non-circular slot antennas, each having a plurality of plasma-tuning rods extending therethrough. Some of the plasma tuning rods can be configured to couple the electromagnetic (EM) energy from one or more of the non-circular slot antennas to the process space within the process chamber. The invention also provides SWA plasma sources that can comprise a plurality of resonant cavities, each having one or more plasma-tuning rods extending therefrom. Some of the plasma tuning rods can be configured to couple the EM energy from one or more of the resonant cavities to the process space within the process chamber.

### CROSS-REFERENCE TO RELATED APPLICATIONS

This application is related to co-pending U.S. patent application Ser. No. 13/______, attorney docket No. TEA-074, entitled “Plasma Tuning Rods in Microwave Resonator Plasma Sources”, filed on even date herewith. This application is related to co-pending U.S. patent application Ser. No. 13/______, attorney docket No. TEA-071, entitled “Plasma Tuning Rods in Microwave Processing Systems”, filed on even date herewith. The contents of each of these applications are herein incorporated by reference in their entireties.

### BACKGROUND OF THE INVENTION

1. Field of the Invention

The present invention relates to substrate/wafer processing, and more particularly to Surface Wave Antenna (SWA) processing systems and methods for processing substrates and/or semiconductor wafers using SWA processing systems.

2. Description of the Related Art

Typically, during semiconductor processing, a (dry) plasma etch process is utilized to remove or etch material along fine lines or within vias or contacts patterned on a semiconductor substrate. The plasma etch process generally involves positioning a semiconductor substrate with an overlying patterned, protective layer, for example a photoresist layer, into a process chamber.

Once the substrate is positioned within the chamber, an ionizable, dissociative gas mixture is introduced within the chamber at a pre-specified flow rate, while a vacuum pump is throttled to achieve an ambient process pressure. Thereafter, a plasma is formed when a portion of the gas species present are ionized following a collision with an energetic electron. Moreover, the heated electrons serve to dissociate some species of the mixture gas species and create reactant specie(s) suitable for the etching exposed surfaces. Once the plasma is formed, any exposed surfaces of the substrate are etched by the plasma. The process is adjusted to achieve optimal conditions, including an appropriate concentration of desirable reactant and ion populations to etch various features (e.g., trenches, vias, contacts, etc.) in the exposed regions of substrate. Such substrate materials where etching is required include silicon dioxide (SiO₂), poly-silicon, and silicon nitride, for example.

Conventionally, various techniques have been implemented for exciting a gas into plasma for the treatment of a substrate during semiconductor device fabrication, as described above. In particular, (“parallel plate”) capacitively coupled plasma (CCP) processing systems, or inductively coupled plasma (ICP) processing systems have been utilized commonly for plasma excitation. Among other types of plasma sources, there are microwave plasma sources (including those utilizing electron-cyclotron resonance (ECR)), surface wave plasma (SWP) sources, and helicon plasma sources.

It is becoming common wisdom that microwave resonator systems offer improved plasma processing performance, particularly for etching processes, over CCP systems, ICP systems, and resonantly heated systems. Microwave resonator systems produce a high degree of ionization at a relatively lower Boltzmann electron temperature (Tₑ). In addition, SWP sources generally produce plasma richer in electronically excited molecular species with reduced molecular dissociation. However, the practical implementation of microwave resonator systems still suffers from several deficiencies including, for example, plasma stability and uniformity.

### SUMMARY OF THE INVENTION

The invention relates to SWA processing systems and, more particularly, to SWA processing systems having at least one plasma-tuning rod for creating large stable and/or uniform plasma systems.

According to embodiments, a plurality of SWA plasma sources are described. In some embodiments, the SWA plasma sources can comprise one or more non-circular slot antennas, each having a plurality of plasma-tuning rods extending therethrough. Some of the plasma tuning rods can be configured to couple the electromagnetic (EM) energy from one or more of the non-circular slot antennas to the process space within the process chamber.

In other embodiments, the SWA plasma sources can comprise a plurality of resonant cavities, each having one or more plasma-tuning rods extending therefrom. Some of the plasma tuning rods can be configured to couple the EM energy from one or more of the resonant cavities to the process space within the process chamber.

In some other embodiments, the SWA plasma sources can comprise one or more non-circular slot antennas, each having a plurality of plasma-tuning rods extending therethrough. Some of the plasma-tuning rods can be configured to couple the EM energy from one or more of the non-circular slot antennas to the process space within the process chamber. In addition, the SWA plasma sources can comprise a plurality of resonant cavities, each having one or more additional plasma-tuning rods extending therefrom. Some of the additional plasma-tuning rods can be configured to couple the EM energy from one or more of the resonant cavities to the process space within the process chamber.

### BRIEF DESCRIPTION OF THE DRAWINGS

Embodiments of the invention will now be described, by way of example only, with reference to the accompanying schematic drawings in which corresponding reference symbols indicate corresponding parts, and in which:

FIGS. 1A-1C illustrate different exemplary views of a first SWA processing system according to embodiments of the invention;

FIGS. 2A-2C illustrate different exemplary views of a second SWA processing system according to embodiments of the invention;

FIGS. 3A-3C illustrate different exemplary views of a third SWA processing system according to embodiments of the invention;

FIG. 4 illustrates an exemplary EM wave launcher according to embodiments of the invention;

FIGS. 5A-5D show different views of exemplary plasma-tuning rods in accordance with embodiments of the invention;

FIGS. 6A-6D show different views of other exemplary plasma-tuning rods in accordance with embodiments of the invention;

FIGS. 7A-7D show different views of exemplary plasma-tuning rods in accordance with embodiments of the invention;

FIG. 8 illustrates a flow diagram for an exemplary operating procedure in accordance with embodiments of the invention; and

FIG. 9 illustrates another SWA processing system according to embodiments of the invention.

### DETAILED DESCRIPTION

SWA plasma sources and SWA processing systems are disclosed in various embodiments. However, one skilled in the relevant art will recognize that the various embodiments may be practiced without one or more of the specific details, or with other replacement and/or additional methods, materials, or components. In other instances, well-known structures, materials, or operations are not shown or described in detail to avoid obscuring aspects of various embodiments of the invention.

Similarly, for purposes of explanation, specific numbers, materials, and configurations are set forth in order to provide a thorough understanding of the invention. Nevertheless, the invention may be practiced without specific details. Furthermore, it is understood that the various embodiments shown in the figures are illustrative representations and are not necessarily drawn to scale.

Reference throughout this specification to “one embodiment” or “an embodiment” or variation thereof means that a particular feature, structure, material, or characteristic described in connection with the embodiment is included in at least one embodiment of the invention, but do not denote that they are present in every embodiment. Thus, the appearances of the phrases such as “in one embodiment” or “in an embodiment” in various places throughout this specification are not necessarily referring to the same embodiment of the invention. Furthermore, the particular features, structures, materials, or characteristics may be combined in any suitable manner in one or more embodiments.

Nonetheless, it should be appreciated that, contained within the description are features, which, notwithstanding the inventive nature of the general concepts being explained, are also of an inventive nature.

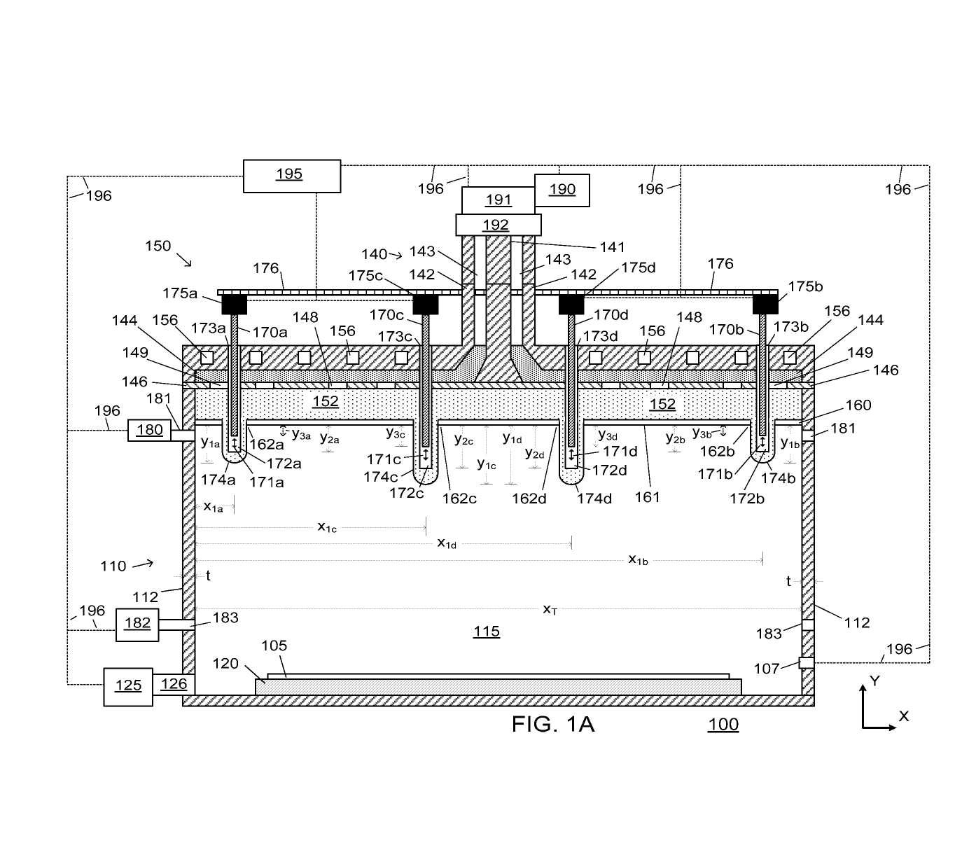

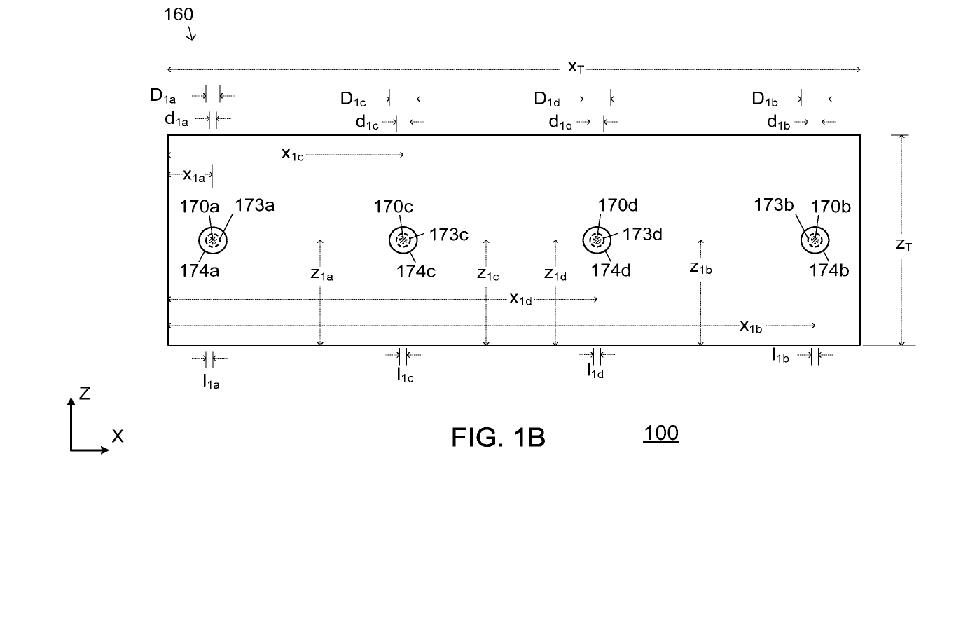

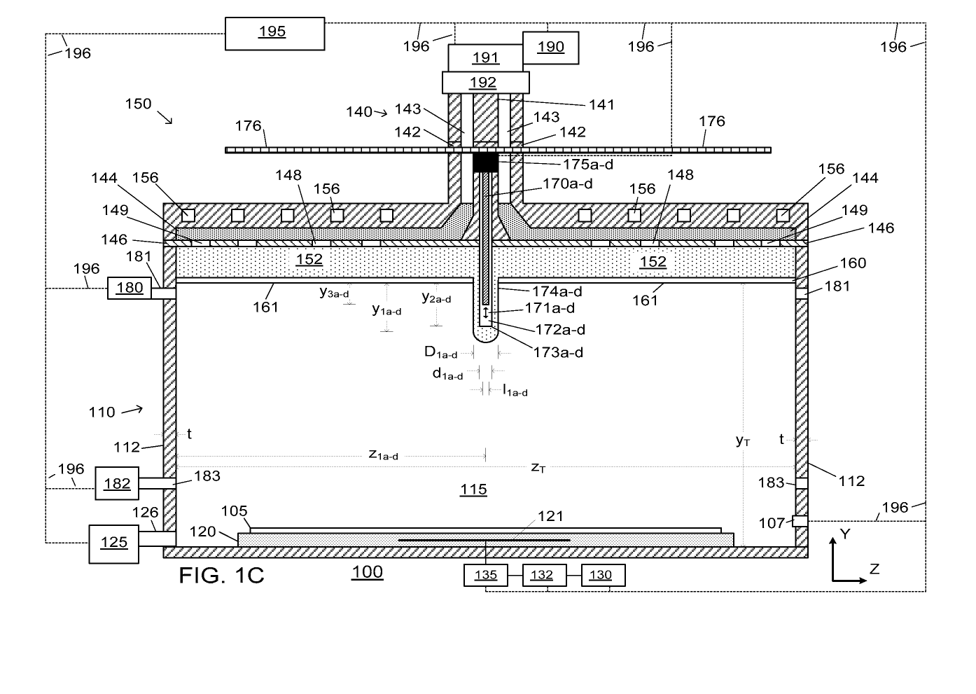

Referring now to the drawings, wherein like reference numerals designate identical or corresponding parts throughout the several views, FIG. 1A illustrates a first SWA processing system 100 according to embodiments of the invention. The first SWA processing system 100 may be used in a dry plasma etching system or a plasma enhanced deposition system, or in general a plasma treatment system.

FIG. 1A illustrates a front view of a first SWA processing system in accordance with embodiments of the invention. The first SWA processing system 100 can comprise a SWA plasma source 150 having a slot antenna 146 therein. Alternatively, the first SWA processing system 100 may be configured differently.

The first SWA processing system 100 can comprise a process chamber 110 configured to define a process space 115. The front view shows an x/y plane view of a process chamber 110 that can be configured using a cover plate 160 and a plurality of chamber walls 112 coupled to each other and the cover plate 160. For example, the chamber walls 112 can have wall thicknesses (t) associated therewith, and the wall thicknesses (t) can vary from about 1 mm (millimeter) to about 5 mm. The cover plate 160 have a first cover plate thickness associated therewith, and the cover plate thickness can vary from about 1 mm to about 10 mm. The cover plate 160 can have a plurality of holes (162a, 162b, 162c, and 162d) associated therewith, and the hole diameters can vary from about 1 mm to about 10 mm.

The process chamber 110 can comprise a substrate holder 120 configured to support a substrate 105. The substrate 105 can be exposed to plasma and/or process chemistry in process space 115. The first SWA processing system 100 can comprise a first SWA plasma source 150 coupled to the plasma chamber 110, and configured to form plasma in the process space 115.

One or more EM sources 190 can be coupled to the first SWA plasma source 150, and the EM energy generated by the one or more EM sources 190 can flow through a match network/phase shifter 191 to a tuner network/isolator 192 for absorbing EM energy reflected back to the EM source 190. The EM energy can be converted to a TEM (transverse electromagnetic) mode via the tuner network/isolator 192. A tuner may be employed for impedance matching, and improved power transfer. The EM source 190, the match network/phase shifter 191, and the tuner network/isolator 192 can operate from about 500 MHz (mega-Hertz) to about 5000 MHz.

The first SWA plasma source 150 can comprise a feed assembly 140 having an inner conductor 141, an outer conductor 142, an insulator 143, and slot antenna 146 having a plurality of first slots 148 and a plurality of second slots 149 coupled between the inner conductor 141 and the outer conductor 142. The plurality of first and second slots (148 and 149) permit the coupling of EM energy from a first region above the slot antenna 146 to a second region below the slot antenna 146.

The design of the slot antenna 146 can be used to control the spatial uniformity of the plasma in process space 115. For example, the number, geometry, size, and distribution of the plurality of first and second slots (148, and 149) are all factors that can contribute to the spatial uniformity of the plasma formed in the process space 115.

Some exemplary first SWA plasma sources 150 can comprise a slow wave plate 144, and the design of the slow wave plate 144 can be used to control the spatial uniformity of the plasma in process space 115. For example, the geometry, size, and plate material can be factors that can contribute to the spatial uniformity of the plasma formed in the process space 115. Alternatively, the slow wave plate 144 may be configured differently or may not be required.

Other exemplary first SWA plasma sources 150 can comprise a resonator plate 152, and the design of the resonator plate 152 can be used to control the spatial uniformity of the plasma in process space 115. For example, the geometry, size, and the resonator plate material can be factors that can contribute to the spatial uniformity of the plasma formed in the process space 115. Alternatively, the resonator plate 152 may be configured differently or may not be required.

Still other exemplary first SWA plasma sources 150 can comprise a cover plate 160, and the design of the cover plate 160 can be used to control the spatial uniformity of the plasma in process space 115. For example, the geometry, size, and the cover plate material can be factors that can contribute to the spatial uniformity of the plasma formed in the process space 115. Alternatively, the cover plate 160 may be configured differently or may not be required.

Other additional exemplary first SWA plasma sources 150 can comprise one or more fluid channels 156 that can be configured to flow a temperature control fluid for temperature control of the first SWA plasma source 150. The design of the one or more fluid channels 156 can be used to control the spatial uniformity of the plasma in process space 115. For example, the geometry, size, and flow rate of the one or more fluid channels 156 can be factors that can contribute to the spatial uniformity of the plasma formed in the process space 115. Alternatively, one or more of the fluid channels 156 may be configured differently or may not be required.

The EM energy can be coupled to the first SWA plasma source 150 via the feed assembly 140, wherein another mode change occurs from the TEM (transverse electro-magnetic) mode in the feed assembly 140 to a TM (transverse magnetic) mode. Additional details regarding the design of the feed assembly 140 and the slot antenna 146 can be found in U.S. Pat. No. 5,024,716, entitled “Plasma processing apparatus for etching, ashing, and film-formation”; the content of which is herein incorporated by reference in its entirety.

The first SWA plasma source 150 can comprise a first protection assembly 174a that can be configured as an extension of the resonator plate 152. For example, the resonator plate 152 and the first protection assembly 174a can comprise a dielectric material, such as quartz. The design of the first protection assembly 174a can be used to control the spatial uniformity of the plasma in process space 115. In addition, the geometry, size, and material of the first protection assembly 174a can be factors that can contribute to the spatial uniformity of the plasma formed in the process space 115. Alternatively, the first protection assembly 174a may be configured differently or may not be required.

A first positioning subsystem 175a can be coupled to a first plasma-tuning rod 170a and can be coupled to at least one mounting structure 176. The first positioning subsystem 175a can be used to create first movements 171a in the first plasma-tuning rod 170a within a first tuning space 172a established in a first tuning assembly 173a. The first tuning space 172a and the first tuning assembly 173a can be configured to extend through the outer conductor 142, the slow wave plate 144, the slot antenna 146, the resonator plate 152, and the cover plate 160 and can extend into the first protection assembly 174a as shown. Alternatively, the first tuning space 172a and the first tuning assembly 173a can be configured differently.

As shown in FIG. 1A, the first plasma-tuning rod 170a can extend through the slow wave plate 144, the slot antenna 146, and the resonator plate 152 and can obtain first tunable EM energy from the slot antenna 146, the slow wave plate 144, and/or the resonator plate 152. The first plasma-tuning rod 170a that can have first movements 171a associated therewith and the first movements 171a can be used to control the tunable EM energy. For example, the first plasma-tuning rod 170a can move in a first (vertical) direction within the first tuning space 172a established in the first tuning assembly 173a. In addition, the first tunable EM energy provided to the process space 115 by the lower portion of the first plasma-tuning rod 170a can include a tunable E-field component, a tunable H-field component, a tunable voltage component, a tunable energy component, or a tunable current component, or any combination thereof.

The first tuning space 172a and the first tuning assembly 173a can be cylindrically shaped, and can have diameters (d₁ₐ) larger than the diameter (l₁ₐ) of the first plasma tuning rod 170a, thereby allowing the first plasma-tuning rod 170a to move freely therein. Alternatively, the number, shape, length, and/or position of first plasma tuning rod 170a may be different.

The first plasma-tuning rod 170a, first tuning space 172a, the first tuning assembly 173a, and the first protection assembly 174a can be aligned at a first x/y plane location (x₁ₐ) in the process space 115, and the first tunable EM energy can be provided by the first plasma-tuning rod 170a at the first x/y plane location (x₁ₐ) in the process space 115. Alternatively, the first plasma-tuning rod 170a, the first tuning space 172a, the first tuning assembly 173a, and the first protection assembly 174a may be configured differently.

The first protection assembly 174a can extend a first insertion length (y₁ₐ) into the process space 115, and the first insertion length (y₁ₐ) can be established relative to a plasma-facing surface 161 of the cover plate 160. The first insertion length (y₁ₐ) can be wavelength-dependent and may vary from about (λ/20) to about (10λ), wherein (λ) is the effective wavelength for propagation of EM energy at a given frequency from at least one of the one or more EM sources 190. Alternatively, the first insertion length (y₁ₐ) may vary from about 1 mm to about 5 mm.

The first tuning space 172a and the first tuning assembly 173a can extend second insertion lengths (y₂ₐ) into the process space 115, and the second insertion length (y₂ₐ) can be established relative to the plasma-facing surface 161 of the cover plate 160 in the SWA plasma source 150. The second insertion length (y₂ₐ) can be wavelength-dependent and can vary from about (λ/20) to about (10λ). Alternatively, the second insertion length (y₂ₐ) may vary from about 1 mm to about 5 mm. For example, the first insertion length (y₁ₐ) and the second insertion length (y₂ₐ) can be factors that can contribute to the spatial uniformity of the plasma formed in the process space 115. Alternatively, the first protection assembly 174a may be configured differently or may not be required.

The first plasma-tuning rod 170a can extend a third insertion length (y₃ₐ) into the process space 115, and the third insertion length (y₃ₐ) can be established relative to the plasma-facing surface 161 of the cover plate 160 of the SWA plasma source 150. The third insertion lengths (y₃ₐ) can be dependent upon the first movements 171a, can be wavelength-dependent, and can vary from about (λ/20) to about (10λ). Alternatively, the third insertion lengths (y₃ₐ) may vary from about 1 mm to about 5 mm. A controller 195 can control the third insertion lengths (y₃ₐ) using the first positioning subsystem 175a, and the controller 195 can use process recipes to establish, control, and optimize the third insertion lengths (y₃ₐ) in real-time to control the plasma uniformity within the process space 115. For example, the controller can control the first movements 171a and the third insertion lengths (y₃ₐ) associated with the first plasma-tuning rod 170a in real-time to control the first plasma-tuning EM energy provided to the process space 115 by the first plasma-tuning rod 170a.

The first SWA plasma source 150 can comprise a second protection assembly 174b that can be configured as an extension of the resonator plate 152. For example, the resonator plate 152 and the second protection assembly 174b can comprise a dielectric material, such as quartz. The design of the second protection assembly 174b can be used to control the spatial uniformity of the plasma in process space 115. In addition, the geometry, size, and material of the second protection assembly 174b can be factors that can contribute to the spatial uniformity of the plasma formed in the process space 115. Alternatively, the second protection assembly 174b may be configured differently or may not be required.

A second positioning subsystem 175b can be coupled to the second plasma-tuning rod 170b and can be coupled to at least one mounting structure 176. The second positioning subsystem 175b can be used to create second movements 171b in the second plasma-tuning rod 170b within a second tuning space 172b established in a second tuning assembly 173b. The second tuning space 172b and the second tuning assembly 173b can be configured to extend through the outer conductor 142, the slow wave plate 144, the slot antenna 146, the resonator plate 152, and the cover plate 160 and can extend into the second protection assembly 174b as shown. Alternatively, the second tuning space 172b and the second tuning assembly 173b can be configured differently.

As shown in FIG. 1A, the second plasma-tuning rod 170b can extend through the slow wave plate 144, the slot antenna 146, and the resonator plate 152 and can obtain second tunable EM energy from the slot antenna 146, the slow wave plate 144, and/or the resonator plate 152. The second plasma-tuning rod 170b that can have second movements 171b associated therewith and the second movements 171b can be used to control the tunable EM energy. For example, the second plasma-tuning rod 170b can move in a second (vertical) direction within a second tuning space 172b established in the second tuning assembly 173b. In addition, the second tunable EM energy provided to the process space 115 by the lower portion of the second plasma-tuning rod 170b can include a tunable E-field component, a tunable H-field component, a tunable voltage component, a tunable energy component, or a tunable current component, or any combination thereof.

The second tuning space 172b and the second tuning assembly 173b can be cylindrically shaped, and can have diameters (d_{1b}) larger than the diameter (l_{1b}) of the second plasma tuning rod 170b, thereby allowing the second plasma-tuning rod 170b to move freely therein. Alternatively, the number, shape, length, and/or position of the second plasma-tuning rod 170b may be different.

The second plasma-tuning rod 170b, second tuning space 172b, the second tuning assembly 173b, and the second protection assembly 174b can be aligned at a second x/y plane location (x_{1b}) in the process space 115, and the second tunable EM energy can be provided by the second plasma-tuning rod 170b at the second x/y plane location (x_{1b}) in the process space 115. Alternatively, the second plasma-tuning rod 170b, second tuning space 172b, the second tuning assembly 173b, and the second protection assembly 174b may be configured differently.

The second protection assembly 174b can extend a first insertion length (y_{1b}) into the process space 115, and the first insertion length (y_{1b}) can be established relative to the plasma-facing surface 161 of the cover plate 160 of the SWA plasma source 150. The first insertion length (y_{1b}) can be wavelength-dependent and can vary from about (λ/20) to about (10λ). Alternatively, the first insertion length (y_{1b}) may vary from about 1 mm to about 5 mm.

The second tuning space 172b and the second tuning assembly 173b can extend second insertion lengths (y_{2b}) into the process space 115, and the second insertion length (y_{2b}) can be established relative to the plasma-facing surface 161 of the cover plate 160 of the SWA plasma source 150. The second insertion length (y_{2b}) can be wavelength-dependent and can vary from about (λ/20) to about (10λ). Alternatively, the second insertion length (y_{2b}) may vary from about 1 mm to about 5 mm. For example, the first insertion length (y_{1b}) and the second insertion length (y_{2b}) can be factors that can contribute to the spatial uniformity of the plasma formed in the process space 115. Alternatively, the second protection assembly 174b may be configured differently or may not be required.

The second plasma-tuning rod 170b can extend a third insertion length (y_{3b}) into the process space 115, and the third insertion length (y_{3b}) can be established relative to the plasma-facing surface 161 of the cover plate 160 of the SWA plasma source 150. The third insertion lengths (y_{3b}) can be dependent upon the second movements 171b, can be wavelength-dependent, and can vary from about (λ/20) to about (10λ). Alternatively, the third insertion lengths (y_{3b}) may vary from about 1 mm to about 5 mm. The controller 195 can control the third insertion lengths (y_{3b}) using the second positioning subsystem 175b, and the controller 195 can use process recipes to establish, control, and optimize the third insertion lengths (y_{3b}) in real-time to control the plasma uniformity within the process space 115. For example, the controller can control the second movements 171b of the second plasma-tuning rod 170b in real-time to control the second tunable EM energy and the plasma uniformity within the process space 115.

The first SWA plasma source 150 can comprise a third protection assembly 174c that can be configured as an extension of the resonator plate 152. For example, the resonator plate 152 and the third protection assembly 174c can comprise a dielectric material, such as quartz. The design of the third protection assembly 174c can be used to control the spatial uniformity of the plasma in process space 115. In addition, the geometry, size, and material of the third protection assembly 174c can be factors that can contribute to the spatial uniformity of the plasma formed in the process space 115. Alternatively, the third protection assembly 174c may be configured differently or may not be required.

A third positioning subsystem 175c can be coupled to a third plasma-tuning rod 170c and can be coupled to the at least one mounting structure 176. The third positioning subsystem 175c can be used to create third movements 171c in the third plasma-tuning rod 170c within a third tuning space 172c established in a third tuning assembly 173c. The third tuning space 172c and the third tuning assembly 173c can be configured to extend through the outer conductor 142, the slow wave plate 144, the slot antenna 146, the resonator plate 152, and the cover plate 160 and can extend into the third protection assembly 174c as shown. Alternatively, the third tuning space 172c and the third tuning assembly 173c can be configured differently.

As shown in FIG. 1A, the third plasma-tuning rod 170c can extend through the slow wave plate 144, the slot antenna 146, and the resonator plate 152 and can obtain third tunable EM energy from the slot antenna 146, the slow wave plate 144, and/or the resonator plate 152. The third plasma-tuning rod 170c that can have third movements 171c associated therewith and the third movements 171c can be used to control the tunable EM energy. For example, the third plasma-tuning rod 170c can move in a third (vertical) direction within a third tuning space 172c established in the third tuning assembly 173c. In addition, the third tunable EM energy provided to the process space 115 by the lower portion of the third plasma-tuning rod 170c can include a tunable E-field component, a tunable H-field component, a tunable voltage component, a tunable energy component, or a tunable current component, or any combination thereof.

The third tuning space 172c and the third tuning assembly 173c can be cylindrically shaped, and can have diameters (d_{1c}) larger than the diameter (l_{1c}) of the third plasma tuning rods 170c, thereby allowing the third plasma-tuning rod 170c to move freely therein. Alternatively, the number, shape, length, and/or position of third plasma tuning rods 170c may be different.

The third plasma-tuning rod 170c, third tuning space 172c, the third tuning assembly 173c, and the third protection assembly 174c can be aligned at a third x/y plane location (x_{1c}) in the process space 115, and the third tunable EM energy can be provided by the third plasma-tuning rod 170c at the third x/y plane location (x_{1c}) in the process space 115. Alternatively, the third plasma-tuning rod 170c, third tuning space 172c, the third tuning assembly 173c, and the third protection assembly 174c may be configured differently.

The third protection assembly 174c can extend a first insertion length (y_{1c}) into the process space 115, and the first insertion length (y_{1c}) can be established relative to the plasma-facing surface 161 of the cover plate 160 of the SWA plasma source 150. The first insertion length (y_{1c}) can be wavelength-dependent and can vary from about (λ/20) to about (10λ), or the first insertion length (y_{1c}) may vary from about 1 mm to about 5 mm.

The third tuning space 172c and the third tuning assembly 173c can extend second insertion lengths (y_{2c}) into the process space 115, and the second insertion length (y_{2c}) can be established relative to the plasma-facing surface 161 of the cover plate 160 of the SWA plasma source 150. The second insertion length (y_{2c}) can be wavelength-dependent and can vary from about (λ/20) to about (10λ). Alternatively, the second insertion length (y_{2c}) may vary from about 1 mm to about 5 mm. For example, the first insertion length (y_{1c}) and the second insertion length (y_{2c}) can be factors that can contribute to the spatial uniformity of the plasma formed in the process space 115. Alternatively, the third protection assembly 174c may be configured differently or may not be required.

The third plasma-tuning rod 170c can extend a third insertion length (y_{3c}) into the process space 115, and the third insertion length (y_{3c}) can be established relative to the plasma-facing surface 161 of the cover plate 160 of the SWA plasma source 150. The third insertion lengths (y_{3c}) can be dependent upon the third movements 171c, can be wavelength-dependent, and can vary from about (λ/20) to about (10λ). Alternatively, the third insertion lengths (y_{3c}) may vary from about 1 mm to about 5 mm. The controller 195 can control the third insertion lengths (y_{3c}) using the third positioning subsystem 175c, and the controller 195 can use process recipes to establish, control, and optimize the third insertion lengths (y_{3c}) in real-time to control the plasma uniformity within the process space 115. For example, the controller can control the third movements 171c of the third plasma-tuning rod 170c in real-time to control the third tunable EM energy and the plasma uniformity within the process space 115.

The first SWA plasma source 150 can comprise a fourth protection assembly 174d that can be configured as an extension of the resonator plate 152. For example, the resonator plate 152 and the fourth protection assembly 174d can comprise a dielectric material, such as quartz. The design of the fourth protection assembly 174d can be used to control the spatial uniformity of the plasma in process space 115. In addition, the geometry, size, and material of the fourth protection assembly 174d can be factors that can contribute to the spatial uniformity of the plasma formed in the process space 115. Alternatively, the fourth protection assembly 174d may be configured differently or may not be required.

A fourth positioning subsystem 175d can be coupled to a fourth plasma-tuning rod 170d and can be coupled to at least one mounting structure 176. The fourth positioning subsystem 175d can be used to create fourth movements 171d in the fourth plasma-tuning rod 170d within a fourth tuning space 172d established in a fourth tuning assembly 173d. The fourth tuning space 172d and the fourth tuning assembly 173d can be configured to extend through the outer conductor 142, the slow wave plate 144, the slot antenna 146, the resonator plate 152, and the cover plate 160 and can extend into the fourth protection assembly 174d as shown. Alternatively, the fourth tuning space 172d and the fourth tuning assembly 173d can be configured differently.

As shown in FIG. 1A, the fourth plasma-tuning rod 170d can extend through the slow wave plate 144, the slot antenna 146, and the resonator plate 152 and can obtain fourth tunable EM energy from the slot antenna 146, the slow wave plate 144, and/or the resonator plate 152. The fourth plasma-tuning rod 170d that can have fourth movements 171d associated therewith and the fourth movements 171d can be used to control the tunable EM energy. For example, the fourth plasma-tuning rod 170d can move in a fourth (vertical) direction within a fourth tuning space 172d established in the fourth tuning assembly 173d. In addition, the fourth tunable EM energy provided to the process space 115 by the lower portion of the fourth plasma-tuning rod 170d can include a tunable E-field component, a tunable H-field component, a tunable voltage component, a tunable energy component, or a tunable current component, or any combination thereof.

The fourth tuning space 172d and the fourth tuning assembly 173d can be cylindrically shaped, and can have diameters (d_{1d}) larger than the diameter (l_{1d}) of the fourth plasma tuning rods 170d, thereby allowing the fourth plasma-tuning rod 170d to move freely therein. Alternatively, the number, shape, length, and/or position of fourth plasma tuning rods 170d may be different.

The fourth plasma-tuning rod 170d, fourth tuning space 172d, the fourth tuning assembly 173d, and the fourth protection assembly 174d can be aligned at a fourth x/y plane location (x_{1d}) in the process space 115, and the fourth tunable EM energy can be provided by the fourth plasma-tuning rod 170d at the fourth x/y plane location (x_{1d}) in the process space 115. Alternatively, the fourth plasma-tuning rod 170d, fourth tuning space 172d, the fourth tuning assembly 173d, and the fourth protection assembly 174d may be configured differently.

The fourth protection assembly 174d can extend a first insertion length (y_{1d}) into the process space 115, and the first insertion length (y_{1d}) can be established relative to the plasma-facing surface 161 of the cover plate 160 of the SWA plasma source 150. The first insertion length (y_{1d}) can be wavelength-dependent and can vary from about (λ/20) to about (10λ). Alternatively, the first insertion length (y_{1d}) may vary from about 1 mm to about 5 mm.

The fourth tuning space 172d and the fourth tuning assembly 173d can extend second insertion lengths (y_{2d}) into the process space 115, and the second insertion length (y_{2d}) can be established relative to the plasma-facing surface 161 of the cover plate 160 of the SWA plasma source 150. The second insertion length (y_{2d}) can be wavelength-dependent and can vary from about (λ/20) to about (10λ). Alternatively, the second insertion length (y_{2d}) may vary from about 1 mm to about 5 mm. For example, the first insertion length (y_{1d}) and the second insertion length (y_{2d}) can be factors that can contribute to the spatial uniformity of the plasma formed in the process space 115. Alternatively, the fourth protection assembly 174d may be configured differently or may not be required.

The fourth plasma-tuning rod 170d can extend a third insertion length (y_{3d}) into the process space 115, and the third insertion length (y_{3d}) can be established relative to the plasma-facing surface 161 of the cover plate 160 of the SWA plasma source 150. The third insertion lengths (y_{3d}) can be dependent upon the fourth movements 171d, can be wavelength-dependent, and can vary from about (λ/20) to about (10λ). Alternatively, the third insertion lengths (y_{3d}) may vary from about 1 mm to about 5 mm. The controller 195 can control the third insertion lengths (y_{3d}) using the fourth positioning subsystem 175d, and the controller 195 can use process recipes to establish, control, and optimize the third insertion lengths (y_{3d}) in real-time to control the plasma uniformity within the process space 115. For example, the controller can control the fourth movements 171d of the fourth plasma-tuning rod 170d in real-time to control the fourth tunable EM energy and the plasma uniformity within the process space 115.

In some embodiments, the first SWA processing system 100 can be configured to form plasma in the process space 115 as the substrate holder 120 and the substrate are moved through the process space 115. In other embodiments, the first SWA processing system 100 can be configured to form plasma in the process space 115 as the substrate holder 120 and the substrate are positioned within the process space 115. Alternatively, the substrate holder 120 may or may not be movable.

For example, the x/y plane offsets {(x₁ₐ), (x_{1b}), (x_{1c}), and (x_{1d})} can be established relative to one of the chamber walls 112, can be wavelength-dependent, and can vary from about (λ/4) to about (10λ).

The controller 195 can be coupled 196 to the EM source 190, the match network/phase shifter 191, and the tuner network/isolator 192, and the controller 195 can use process recipes to establish, control, and optimize the EM source 190, the match network/phase shifter 191, and the tuner network/isolator 192 to control the plasma uniformity within the process space 115. For example, the EM source 190 can operate at frequencies from about 500 MHz to about 5000 MHz. In addition, the controller 195 can be coupled 196 to the process sensors 107, and the controller 195 can use process recipes to establish, control, and optimize the data from the process sensors 107 to control the plasma uniformity within the process space 115.

Some of the first SWA processing systems 100 can include a pressure control system 125 and exhaust port 126 coupled to the process chamber 110, and configured to evacuate the process chamber 110, as well as control the pressure within the process chamber 110. Alternatively, the pressure control system 125 and/or the exhaust port 126 may not be required.

As shown in FIG. 1A, the first SWA processing system 100 can comprise a first gas supply system 180 coupled to one or more first flow elements 181 that can be coupled to the process chamber 110. The first flow elements 181 can be configured to introduce a first process gas to process space 115, and can include flow control and/or flow measuring devices. In addition, the first SWA processing system 100 can comprise a second gas supply system 182 coupled to one or more second flow elements 183 that can be coupled to the process chamber 110. The second flow elements 183 can be configured to introduce a second process gas to process space 115, and can include flow control and/or flow measuring devices. Alternatively, the second gas supply system 182 and/or the second flow elements 183 may not be required.

During dry plasma etching, the process gas may comprise an etchant, a passivant, or an inert gas, or a combination of two or more thereof. For example, when plasma etching a dielectric film such as silicon oxide (SiOₓ) or silicon nitride (SiₓN_{y}), the plasma etch gas composition generally includes a fluorocarbon-based chemistry (CₓF_{y}) such as at least one of C₄F₈, C₅F₈, C₃F₆, C₄F₆, CF₄, etc., and/or may include a fluorohydrocarbon-based chemistry (CₓH_{y}F_{z}) such as at least one of CHF₃, CH₂F₂, etc., and can have at least one of an inert gas, oxygen, CO or CO₂. Additionally, for example, when etching polycrystalline silicon (poliesilicon), the plasma etch gas composition generally includes a halogen-containing gas such as HBr, Cl₂, NF₃, or SF₆ or a combination of two or more thereof, and may include fluorohydrocarbon-based chemistry (CₓH_{y}F_{z}) such as at least one of CHF₃, CH₂F₂, etc., and at least one of an inert gas, oxygen, CO or CO₂, or two or more thereof. During plasma-enhanced deposition, the process gas may comprise a film forming precursor, a reduction gas, or an inert gas, or a combination of two or more thereof.

FIG. 1B illustrates a partial bottom view of a cover plate 160 in the first SWA plasma source 150 in accordance with embodiments of the invention. The cover plate 160 can have a total length (x_{T}) and a total width (z_{T}) associated therewith in the x/z plane. For example, the total length (x_{T}) can vary from about 10 mm to about 1000 mm, and the total width (z_{T}) can vary from about 10 mm to about 1000 mm.

The partial bottom view of cover plate 160 in the first SWA plasma source 150 includes a bottom (dotted line) view of the first plasma-tuning rod 170a that is shown surrounded by a bottom (dash line) view of the first tuning assembly 173a, and the bottom view of the first tuning assembly 173a is shown surrounded by a bottom view of the first protection assembly 174a.

The first plasma-tuning rod 170a can have a first diameter (d₁ₐ) associated therewith, and the first diameter (d₁ₐ) can vary from about 0.01 mm to about 1 mm. The first tuning assembly 173a can have a first diameter (D₁ₐ) associated therewith, and the first diameter (D₁ₐ) can vary from about 1 mm to about 10 mm. The first protection assembly 174a can have a first length (l₁ₐ) associated therewith, and the first length (l₁ₐ) can vary from about 1 mm to about 10 mm. The first plasma-tuning rod 170a, the first tuning assembly 173a, and the first protection assembly 174a can have first x/z plane offsets (x₁ₐ) associated therewith, and the first x/z plane offsets (x₁ₐ) can vary from about 10 mm to about 1000 mm. Alternatively, the first plasma-tuning rod 170a, the first tuning assembly 173a, and the first protection assembly 174a may have different first x/z plane offsets (x₁ₐ) associated therewith. The first plasma-tuning rod 170a, the first tuning assembly 173a, and the first protection assembly 174a can have first x/z plane offsets (z₁ₐ) associated therewith, and the first x/z plane offsets (z₁ₐ) can vary from about 10 mm to about 1000 mm. Alternatively, the first plasma-tuning rod 170a, the first tuning assembly 173a, and the first protection assembly 174a may have different first x/z plane offsets (z₁ₐ) associated therewith.

The partial bottom view of cover plate 160 in the first SWA plasma source 150 includes a bottom (dotted line) view of the second plasma-tuning rod 170b that is shown surrounded by a bottom (dash line) view of the second tuning assembly 173b, and the bottom view of the second tuning assembly 173b is shown surrounded by a bottom view of the second protection assembly 174b.

The second plasma-tuning rod 170b can have a first diameter (d_{1b}) associated therewith, and the first diameter (d_{1b}) can vary from about 0.01 mm to about 1 mm. The second tuning assembly 173b can have a first diameter (D_{1b}) associated therewith, and the first diameter (D_{1b}) can vary from about 1 mm to about 10 mm. The second protection assembly 174b can have a first length (l_{1b}) associated therewith, and the first length (l_{1b}) can vary from about 1 mm to about 10 mm. The second plasma-tuning rod 170b, the second tuning assembly 173b, and the second protection assembly 174b can have first x/z plane offsets (x_{1b}) associated therewith, and the first x/z plane offsets (x_{1b}) can vary from about 10 mm to about 1000 mm. Alternatively, the second plasma-tuning rod 170b, the second tuning assembly 173b, and the second protection assembly 174b may have different first x/z plane offsets (x_{1b}) associated therewith. The second plasma-tuning rod 170b, the second tuning assembly 173b, and the second protection assembly 174b can have first x/z plane offsets (z_{1b}) associated therewith, and the first x/z plane offsets (z_{1b}) can vary from about 10 mm to about 1000 mm. Alternatively, the second plasma-tuning rod 170b, the second tuning assembly 173b, and the second protection assembly 174b may have different first x/z-lane offsets (z_{1b}) associated therewith.

Still referring to FIG. 1B, the partial bottom view of cover plate 160 in the first SWA plasma source 150 includes a bottom (dotted line) view of the third plasma-tuning rod 170c that is shown surrounded by a bottom (dash line) view of the third tuning assembly 173c, and the bottom view of the third tuning assembly 173c is shown surrounded by a bottom view of the third protection assembly 174c.

The third plasma-tuning rod 170c can have a first diameter (d_{1c}) associated therewith, and the first diameter (d_{1c}) can vary from about 0.01 mm to about 1 mm. The third tuning assembly 173c can have a first diameter (D_{1c}) associated therewith, and the first diameter (D_{1c}) can vary from about 1 mm to about 10 mm. The third protection assembly 174c can have a first length (l_{1c}) associated therewith, and the first length (l_{1c}) can vary from about 1 mm to about 10 mm. The third plasma-tuning rod 170c, the third tuning assembly 173c, and the third protection assembly 174c can have first x/z plane offsets (x_{1c}) associated therewith, and the first x/z plane offsets (x_{1c}) can vary from about 10 mm to about 1000 mm. Alternatively, the third plasma-tuning rod 170c, the third tuning assembly 173c, and the third protection assembly 174c may have different first x/z plane offsets (x_{1c}) associated therewith. The third plasma-tuning rod 170c, the third tuning assembly 173c, and the third protection assembly 174c can have first x/z plane offsets (z_{1c}) associated therewith, and the first x/z plane offsets (z_{1c}) can vary from about 10 mm to about 1000 mm. Alternatively, the third plasma-tuning rod 170c, the third tuning assembly 173c, and the third protection assembly 174c may have different first x/z plane offsets (z_{1c}) associated therewith.

The partial bottom view of cover plate 160 in the first SWA plasma source 150 also includes a bottom (dotted line) view of the fourth plasma-tuning rod 170d that is shown surrounded by a bottom (dash line) view of the fourth tuning assembly 173d, and the bottom view of the fourth tuning assembly 173d is shown surrounded by a bottom view of the fourth protection assembly 174d.

The fourth plasma-tuning rod 170d can have a first diameter (d_{1d}) associated therewith, and the first diameter (d_{1d}) can vary from about 0.01 mm to about 1 mm. The fourth tuning assembly 173d can have a first diameter (D_{1d}) associated therewith, and the first diameter (D_{1d}) can vary from about 1 mm to about 10 mm. The fourth protection assembly 174d can have a first length (l_{1d}) associated therewith, and the first length (l_{1d}) can vary from about 1 mm to about 10 mm. The fourth plasma-tuning rod 170d, the fourth tuning assembly 173d, and the fourth protection assembly 174d can have first x/z plane offsets (x_{1d}) associated therewith, and the first x/z plane offsets (x_{1d}) can vary from about 10 mm to about 1000 mm. Alternatively, the fourth plasma-tuning rod 170d, the fourth tuning assembly 173d, and the fourth protection assembly 174d may have different first x/z plane offsets (x_{1d}) associated therewith. The fourth plasma-tuning rod 170d, the fourth tuning assembly 173d, and the fourth protection assembly 174d can have first x/z plane offsets (z_{1d}) associated therewith, and the first x/z plane offsets (z_{1d}) can vary from about 10 mm to about 1000 mm. Alternatively, the fourth plasma-tuning rod 170d, the fourth tuning assembly 173d, and the fourth protection assembly 174d may have different first x/z plane offsets (z_{1d}) associated therewith.

FIG. 1C illustrates a side view of a first SWA processing system in accordance with embodiments of the invention. The first SWA processing system 100 can comprise a side view of a first SWA plasma source 150 having a slot antenna 146 therein.

The first SWA processing system 100 can comprise a process chamber 110 configured to define a process space 115. The side view shows a y/z plane view of a process chamber 110 that can be configured using a cover plate 160 and a plurality of chamber walls 112 coupled to each other and the cover plate 160. For example, the chamber walls 112 can have wall thicknesses (t) associated therewith, and the wall thicknesses (t) can vary from about 1 mm to about 5 mm. The cover plate 160 have a first cover plate thickness associated therewith that can vary from about 1 mm to about 10 mm.

The side view of the process chamber 110 includes a side view of the substrate holder 120 configured to support a substrate 105. The substrate 105 can be exposed to plasma and/or process chemistry in process space 115. The first SWA processing system 100 can comprise a first SWA plasma source 150 coupled to the plasma chamber 110, and configured to form plasma in the process space 115.

FIG. 1C illustrates that one or more EM sources 190 can be coupled to the first SWA plasma source 150, and the EM energy generated by the EM source 190 can flow through a match network/phase shifter 191 to a tuner network/isolator 192 for absorbing EM energy reflected back to the EM source 190. The EM energy can be converted to a TEM (transverse electromagnetic) mode via the tuner network/isolator 192. A tuner may be employed for impedance matching, and improved power transfer. For example, the EM source 190, the match network/phase shifter 191, and the tuner network/isolator 192 can operate from about 500 MHz to about 5000 MHz.

The first SWA plasma source 150 can comprise a feed assembly 140 having an inner conductor 141, an outer conductor 142, an insulator 143, and a slot antenna 146 having a plurality of first slots 148 and a plurality of second slots 149 coupled between the inner conductor 141 and the outer conductor 142. The plurality of slots (148 and 149) permit the coupling of EM energy from a first region above the slot antenna 146 to a second region below the slot antenna 146.

The design of the slot antenna can be used to control the spatial uniformity of the plasma in process space 115. For example, the number, geometry, size, and distribution of the plurality of first and second slots (148, and 149) are all factors that can contribute to the spatial uniformity of the plasma formed in the process space 115.

Some exemplary first SWA plasma sources 150 can comprise a slow wave plate 144, and the design of the slow wave plate 144 can be used to control the spatial uniformity of the plasma in process space 115. For example, the geometry, size, and plate material can be factors that can contribute to the spatial uniformity of the plasma formed in the process space 115. Alternatively, the slow wave plate 144 may be configured differently or may not be required.

Other exemplary first SWA plasma sources 150 can comprise a resonator plate 152, and the design of the resonator plate 152 can be used to control the spatial uniformity of the plasma in process space 115. For example, the geometry, size, and the resonator plate material can be factors that can contribute to the spatial uniformity of the plasma formed in the process space 115. Alternatively, the resonator plate 152 may be configured differently or may not be required.

Still other exemplary first SWA plasma sources 150 can comprise a cover plate 160, and the design of the cover plate 160 can be used to control the spatial uniformity of the plasma in process space 115. For example, the geometry, size, and the cover plate material can be factors that can contribute to the spatial uniformity of the plasma formed in the process space 115. Alternatively, the cover plate 160 may be configured differently or may not be required.

Other additional exemplary first SWA plasma sources 150 can comprise one or more fluid channels 156 that can be configured to flow a temperature control fluid for temperature control of the first SWA plasma source 150. The design of the fluid channels 156 can be used to control the spatial uniformity of the plasma in process space 115. For example, the geometry, size, and flow rate of the fluid channels 156 can be factors that can contribute to the spatial uniformity of the plasma formed in the process space 115. Alternatively, the fluid channels 156 may be configured differently or may not be required.

The EM energy can be coupled to the first SWA plasma source 150 via the feed assembly 140, wherein another mode change occurs from the TEM mode in the feed assembly 140 to a TM (transverse magnetic) mode. Additional details regarding the design of the feed assembly 140 and the slot antenna 146 can be found in U.S. Pat. No. 5,024,716, entitled “Plasma processing apparatus for etching, ashing, and film-formation”; the content of which is herein incorporated by reference in its entirety.

FIG. 1C illustrates that the first SWA plasma source 150 can comprise a first set of protection assemblies (174a-174d) that can be configured as extensions of the resonator plate 152. For example, the resonator plate 152 and the first set of protection assemblies (174a-174d) can comprise a dielectric material, such as quartz. The design of the first set of protection assemblies (174a-174d) can be used to control the spatial uniformity of the plasma in process space 115. In addition, the geometry, size, and material of the first set of protection assemblies (174a-174d) can be factors that can contribute to the spatial uniformity of the plasma formed in the process space 115. Alternatively, the first set of protection assemblies (174a-174d) may be configured differently or may not be required.

A first set of positioning subsystems (175a-175d) can be coupled to the first set of plasma-tuning rods (170a-170d) and can be coupled to at least one mounting structure 176. The first set of positioning subsystems (175a-175d) can be used to create the set of first movements (171a-171d) in the first set of plasma-tuning rods (170a-170d) within the first set of tuning spaces (172a-172d) established in the first set of tuning assemblies (173a-173d). The first set of tuning spaces (172a-172d) and the first set of tuning spaces (172a-172d) can be configured to extend through the outer conductor 142, the slow wave plate 144, the slot antenna 146, the resonator plate 152, and the cover plate 160 and can extend into the first set of protection assemblies (174a-174d). Alternatively, the first set of tuning spaces (172a-172d), and the first set of tuning assemblies (173a-173d) can be configured differently.

The first set of tuning spaces (172a-172d) and the first set of tuning assemblies (173a-173d) can be cylindrically shaped, and can have diameters (d_{1a-d}) larger than the diameters (l_{1a-d}) of the first set of plasma-tuning rods (170a-170d), thereby allowing the first set of plasma-tuning rods (170a-170d) to move freely therein. Alternatively, the number, shape, length, and/or position of first plasma tuning rods 170a may be different.

The first set of plasma-tuning rods (170a-170d), first set of tuning spaces (172a-172d), the first set of tuning assemblies (173a-173d), and the first set of protection assemblies (174a-174d) can be aligned at first y/z plane locations (z_{1a-d}) in the process space 115, and the first set of tunable microwave energies can be provided by the first set of plasma-tuning rods (170a-170d) at the first y/z plane locations (z_{1a-d}) in the process space 115. Alternatively, the first set of plasma-tuning rods (170a-170d), first set of tuning spaces (172a-172d), the first set of tuning assemblies (173a-173d), and the first set of protection assemblies (174a-174d) may be configured differently.

The first set of protection assemblies (174a-174d) can extend first insertion lengths (y_{1a-d}) into the process space 115, and the set of first insertion lengths (y_{1a-d}) can be established relative to the plasma-facing surface 161 of the cover plate 160. The set of first insertion lengths (y_{1a-d}) can be wavelength-dependent and may vary from about (λ/20) to about (10λ). Alternatively, the set of first insertion lengths (y_{1a-d}) may vary from about 1 mm to about 5 mm.

The first set of tuning spaces (172a-172d) and the first set of tuning assemblies (173a-173d) can extend second insertion lengths (y_{2a-d}) into the process space 115, and the set of second insertion lengths (y_{2a-d}) can be established relative to the plasma-facing surface 161 of the cover plate 160. The set of second insertion lengths (y_{2a-d}) can be wavelength-dependent and can vary from about (λ/20) to about (10λ). Alternatively, the set of second insertion lengths (y_{2a-d}) may vary from about 1 mm to about 5 mm. For example, the set of first insertion lengths (y_{1a-d}) and the set of second insertion lengths (y_{2a-d}) can be factors that can contribute to the spatial uniformity of the plasma formed in the process space 115. Alternatively, the first set of protection assemblies (174a-174d) may be configured differently or may not be required.

The first set of plasma-tuning rods (170a-170d) can extend third insertion lengths (y_{3a-d}) into the process space 115, and the set of third insertion lengths (y_{3a-d}) can be established relative to the plasma-facing surface 161 of the cover plate 160. The set of third insertion lengths (y_{3a-d}) can be dependent upon the set of first movements (171a-171d), can be wavelength-dependent, and can vary from about (λ/20) to about (10λ). Alternatively, the set of third insertion lengths (y_{3a-d}) may vary from about 1 mm to about 5 mm. The controller 195 can control the set of third insertion lengths (y_{3a-d}) using the first set of positioning subsystems (175a-175d), and the controller 195 can use process recipes to establish, control, and optimize the set of third insertion lengths (y_{3a-d}) in real-time to control the plasma uniformity within the process space 115. For example, the controller can control the set of first movements (171a-171d) of the first set of plasma-tuning rods (170a-170d) in real-time to control the first tunable EM energy and the plasma uniformity within the process space 115.

In some embodiments, the first SWA processing system 100 can be configured to form plasma in the process space 115 as the substrate holder 120 and the substrate are moved through the process space 115. In other embodiments, the first SWA processing system 100 can be configured to form plasma in the process space 115 as the substrate holder 120 and the substrate are positioned within the process space 115.

For example, the y/z plane offsets {(z₁ₐ), (z_{1b}), (z_{1c}), and (z_{1d})} can be established relative to one of the chamber walls 112, can be wavelength-dependent, and can vary from about (λ/4) to about (10λ).

The controller 195 can be coupled 196 to the EM source 190, the match network/phase shifter 191, and the tuner network/isolator 192, and the controller 195 can use process recipes to establish, control, and optimize the EM source 190, the match network/phase shifter 191, and the tuner network/isolator 192 to control the plasma uniformity within the process space 115. For example, the EM source 190 can operate at frequencies from about 500 MHz to about 5000 MHz. In addition, the controller 195 can be coupled 196 to the process sensors 107, and the controller 195 can use process recipes to establish, control, and optimize the data from the process sensors 107 to control the plasma uniformity within the process space 115.

Some of the first SWA processing systems 100 can include a pressure control system 125 and exhaust port 126 coupled to the process chamber 110, and configured to evacuate the process chamber 110, as well as control the pressure within the process chamber 110. Alternatively, the pressure control system 125 and/or the exhaust port 126 may not be required.

As shown in FIG. 1C, the first SWA processing system 100 can comprise a first gas supply system 180 coupled to one or more first flow elements 181 that can be coupled to the process chamber 110. The first flow elements 181 can be configured to introduce a first process gas to process space 115, and can include flow control and/or flow measuring devices. In addition, the first SWA processing system 100 can comprise a second gas supply system 182 coupled to one or more second flow elements 183 that can be coupled to the process chamber 110. The second flow elements 183 can be configured to introduce a second process gas to process space 115, and can include flow control and/or flow measuring devices. Alternatively, the second gas supply system 182 and/or the second flow elements 183 may not be required.

During dry plasma etching, the process gas may comprise an etchant, a passivant, or an inert gas, or a combination of two or more thereof. For example, when plasma etching a dielectric film such as silicon oxide (SiOₓ) or silicon nitride (SiₓN_{y}), the plasma etch gas composition generally includes a fluorocarbon-based chemistry (CₓF_{y}) such as at least one of C₄F₈, C₅F₈, C₃F₆, C₄F₆, CF₄, etc., and/or may include a fluorohydrocarbon-based chemistry (CₓH_{y}F_{z}) such as at least one of CHF₃, CH₂F₂, etc., and can have at least one of an inert gas, oxygen, CO or CO₂. Additionally, for example, when etching polycrystalline silicon (poliesilicon), the plasma etch gas composition generally includes a halogen-containing gas such as HBr, Cl₂, NF₃, or SF₆ or a combination of two or more thereof, and may include fluorohydrocarbon-based chemistry (CₓH_{y}F_{z}) such as at least one of CHF₃, CH₂F₂, etc., and at least one of an inert gas, oxygen, CO or CO₂, or two or more thereof. During plasma-enhanced deposition, the process gas may comprise a film forming precursor, a reduction gas, or an inert gas, or a combination of two or more thereof.

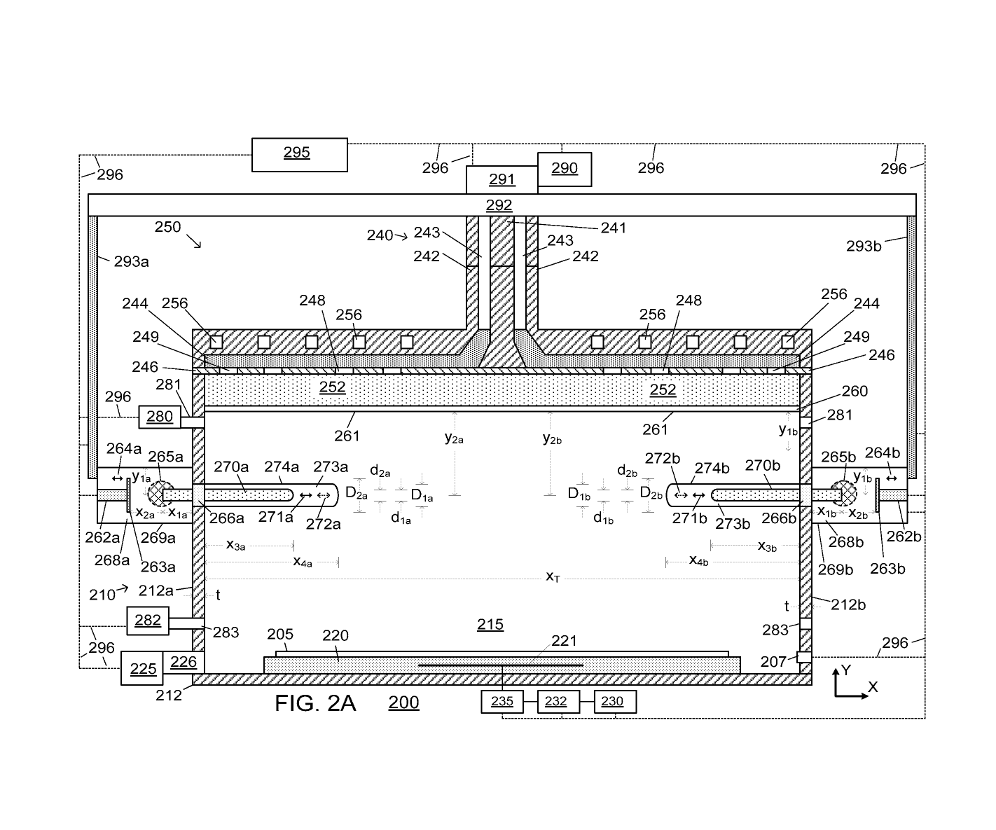

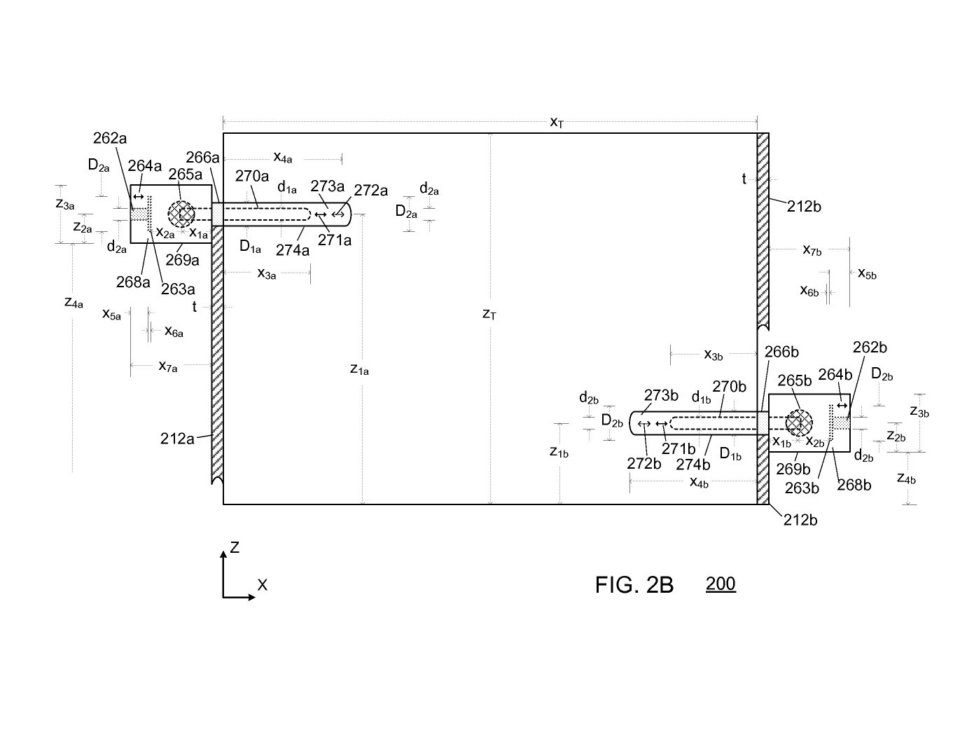

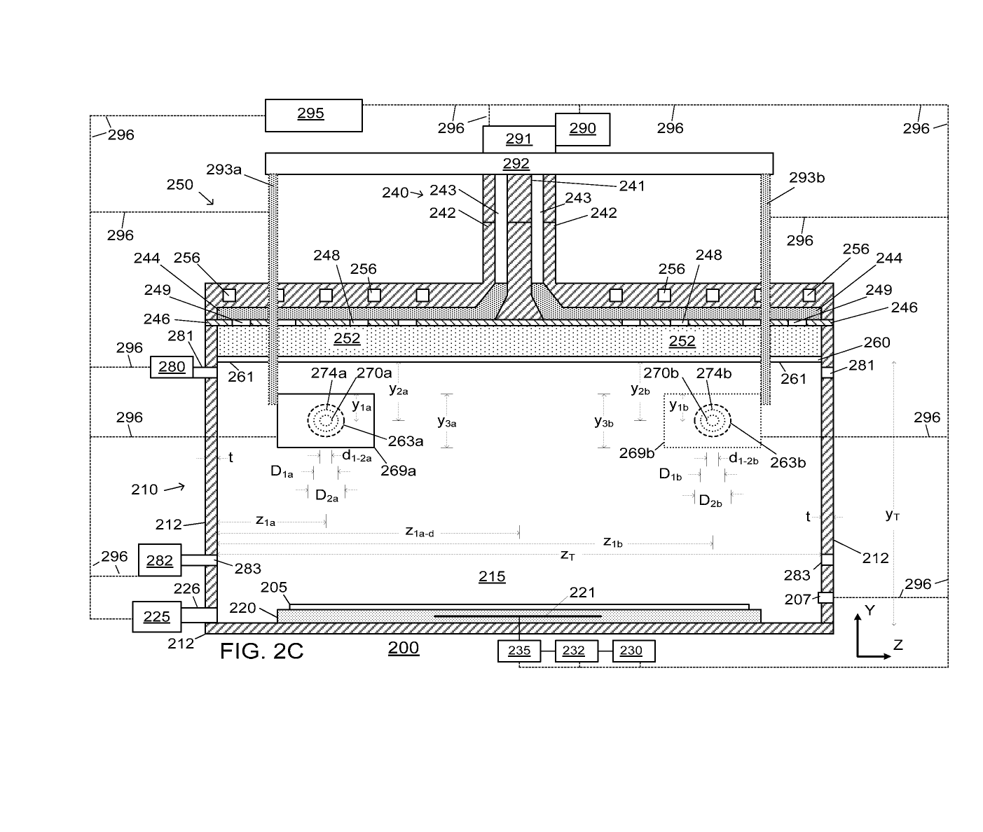

FIG. 2A illustrates a front view of a second SWA processing system in accordance with embodiments of the invention. The second SWA processing system 200 can comprise a second SWA plasma source 250 having a slot antenna 246 therein. For example, the second SWA processing system 200 can comprise a dry plasma etching system or a plasma enhanced deposition system.

The second SWA processing system 200 can comprise a second process chamber 210 configured to define a process space 215. The front view shows an x/y plane front view of a second process chamber 210 that can be configured using a cover plate 260 and a plurality of chamber walls (212, 212a, and 212b) coupled to each other and to the cover plate 260. For example, the chamber walls (212, 212a, and 212b) can have wall thicknesses (t) associated therewith, and the wall thicknesses (t) can vary from about 1 mm to about 5 mm. The cover plate 260 have a cover plate thickness associated therewith, and the cover plate thickness can vary from about 1 mm to about 10 mm.

The second process chamber 210 can comprise a substrate holder 220 configured to support a substrate 205. The substrate 205 can be exposed to plasma and/or process chemistry in process space 215. The second SWA processing system 200 can comprise a second SWA plasma source 250 coupled to the second process chamber 210, and configured to form plasma in the process space 215.

In some embodiments, one or more EM sources 290 can be coupled to the second SWA plasma source 250, and the EM energy generated by the EM source 290 can flow through a match network/phase shifter 291 to a tuner network/isolator 292 for absorbing EM energy reflected back to the EM source 290. The EM energy can be converted to a TEM (transverse electromagnetic) mode via the tuner network/isolator 292. A tuner may be employed for impedance matching, and improved power transfer. For example, the EM source 290, the match network/phase shifter 291, and the tuner network/isolator 292 can operate from about 500 MHz to about 5000 MHz.

In other embodiments, the second EM source 290 can be coupled to a first resonant cavity 269a and a second resonant cavity 269b. Alternatively, one or more separate EM sources (not shown) may be coupled to the first resonant cavity 269a and/or to the second resonant cavity 269b. For example, the tuner network/isolator 292 can be coupled to a first coupling (matching) network 293a and to a second coupling (matching) network 293b. Alternatively, a plurality of EM sources (not shown) or a plurality of coupling networks (not shown) may be used. The first coupling (matching) network 293a can be removably coupled to a first resonant cavity 269a and can be used to provide first EM energy to the first resonant cavity 269a. The second coupling (matching) network 293b can be removably coupled to the second resonant cavity 269b and can be used to provide second EM energy to the second resonant cavity 269b. Alternatively, other coupling configurations may be used.

The second SWA plasma source 250 can comprise a feed assembly 240 having an inner conductor 241, an outer conductor 242, an insulator 243, and a slot antenna 246 having a plurality of first slots 248 and a plurality of second slots 249 coupled between the inner conductor 241 and the outer conductor 242. The plurality of slots (248 and 249) permit the coupling of EM energy from a first region above the slot antenna 246 to a second region below the slot antenna 246. The design of the slot antenna 246 in the x/y plane can be used to control the spatial uniformity of the plasma in process space 215. For example, the number, geometry, size, and distribution of the slots (248, and 249) are all factors that can contribute to the spatial uniformity of the plasma formed in the process space 215.

Some exemplary second SWA plasma sources 250 can comprise a slow wave plate 244, and the design of the slow wave plate 244 in the x/y plane can be used to control the spatial uniformity of the plasma in process space 215. For example, the geometry, size, and plate material can be factors that can contribute to the spatial uniformity of the plasma formed in the process space 215. Alternatively, the slow wave plate 244 may be configured differently or may not be required.

Other exemplary second SWA plasma sources 250 can comprise a resonator plate 252, and the design of the resonator plate 252 in the x/y plane can be used to control the spatial uniformity of the plasma in process space 215. For example, the geometry, size, and the resonator plate material can be factors that can contribute to the spatial uniformity of the plasma formed in the process space 215. Alternatively, the resonator plate 252 may be configured differently or may not be required.

Still other exemplary second SWA plasma sources 250 can comprise a cover plate 260 configured to protect the resonator plate 252, and the design of the cover plate 260 in the x/y plane can be used to control the spatial uniformity of the plasma in process space 215. For example, the geometry, size, and the cover plate material can be factors that can contribute to the spatial uniformity of the plasma formed in the process space 215. Alternatively, the cover plate 260 may be configured differently or may not be required.

Other additional exemplary second SWA plasma sources 250 can comprise one or more fluid channels 256 that can be configured to flow a temperature control fluid for temperature control of the second SWA plasma source 250. The design of the fluid channels 256 can be used to control the spatial uniformity of the plasma in process space 215. For example, the geometry, size, and flow rate of the fluid channels 256 can be factors that can contribute to the spatial uniformity of the plasma formed in the process space 215. Alternatively, the fluid channels 256 may be configured differently or may not be required.

The EM energy can be coupled to the second SWA plasma source 250 via the feed assembly 240, and mode changes can occur in the feed assembly 240. Additional details regarding the design of the feed assembly 240 and the slot antenna 246 can be found in U.S. Pat. No. 5,024,716, entitled “Plasma processing apparatus for etching, ashing, and film-formation”; the content of which is herein incorporated by reference in its entirety.

The front view illustrates that the second SWA processing system 200 can comprise a plurality of plasma-tuning rods (270a and 270b) and a plurality of protection assemblies (274a and 274b) that can be coupled to a plurality of isolation assemblies (266a and 266b). For example, the plasma-tuning rods (270a and 270b) and the protection assemblies (274a and 274b) can comprise dielectric materials, such as quartz. Alternatively, the plasma-tuning rods (270a and 270b) and the protection assemblies (274a and 274b) may comprise semiconductor or metallic materials. In addition, the isolation assemblies (266a and 266b) can include isolation and movement devices (not shown) and the isolation assemblies (266a and 266b) may comprise dielectric, semiconductor, and/or metallic materials.

The design of the plasma-tuning rods (270a and 270b) and the protection assemblies (274a and 274b) can be used to control the spatial uniformity of the plasma in process space 215. For example, the geometry, size, and material of the plasma-tuning rods (270a and 270b) and/or the protection assemblies (274a and 274b) can be factors that can contribute to the spatial uniformity of the plasma formed in the process space 215. Alternatively, the plasma-tuning rods (270a and 270b) or the protection assemblies (274a and 274b) may be configured differently or may not be required.

Still referring to FIG. 2A, a second portion of the first plasma-tuning rod 270a is shown extending into the first isolated tuning space 273a established in the first protection assembly 274a at a first x/y plane location (y₂ₐ) in the process space 215, and a first portion of the first plasma-tuning rod 270a is shown extending into the first EM energy tuning space 268a in the first resonant cavity 269a at the first x/y plane location (y₂ₐ). A first isolation assembly 266a can include movement devices (not shown) that can be used to position and move 271a the first plasma-tuning rod 270a the first plasma-tuning distances 272a within the first isolated tuning space 273a established in the first protection assembly 274a. For example, the first plasma-tuning distance 272a can vary from about 0.10 mm to about 1 mm, and the first plasma-tuning distance 272a can be wavelength-dependent and can vary from about (λ/40) to about (10λ).

A first coupling region 265a can be established in the first EM energy tuning space 268a at a first coupling distance (x₁ₐ) from one or more of the walls of the first resonant cavity 269a, and the first portion of the first plasma-tuning rod 270a can extend into the first coupling region 265a in the first EM energy tuning space 268a. The first portion of the first plasma-tuning rod 270a can obtain first tunable EM energy from the first coupling region 265a, and the first EM energy can be transferred to the process space 215 at the first x/y plane location defined using (y₂ₐ) using the second portion of the first plasma-tuning rod 270a. The first coupling region 265a can include a tunable E-field region, a tunable H-field region, a maximum field region, a maximum voltage region, maximum energy region, or a maximum current region, or any combination thereof. For example, the first coupling distance (x₁ₐ) can vary from about 0.01 mm to about 10 mm, and the first coupling distance (x₁ₐ) can be wavelength-dependent and can vary from about (λ/4) to about (10λ).

A first tuning slab 263a can be coupled to a first control assembly 262a and can be used to move 264a the first tuning slab 263a a first cavity-tuning distance (x₂ₐ) relative to the first portion of the first plasma-tuning rod 270a within the first EM energy tuning space 268a in the first resonant cavity 269a. The first control assembly 262a and the first tuning slab 263a can be used to optimize the first EM energy coupled from the first coupling region 265a to the second portion of the first plasma-tuning rod 270a. For example, the first plasma-tuning distance 272a can vary from about 0.01 mm to about 1 mm.

The controller 295 can be coupled 296 to the first control assembly 262a and can control the first cavity-tuning distance (x₂ₐ) using the first control assembly 262a, and the controller 295 can use process recipes to establish, control, and optimize the first cavity-tuning distance (x₂ₐ) in real-time to control the plasma uniformity within the process space 215. Alternatively, the controller 295 may independently control the first movements 271a of the first plasma-tuning rod 270a in real-time to control the first tunable EM energy and the plasma uniformity within the process space 215.

The first plasma-tuning rod 270a can have a first diameter (d₁ₐ) associated therewith, and the first diameter (d₁ₐ) can vary from about 0.01 mm to about 1 mm. The first isolation assembly 274a can have a first diameter (D₁ₐ) associated therewith, and the first diameter (D₁ₐ) can vary from about 1 mm to about 10 mm.

The second portion of the first plasma-tuning rod 270a, the first coupling region 265a, the first control assembly 262a, and the first tuning slab 263a can have a first x/y plane offset (y₁ₐ) associated therewith. For example, the first x/y plane offset (y₁ₐ) can be established relative to a cavity wall, can be wavelength-dependent, and can vary from about (λ/4) to about (10λ). The first control assembly 262a can have a cylindrical configuration and a diameter (d₂ₐ) that can vary from about 1 mm to about 5 mm. The first tuning slab 263a can have diameters (D₂ₐ) associated therewith, which can vary from about 1 mm to about 10 mm.

Referring still to FIG. 2A, a second portion of a second plasma-tuning rod 270b is shown extending into the second isolated tuning space 273b established in the second protection assembly 274b at a second x/y plane location (y_{2b}) in the process space 215, and a first portion of the second plasma-tuning rod 270b is shown extending into the second EM energy tuning space 268b in the second resonant cavity 269b at the second x/y plane location (y_{2b}). A second isolation assembly 266b can be used to position and move 272b the second plasma-tuning rod 270b the second plasma-tuning distances 272b within the second isolated tuning space 273b established in the second protection assembly 274b. For example, the second plasma-tuning distance 272b can vary from about 0.10 mm to about 1 mm, and the second plasma-tuning distance 272b can be wavelength-dependent and can vary from about (λ/40) to about (10λ).

A second coupling region 265b can be established at a first coupling distance (x_{1b}) from one or more of the walls of the second resonant cavity 269b, and the second portion of the second plasma-tuning rod 270b can extend into the second coupling region 265b. The first portion of the second plasma-tuning rod 270b can obtain second tunable EM energy from the second coupling region 265b, and the second EM energy can be transferred to the process space 215 at the second x/y plane locations (y_{1b}) using the second portion of the second plasma-tuning rod 270b. The second coupling region 265b can include a tunable E-field region, a tunable H-field region, a maximum field region, a maximum voltage region, maximum energy region, or a maximum current region, or any combination thereof. For example, the first coupling distance (x_{1b}) can vary from about 0.01 mm to about 10 mm, and the first coupling distance (x_{1b}) can be wavelength-dependent and can vary from about (λ/4) to about (10λ).

A second control assembly 262b can be coupled to a second tuning slab 263b and can be used to move 264b the second tuning slab 263b a second cavity-tuning distance (x_{2b}) relative to the second portion of the second plasma-tuning rod 270b within the second EM energy tuning space 268b in the second resonant cavity 269b. The second control assembly 262b and the second tuning slab 263b can be used to optimize the second EM energy coupled from the second coupling region 265b to the first portion of the second plasma-tuning rod 270b. For example, the second cavity-tuning distance (x_{2b}) can vary from about 0.01 mm to about 1 mm.

The controller 295 can be coupled 296 to the second control assembly 262b and can control the second cavity-tuning distance (x_{2b}) using the second control assembly 262b, and the controller 295 can use process recipes to establish, control, and optimize the second cavity-tuning distance (x_{2b}) in real-time to control the plasma uniformity within the process space 215. Alternatively, the controller 295 may independently control the second movements 271b of the second plasma-tuning rod 270b in real-time to control the second tunable EM energy and the plasma uniformity within the process space 215.

The second plasma-tuning rod 270b can have a second diameter (d_{1b}) associated therewith, and the second diameter (d_{1b}) can vary from about 0.01 mm to about 1 mm. The second protection assembly 274b can have a diameter (D_{1b}) associated therewith, and the diameter (D_{1b}) can vary from about 1 mm to about 10 mm.

The second portion of the second plasma-tuning rod 270b, the second coupling region 265b, the second control assembly 262b, and the second tuning slab 263b can have a second x/y plane offset (y_{1b}) associated therewith. For example, the second x/y plane offset (y_{1b}) can be established relative to a cavity wall, can be wavelength-dependent, and can vary from about (λ/4) to about (10λ). The second control assembly 262b can have a cylindrical configuration and diameters (d_{2b}) that can vary from about 1 mm to about 5 mm. The second tuning slab 263b can have diameters (D_{2b}) associated therewith, and the diameter (D_{2b}) can vary from about 1 mm to about 10 mm.

The isolation assemblies (266a and 266b) can be coupled (not shown) to the controller 295, and the controller 295 can use process recipes to establish, control, and optimize the plasma-tuning distances (272a and 272b) and the tuning rod movements (271a and 271b) to control the plasma uniformity within the process space 215.

In some embodiments, the second SWA processing system 200 can be configured to form plasma in the process space 215 as the substrate holder 220 and the substrate are moved through the process space 215. In other embodiments, the second SWA processing system 200 can be configured to form plasma in the process space 215 as the substrate holder 220 and the substrate are positioned within the process space 215.

Referring still to the front view, a controller 295 is shown coupled 296 to the EM source 290, the match network/phase shifter 291, and the tuner network/isolator 292, and the controller 295 can use process recipes to establish, control, and optimize the EM source 290, the match network/phase shifter 291, and the tuner network/isolator 292 to control the plasma uniformity within the process space 215. For example, the EM source 290 can operate at frequencies from about 500 MHz to about 5000 MHz, and the controller 295 can optimize the operating frequencies in real-time. In addition, the controller 295 can be coupled 296 to the process sensors 207, and the controller 295 can use process recipes to establish, control, and optimize the data from the process sensors 207 to control the plasma uniformity within the process space 215.

The controller 295 can be coupled 296 to the first coupling (matching) network 293a and to the second coupling (matching) network 293b when they are present. The controller 295 can use process recipes to establish, control, and optimize the first coupling (matching) network 293a and the second coupling (matching) network 293b when they are present, to control the plasma uniformity within the process space 215. For example, first coupling (matching) network 293a and the second coupling (matching) network 293b, when they are present, can operate at frequencies from about 500 MHz to about 5000 MHz. In addition, the controller 295 can be coupled 296 to the resonant cavities (269a and 269b), and the controller 295 can use process recipes to establish, tune, control, and optimize the data from the resonant cavities (269a and 269b), to control the plasma uniformity within the process space 215.

Some of the second SWA processing systems 200 can include a pressure control system 225 and exhaust port 226 coupled to the second process chamber 210, and configured to evacuate the second process chamber 210, as well as control the pressure within the second process chamber 210. Alternatively, the pressure control system 225 and/or the exhaust port 226 may not be required.

As shown in FIG. 2A, the second SWA processing system 200 can comprise a first gas supply system 280 coupled to one or more first flow elements 281 that can be coupled to the second process chamber 210. The first flow elements 281 can be configured to introduce a first process gas to process space 215, and can include flow control and/or flow measuring devices. In addition, the second SWA processing system 200 can comprise a second gas supply system 282 coupled to one or more second flow elements 283 that can be coupled to the second process chamber 210. The second flow elements 283 can be configured to introduce a second process gas to process space 215, and can include flow control and/or flow measuring devices. Alternatively, the second gas supply system 282 and/or the second flow elements 283 may not be required.

During dry plasma etching, the process gas may comprise an etchant, a passivant, or an inert gas, or a combination of two or more thereof. For example, when plasma etching a dielectric film such as silicon oxide (SiOₓ) or silicon nitride (SiₓN_{y}), the plasma etch gas composition generally includes a fluorocarbon-based chemistry (CₓF_{y}) such as at least one of C₄F₈, C₅F₈, C₃F₆, C₄F₆, CF₄, etc., and/or may include a fluorohydrocarbon-based chemistry (CₓH_{y}F_{z}) such as at least one of CHF₃, CH₂F₂, etc., and can have at least one of an inert gas, oxygen, CO or CO₂. Additionally, for example, when etching polycrystalline silicon (poliesilicon), the plasma etch gas composition generally includes a halogen-containing gas such as HBr, Cl₂, NF₃, or SF₆ or a combination of two or more thereof, and may include fluorohydrocarbon-based chemistry (CₓH_{y}F_{z}) such as at least one of CHF₃, CH₂F₂, etc., and at least one of an inert gas, oxygen, CO or CO₂, or two or more thereof. During plasma-enhanced deposition, the process gas may comprise a film forming precursor, a reduction gas, or an inert gas, or a combination of two or more thereof.

FIG. 2B illustrates a simplified partial bottom view of a cover plate 260 in the second SWA plasma source 250 in accordance with embodiments of the invention. The cover plate 260 can have a total length (x_{T}) and a total width (z_{T}) associated therewith in an x/z plane. For example, the total length (x_{T}) can vary from about 10 mm to about 1000 mm, and the total width (z_{T}) can vary from about 10 mm to about 1000 mm.

The partial bottom view of cover plate 260 in the second SWA plasma source 250 includes a bottom (dotted line) view of a first plasma-tuning rod 270a that is shown surrounded by a bottom (dash line) view of the first isolated tuning space 273a, and the bottom view of a first isolated tuning space 273a is shown surrounded by a bottom view of the first protection assembly 274a.

As shown in FIG. 2B, the first plasma-tuning rod 270a can have first diameters (d₁ₐ) associated therewith, and the first diameters (d₁ₐ) can vary from about 0.01 mm to about 1 mm. The first portion of the first plasma-tuning rod 270a can have first lengths (x₁ₐ) associated therewith, and the first lengths (x₁ₐ) can vary from about 0.1 mm to about 1 mm. The second portion of the first plasma-tuning rod 270a can have second lengths (x₃ₐ) associated therewith, and the second lengths (x₃ₐ) can vary from about 1 mm to about 100 mm. The first protection assembly 274a can have first diameters (D₁ₐ) associated therewith, and the first diameters (D₁ₐ) can vary from about 1 mm to about 10 mm. The first protection assembly 274a can have lengths (x₄ₐ) associated therewith, and the lengths (x₄ₐ) can vary from about 1 mm to about 200 mm.

The second portion of the plasma-tuning rod 270a, the first isolated tuning space 273a, and the first protection assembly 274a can have first x/z plane offsets (z₁ₐ) associated therewith, and the first x/z plane offsets (z₁ₐ) can vary from about 2 mm to about 1000 mm. Alternatively, the second portion of the plasma-tuning rod 270a, the first isolated tuning space 273a, and the first protection assembly 274a may have different first x/z plane offsets (z₁ₐ) associated therewith. The first portion of the plasma-tuning rod 270a, the first tuning slab 263a, and the first control assembly 262a can have second x/z plane offsets (z₂ₐ) associated therewith, and the second x/z plane offsets (z₂ₐ) can vary from about 1 mm to about 10 mm. Alternatively, the first portion of the plasma-tuning rod 270a, the first tuning slab 263a, and the first control assembly 262a may have different first x/z plane offsets (z₁ₐ) associated therewith.

The partial bottom view of cover plate 260 in the second SWA plasma source 250 includes a bottom (dotted line) view of a second plasma-tuning rod 270b that is shown surrounded by a bottom (dash line) view of the second isolated tuning space 273b, and the bottom view of a second isolated tuning space 273b is shown surrounded by a bottom view of the second protection assembly 274b.

As shown in FIG. 2B, the second plasma-tuning rod 270b can have second diameters (d_{1b}) associated therewith, and the second diameters (d_{1b}) can vary from about 0.01 mm to about 1 mm. The first portion of the second plasma-tuning rod 270b can have first lengths (x_{1b}) associated therewith, and the first lengths (x_{1b}) can vary from about 0.1 mm to about 1 mm. The second portion of the second plasma-tuning rod 270b can have second lengths (x_{3b}) associated therewith, and the second lengths (x_{3b}) can vary from about 1 mm to about 100 mm. The second protection assembly 274b can have second diameters (D_{1b}) associated therewith, and the second diameters (D_{1b}) can vary from about 1 mm to about 10 mm. The second protection assembly 274b can have lengths (x_{4b}) associated therewith, and the lengths (x_{4b}) can vary from about 1 mm to about 200 mm.

The second portion of the second plasma-tuning rod 270b, the second isolated tuning space 273b, and the second protection assembly 274b can have second x/z plane offsets (z_{1b}) associated therewith, and the second x/z plane offsets (z_{1b}) can vary from about 2 mm to about 1000 mm. Alternatively, the second portion of the second plasma-tuning rod 270b, the second isolated tuning space 273b, and the second protection assembly 274b may have different second x/z plane offsets (z_{1b}) associated therewith. The first portion of the second plasma-tuning rod 270b, the second tuning slab 263b, and the second control assembly 262b can have second x/z plane offsets (z_{2b}) associated therewith, and the second x/z plane offsets (z_{2b}) can vary from about 1 mm to about 10 mm. Alternatively, the first portion of the second plasma-tuning rod 270b, the second tuning slab 263b, and the second control assembly 262b may have different second x/z plane offsets (z_{1b}) associated therewith.

FIG. 2B illustrates that in some embodiments, the second EM source 290 can include a partial bottom view of a first resonant cavity 269a coupled to a partial bottom view of a chamber wall 212a and can include a partial bottom view of a second resonant cavity 269b coupled to a partial bottom view of another chamber wall 212b.

The bottom view shows that a second portion of the first plasma-tuning rod 270a can extend into the first isolated tuning space 273a established in the first protection assembly 274a at a first x/z plane location (z₁ₐ) in the process space 315, and a first portion of the first plasma-tuning rod 270a can also extend into the first resonant cavity 269a at the second x/z plane location (z₂ₐ). A first isolation assembly 266a can be used to position and move 271a the first plasma-tuning rod 270a the first plasma-tuning distances 272a within the first isolated tuning space 273a established in the first protection assembly 274a. For example, the first plasma-tuning distance 272a can vary from about 0.10 mm to about 1 mm, and the first plasma-tuning distance 272a can be wavelength-dependent and can vary from about (λ/40) to about (10λ).

FIG. 2B shows that a first coupling region 265a can be established at a first x/z plane coupling distance (z₂ₐ) from one or more of the walls of the first resonant cavity 269a, and the first portion of the first plasma-tuning rod 270a can extend into the first coupling region 265a in the first EM energy tuning space 268a in the first resonant cavity 269a. The first portion of the first plasma-tuning rod 270a can obtain first tunable EM energy from the first coupling region 265a, and the first EM energy can be transferred to the process space 215 at the first x/z plane location (z₁ₐ) using the second portion of the first plasma-tuning rod 270a. The first coupling region 265a can include a tunable E-field region, a tunable H-field region, a maximum field region, a maximum voltage region, maximum energy region, or a maximum current region, or any combination thereof. The first coupling distance (x₁ₑ) can vary from about 0.01 mm to about 10 mm, and the first coupling distance (x₁ₑ) can be wavelength-dependent and can vary from about (λ/4) to about (10λ).

A first tuning slab 263a can be coupled to a first control assembly 262a and can be used to move 264a the first tuning slab 263a a first cavity-tuning distance (x₂ₐ) relative to the first portion of the first plasma-tuning rod 270a within the first EM energy tuning space 268a in the first resonant cavity 269a. The first control assembly 262a and the first tuning slab 263a can be used to optimize the first EM energy coupled from the first coupling region 265a to the second portion of the first plasma-tuning rod 270a. For example, the first cavity-tuning distance (x₂ₐ) can vary from about 0.01 mm to about 1 mm.

The first control assembly 262a can have lengths (x₅ₑ) associated therewith, and the lengths (x₅ₑ) can vary from about 1 mm to about 10 mm. The first tuning slab 263a can have thicknesses (x₆ₑ) associated therewith, and the thicknesses (x₆ₑ) can vary from about 0.01 mm to about 1 mm. The first resonant cavity 269a can have lengths (x₇ₑ) associated therewith, and the lengths (x₇ₑ) can vary from about 2 mm to about 20 mm. The first resonant cavity 269a can have widths (z₃ₑ) associated therewith, and the widths (z₃ₑ) can vary from about 2 mm to about 20 mm. For example, the first cavity x/z plane offset (z₄ₑ) can be established relative to one or more edges of the cover plate 260, can be wavelength-dependent, and can vary from about (λ/4) to about (10λ).

The first plasma-tuning rod 270a can have a diameter (d₁ₐ) associated therewith, and the diameter (d₁ₐ) can vary from about 0.01 mm to about 1 mm. The first protection assembly 274a and the first isolation assembly 266a can have first diameters (D₁ₐ) associated therewith, and the first diameters (D₁ₐ) can vary from about 1 mm to about 10 mm.

The second portion of the first plasma-tuning rod 270a, the first coupling region 265a, the first control assembly 262a, and the first tuning slab 263a can have first x/z plane offset (z₁ₐ) associated therewith. For example, the first x/z plane offset (z₁ₐ) can be established relative to one or more edges of the cover plate 260, can be wavelength-dependent, and can vary from about (λ/4) to about (10λ). The first control assembly 262a can have a cylindrical configuration and diameters (d₂ₑ) that can vary from about 1 mm to about 5 mm. The first tuning slab 263a can be circular and can have diameters (D₂ₐ) associated therewith, and the diameters (D₂ₐ) can vary from about 1 mm to about 10 mm.

Still referring to FIG. 2B, the bottom view shows that a second portion of the second plasma-tuning rod 270b can extend into the second isolated tuning space 273b established in the second protection assembly 274b at a second x/z plane location (z_{2b}) in the process space 215, and a second portion of the second plasma-tuning rod 270b can also extend into the second EM energy tuning space 268b in the second resonant cavity 269b at the second x/z plane location (z_{1b}). A second isolation assembly 266b can be used to position and move 271b the second plasma-tuning rod 270b the second plasma-tuning distances 272b within the second isolated tuning space 273b established in the second protection assembly 274b. The second plasma-tuning distance 272b can vary from about 0.10 mm to about 1 mm, and the second plasma-tuning distance 272b can be wavelength-dependent and can vary from about (λ/40) to about (10λ).

FIG. 2B shows that a second coupling region 265b can be established at a first x/z plane coupling distance (z_{2b}) from one or more of the walls of the second resonant cavity 269b, and the first portion of the second plasma-tuning rod 270b can extend into the second coupling region 265b in the second EM energy tuning space 268b in the second resonant cavity 269b. The first portion of the second plasma-tuning rod can obtain second tunable EM energy from the second coupling region 265b, and the second EM energy can be transferred to the process space 215 at the second x/z plane location (z_{2b}) using the second portion of the second plasma-tuning rod 270b. The second coupling region 265b can include a tunable E-field region, a tunable H-field region, a maximum field region, a maximum voltage region, maximum energy region, or a maximum current region, or any combination thereof. For example, the first coupling distance (x₁ₑ) can vary from about 0.01 mm to about 10 mm, and the first coupling distance (x₁ₑ) can be wavelength-dependent and can vary from about (λ/4) to about (10λ).

A second tuning slab 263b can be coupled to a second control assembly 262b and can be used to move 264b the second tuning slab 263b a second cavity-tuning distance (x_{4b}) relative to the first portion of the second plasma-tuning rod 270b within the second EM energy tuning space 268b in the second resonant cavity 269b. The second control assembly 262b and the second tuning slab 263b can be used to optimize the EM energy coupled from the second coupling region 265b to the second portion of the second plasma-tuning rod 270b. For example, the second cavity-tuning distance (x_{4b}) can vary from about 0.01 mm to about 1 mm.

The second control assembly 262b can have lengths (x_{5b}) associated therewith, and the lengths (x_{5b}) can vary from about 1 mm to about 10 mm. The second tuning slab 263b can have thicknesses (x_{6b}) associated therewith, and the thicknesses (x_{6b}) can vary from about 0.01 mm to about 1 mm. The second resonant cavity 269b can have lengths (x_{7b}) associated therewith, and the lengths (x_{7b}) can vary from about 2 mm to about 20 mm. The second resonant cavity 269b can have widths (z_{3b}) associated therewith, and the widths (z_{3b}) can vary from about 2 mm to about 20 mm. For example, the second cavity x/z plane offset (z_{4b}) can be established relative to one or more edges of the cover plate 260, can be wavelength-dependent, and can vary from about (λ/4) to about (10λ).

The second plasma-tuning rod 270b can have a diameter (d_{1b}) associated therewith, and the diameter (d_{1b}) can vary from about 0.01 mm to about 1 mm. The second isolation assembly 274b and the second isolation assembly 266b can have second diameters (D_{1b}) associated therewith, which can vary from about 1 mm to about 10 mm.

The second portion of the second plasma-tuning rod 270b, the second coupling region 265b, the second control assembly 262b, and the second tuning slab 263b can have second x/z plane offset (z_{1b}) associated therewith. For example, the second x/z plane offset (z_{1b}) can be established relative to one or more edges of the cover plate 260, can be wavelength-dependent, and can vary from about (λ/4) to about (10λ). The second control assembly 262b can have a cylindrical configuration and diameters (d_{2b}) that can vary from about 1 mm to about 5 mm. The second tuning slab 263b can be circular and can have diameters (D_{2b}) associated therewith, and the diameters (D_{2b}) can vary from about 1 mm to about 10 mm.

FIG. 2C illustrates a side view of a second SWA processing system in accordance with embodiments of the invention. The second SWA processing system 200 can comprise a second SWA plasma source 250 having a slot antenna 246 therein. For example, the second SWA processing system 200 can comprise a dry plasma etching system or a plasma enhanced deposition system.

The second SWA processing system 200 can comprise a second process chamber 210 configured to define a process space 215. The side view shows a y/z plane view of a second process chamber 210 that can be configured using a cover plate 260 and a plurality of chamber walls (212, 212a, and 212b) coupled to each other and to the cover plate 260. For example, the chamber walls (212, 212a, and 212b) can have wall thicknesses (t) associated therewith, and the wall thicknesses (t) can vary from about 1 mm to about 5 mm. The cover plate 260 have a first cover plate thickness associated therewith, and the cover plate thickness can vary from about 1 mm to about 10 mm.

The second process chamber 210 can comprise a substrate holder 220 configured to support a substrate 205. The substrate 205 can be exposed to plasma and/or process chemistry in process space 215. The second SWA processing system 200 can comprise a second SWA plasma source 250 coupled to the second process chamber 210, and configured to form uniform plasma in the process space 215.

In some embodiments, one or more EM sources 290 can be coupled to the second SWA plasma source 250, and the EM energy generated by the EM source 290 can flow through a match network/phase shifter 291 to a tuner network/isolator 292 for absorbing EM energy reflected back to the EM source 290. The EM energy can be converted to a TEM (transverse electromagnetic) mode via the tuner network/isolator 292. A tuner may be employed for impedance matching, and improved power transfer. For example, the EM source 290, the match network/phase shifter 291, and the tuner network/isolator 292 can operate from about 500 MHz to about 5000 MHz.

In other embodiments, the second EM source 290 can be coupled to a first resonant cavity 269a and a second resonant cavity 269b. Alternatively, one or more separate EM sources (not shown) may be coupled to the first resonant cavity 269a and/or to the second resonant cavity 269b. For example, the tuner network/isolator 292 can be coupled to a first coupling (matching) network 293a and to a second coupling (matching) network 293b. Alternatively, a plurality of EM sources (not shown) or a plurality of coupling networks (not shown) may be used. The first coupling (matching) network 293a can be removably coupled to a first resonant cavity 269a and can be used to provide first EM energy to the first resonant cavity 269a. The second coupling (matching) network 293b can be removably coupled to the second resonant cavity 269b and can be used to provide second EM energy to the second resonant cavity 269b. Alternatively, other coupling configurations may be used.

The second SWA plasma source 250 can comprise a feed assembly 240 having an inner conductor 241, an outer conductor 242, an insulator 243, and a slot antenna 246 having a plurality of first slots 248 and a plurality of second slots 249 coupled between the inner conductor 241 and the outer conductor 242. The plurality of slots (248 and 249) permit the coupling of EM energy from a first region above the slot antenna 246 to a second region below the slot antenna 246. The design of the slot antenna 246 in the y/z plane can be used to control the spatial uniformity of the plasma in process space 215. For example, the number, geometry, size, and distribution of the slots (248, and 249) are all factors that can contribute to the spatial uniformity of the plasma formed in the process space 215.

Some exemplary second SWA plasma sources 250 can comprise a slow wave plate 244, and the design of the slow wave plate 244 in the y/z plane can be used to control the spatial uniformity of the plasma in process space 215. For example, the geometry, size, and plate material can be factors that can contribute to the spatial uniformity of the plasma formed in the process space 215. Alternatively, the slow wave plate 244 may be configured differently or may not be required.

Other exemplary second SWA plasma sources 250 can comprise a resonator plate 252, and the design of the resonator plate 252 in the y/z plane can be used to control the spatial uniformity of the plasma in process space 215. For example, the geometry, size, and the resonator plate material can be factors that can contribute to the spatial uniformity of the plasma formed in the process space 215. Alternatively, the resonator plate 252 may be configured differently or may not be required.

Still other exemplary second SWA plasma sources 250 can comprise a cover plate 260 configured to protect the resonator plate 252, and the design of the cover plate 260 in the y/z plane can be used to control the spatial uniformity of the plasma in process space 215. For example, the geometry, size, and the cover plate material can be factors that can contribute to the spatial uniformity of the plasma formed in the process space 215. Alternatively, the cover plate 260 may be configured differently or may not be required.

Other additional exemplary second SWA plasma sources 250 can comprise one or more fluid channels 256 that can be configured to flow a temperature control fluid for temperature control of the second SWA plasma source 250. The design of the fluid channels 256 can be used to control the spatial uniformity of the plasma in process space 215. For example, the geometry, size, and flow rate of the fluid channels 256 can be factors that can contribute to the spatial uniformity of the plasma formed in the process space 215. Alternatively, the fluid channels 256 may be configured differently or may not be required.

The EM energy can be coupled to the second SWA plasma source 250 via the feed assembly 240, and mode changes can occur in the feed assembly 240. Additional details regarding the design of the feed assembly 240 and the slot antenna 246 can be found in U.S. Pat. No. 5,024,716, entitled “Plasma processing apparatus for etching, ashing, and film-formation”; the content of which is herein incorporated by reference in its entirety.

The side view illustrates that the second SWA processing system 200 can comprise a plurality of plasma-tuning rods (270a and 270b) and a plurality of protection assemblies (274a and 274b) that can be coupled to a plurality of isolation assemblies (266a and 266b). For example, the plasma-tuning rods (270a and 270b) and the protection assemblies (274a and 274b) can comprise dielectric materials, such as quartz. Alternatively, the plasma-tuning rods (270a and 270b) and the protection assemblies (274a and 274b) may comprise semiconductor or metallic materials. In addition, the isolation assemblies (266a and 266b) can include isolation and movement devices (not shown) and the isolation assemblies (266a and 266b) may comprise dielectric, semiconductor, and/or metallic materials.

The design of the plasma-tuning rods (270a and 270b) and the protection assemblies (274a and 274b) can be used to control the spatial uniformity of the plasma in process space 215. For example, the geometry, size, and material of the plasma-tuning rods (270a and 270b) and/or the protection assemblies (274a and 274b) can be factors that can contribute to the spatial uniformity of the plasma formed in the process space 215. Alternatively, the plasma-tuning rods (270a and 270b) or the protection assemblies (274a and 274b) may be configured differently or may not be required.

Still referring to FIG. 2C, the side view of the second SWA processing system 200 shows a side (dotted line) view of a first plasma-tuning rod 270a that is shown surrounded by a side (dotted line) view of the first protection assembly 274a, and the side view of the first protection assembly 274a is shown surrounded by a side view of the first tuning slab 263a.

The first plasma-tuning rod 270a can have diameters (d₁ₐ) associated therewith, and the diameters (d₁ₐ) can vary from about 0.01 mm to about 1 mm. The first isolation protection 274a can have diameters (D₁ₐ) associated therewith, and the diameters (D₁ₐ) can vary from about 1 mm to about 10 mm.

The first control assembly 262a can have a cylindrical configuration and a diameter (d₂ₐ) that can vary from about 1 mm to about 5 mm. The first tuning slab 263a can have diameters (D₂ₐ) associated therewith, which can vary from about 1 mm to about 10 mm.

The side view of the second SWA processing system 200 shows a side view (dotted line) of a second plasma-tuning rod 270b that is shown surrounded by a side (dotted line) view of the second protection assembly 274b, and the side view of the second protection assembly 274b is shown surrounded by a side view of the second tuning slab 263b.

The second plasma-tuning rod 270b can have diameters (d_{1b}) associated therewith, and the diameters (d_{1b}) can vary from about 0.01 mm to about 1 mm. The second protection assembly 274b can have diameters (D_{1b}) associated therewith, and the diameters (D_{1b}) can vary from about 1 mm to about 10 mm.

The second control assembly 262b can have a cylindrical configuration and a diameter (d_{2b}) that can vary from about 1 mm to about 5 mm. The second tuning slab 263b can have diameters (D_{2b}) associated therewith, and the diameter (D_{2b}) can vary from about 1 mm to about 10 mm.

In some embodiments, the second SWA processing system 200 can be configured to form plasma in the process space 215 as the substrate holder 220 and the substrate are moved through the process space 215. In other embodiments, the second SWA processing system 200 can be configured to form plasma in the process space 215 as the substrate holder 220 and the substrate are positioned within the process space 215.

Referring still to the y/z plane view, a controller 295 is shown coupled 296 to the EM source 290, the match network/phase shifter 291, and the tuner network/isolator 292, and the controller 295 can use process recipes to establish, control, and optimize the EM source 290, the match network/phase shifter 291, and the tuner network/isolator 292 to control the plasma uniformity within the process space 215. For example, the EM source 290 can operate at frequencies from about 500 MHz to about 5000 MHz, and the controller 295 can optimize the operating frequencies in real-time. In addition, the controller 295 can be coupled 296 to the resonant cavities (269a and 269b), the process sensors 207, and the controller 295 can use process recipes to establish, control, and optimize the data from the resonant cavities (269a and 269b), process sensors 207 to control the plasma uniformity within the process space 215.

The controller 295 can be coupled 296 to the first coupling (matching) network 293a and to the second coupling (matching) network 293b when they are present. The controller 295 can use process recipes to establish, control, and optimize the first coupling (matching) network 293a and the second coupling (matching) network 293b when they are present, to control the plasma uniformity within the process space 215. For example, first coupling (matching) network 293a and the second coupling (matching) network 293b, when they are present, can operate at frequencies from about 500 MHz to about 5000 MHz. In addition, the controller 295 can be coupled 296 to the resonant cavities (269a and 269b), and the controller 295 can use process recipes to establish, tune, control, and optimize the data from the resonant cavities (269a and 269b), to control the plasma uniformity within the process space 215.

Some of the second SWA processing systems 200 can include a pressure control system 225 and exhaust port 226 coupled to the second process chamber 210, and configured to evacuate the second process chamber 210, as well as control the pressure within the second process chamber 210. Alternatively, the pressure control system 225 and/or the exhaust port 226 may not be required.

As shown in FIG. 2C, the second SWA processing system 200 can comprise a first gas supply system 280 coupled to one or more first flow elements 281 that can be coupled to the second process chamber 210. The first flow elements 281 can be configured to introduce a first process gas to process space 215, and can include flow control and/or flow measuring devices. In addition, the second SWA processing system 200 can comprise a second gas supply system 282 coupled to one or more second flow elements 283 that can be coupled to the second process chamber 210. The second flow elements 283 can be configured to introduce a second process gas to process space 215, and can include flow control and/or flow measuring devices. Alternatively, the second gas supply system 282 and/or the second flow elements 283 may not be required.

During dry plasma etching, the process gas may comprise an etchant, a passivant, or an inert gas, or a combination of two or more thereof. For example, when plasma etching a dielectric film such as silicon oxide (SiOₓ) or silicon nitride (SiₓN_{y}), the plasma etch gas composition generally includes a fluorocarbon-based chemistry (CₓF_{y}) such as at least one of C₄F₈, C₅F₈, C₃F₆, C₄F₆, CF₄, etc., and/or may include a fluorohydrocarbon-based chemistry (CₓH_{y}F_{z}) such as at least one of CHF₃, CH₂F₂, etc., and can have at least one of an inert gas, oxygen, CO or CO₂. Additionally, for example, when etching polycrystalline silicon (poliesilicon), the plasma etch gas composition generally includes a halogen-containing gas such as HBr, Cl₂, NF₃, or SF₆ or a combination of two or more thereof, and may include fluorohydrocarbon-based chemistry (CₓH_{y}F_{z}) such as at least one of CHF₃, CH₂F₂, etc., and at least one of an inert gas, oxygen, CO or CO₂, or two or more thereof. During plasma-enhanced deposition, the process gas may comprise a film forming precursor, a reduction gas, or an inert gas, or a combination of two or more thereof.

With reference to FIG. 2A and FIG. 2C, various views of a substrate holder 220, and a lower electrode 221 are shown. When present, the lower electrode 221 can be used to couple Radio Frequency (RF) power to plasma in process space 215. For example, lower electrode 221 can be electrically biased at an RF voltage via the transmission of RF power from RF generator 230 through impedance match network 232 and RF sensor 235 to lower electrode 221. The RF bias can serve to heat electrons to form and/or maintain the uniform plasma. A typical frequency for the RF bias can range from about 1 MHz to about 100 MHz. Alternatively, RF power may be applied to the lower electrode 221 at multiple frequencies. Furthermore, impedance match network 232 can serve to maximize the transfer of RF power to the plasma in second process chamber 210 by minimizing the reflected power. Various match network topologies and automatic control methods can be utilized. The RF sensor 335 can measure the power levels and/or frequencies associated with the fundamental signals, harmonic signals, and/or intermodulation signals. In addition, the controller 295 can be coupled 296 to the RF generator 230, the impedance match network 232, and the RF sensor 235, and the controller 295 can use process recipes to establish, control, and optimize the data to and from the RF generator 230, the impedance match network 232, and the RF sensor 235 to control the plasma uniformity within the process space 215.

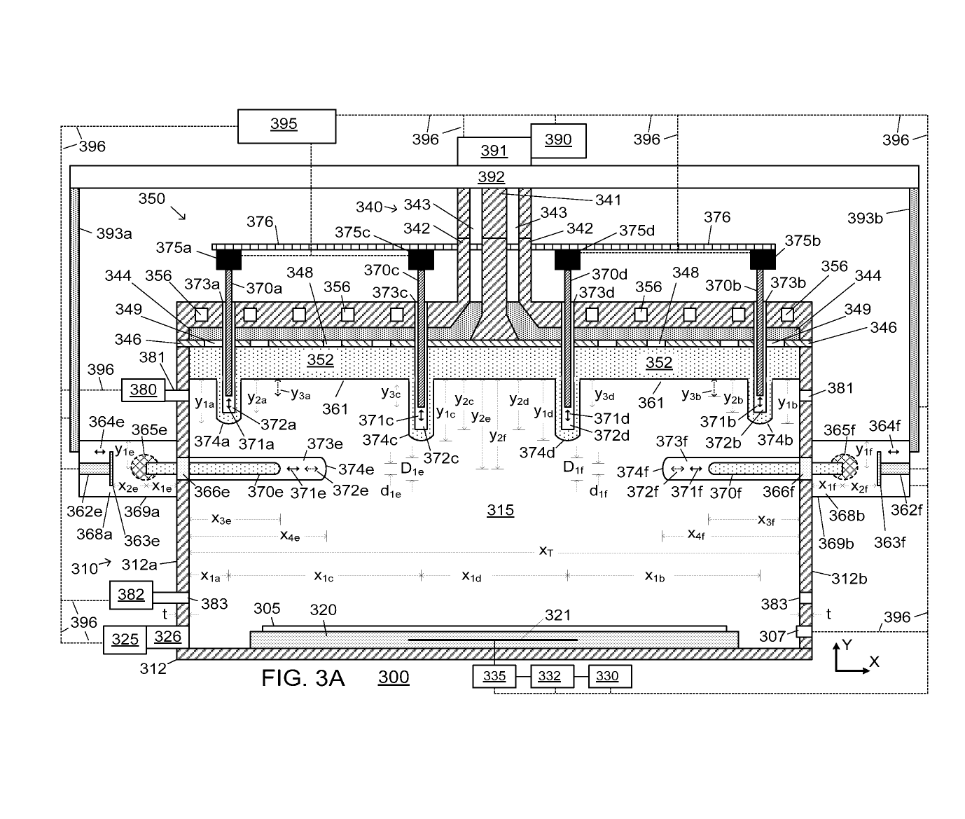

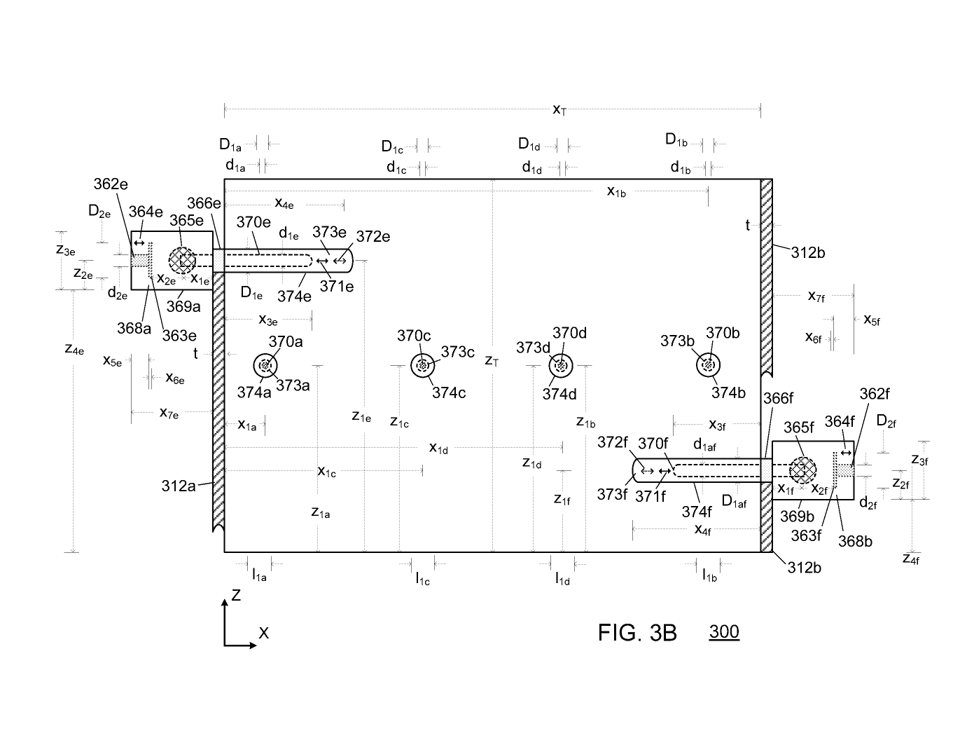

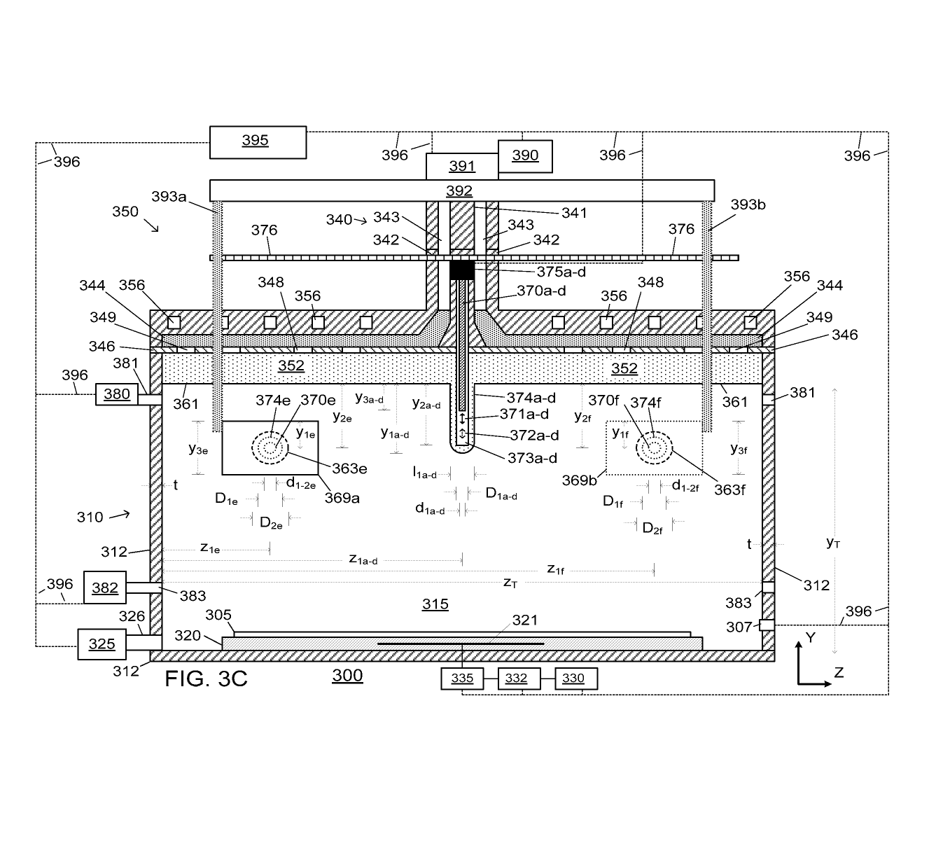

FIG. 3A illustrates a front view of a third SWA processing system in accordance with embodiments of the invention. The third SWA processing system 300 can comprise a third SWA plasma source 350 having a slot antenna 346 therein. For example, the third SWA processing system 300 can comprise a dry plasma etching system or a plasma enhanced deposition system.

The third SWA processing system 300 can comprise a third process chamber 310 configured to define a process space 315. The front view shows an x/y plane view of a third process chamber 310 that can be configured using a resonator plate 352 and a plurality of chamber walls 312 coupled to each other and the resonator plate 352. For example, the chamber walls 312 can have wall thicknesses (t) associated therewith, and the wall thicknesses (t) can vary from about 1 mm to about 5 mm. Alternatively, a cover plate (not shown) may be used.

The third process chamber 310 can comprise a substrate holder 320 configured to support a substrate 305. The substrate 305 can be exposed to plasma and/or process chemistry in process space 315. The third SWA processing system 300 can comprise a third SWA plasma source 350 coupled to the third process chamber 310, and configured to form plasma in the process space 315.

In some embodiments, one or more EM sources 390 can be coupled to the third SWA plasma source 350, and the EM energy generated by the EM source 390 can flow through a match network/phase shifter 391 to a tuner network/isolator 392 for absorbing EM energy reflected back to the EM source 390. The EM energy can be converted to a TEM (transverse electromagnetic) mode via the tuner network/isolator 392. A tuner may be employed for impedance matching, and improved power transfer. For example, the EM source 390, the match network/phase shifter 391, and the tuner network/isolator 392 can operate from about 500 MHz to about 5000 MHz.

In other embodiments, the third EM source 390 can be coupled to a first resonant cavity 369a and a second resonant cavity 369b. Alternatively, one or more separate EM sources (not shown) may be coupled to the first resonant cavity 369a and/or to the second resonant cavity 369b. For example, the tuner network/isolator 392 can be coupled to a first coupling (matching) network 393a and to a second coupling (matching) network 393b. Alternatively, a plurality of EM sources (not shown) or a plurality of coupling networks (not shown) may be used. The first coupling (matching) network 393a can be removably coupled to a first resonant cavity 369a and can be used to provide first EM energy to the first resonant cavity 369a. The second coupling (matching) network 393b can be removably coupled to the second resonant cavity 369b and can be used to provide second EM energy to the second resonant cavity 369b. Alternatively, other coupling configurations may be used.

The third SWA plasma source 350 can comprise a feed assembly 340 having an inner conductor 341, an outer conductor 342, an insulator 343, and a slot antenna 346 having a plurality of first slots 348 and a plurality of second slots 349 coupled between the inner conductor 341 and the outer conductor 342. The plurality of slots (348 and 349) permit the coupling of EM energy from a first region above the slot antenna 346 to a second region below the slot antenna 346. The design of the slot antenna 346 can be used to control the spatial uniformity of the plasma in process space 315. For example, the number, geometry, size, and distribution of the slots (348, and 349) are all factors that can contribute to the spatial uniformity of the plasma formed in the process space 315.

Some exemplary third SWA plasma sources 350 can comprise a slow wave plate 344, and the design of the slow wave plate 344 can be used to control the spatial uniformity of the plasma in process space 315. For example, the geometry, size, and plate material can be factors that can contribute to the spatial uniformity of the plasma formed in the process space 315. Alternatively, the slow wave plate 344 may be configured differently or may not be required.

Other exemplary third SWA plasma sources 350 can comprise a resonator plate 352, and the design of the resonator plate 352 can be used to control the spatial uniformity of the plasma in process space 315. For example, the geometry, size, and the resonator plate material can be factors that can contribute to the spatial uniformity of the plasma formed in the process space 315. Alternatively, the resonator plate 352 may be configured differently or may not be required.

Other additional exemplary third SWA plasma sources 350 can comprise one or more fluid channels 356 that can be configured to flow a temperature control fluid for temperature control of the third SWA plasma source 350. The design of the fluid channels 356 can be used to control the spatial uniformity of the plasma in process space 315. For example, the geometry, size, and flow rate of the fluid channels 356 can be factors that can contribute to the spatial uniformity of the plasma formed in the process space 315. Alternatively, the fluid channels 356 may be configured differently or may not be required.

The EM energy can be coupled to the third SWA plasma source 350 via the feed assembly 340, and mode changes can occur in the feed assembly 340. Additional details regarding the design of the feed assembly 340 and the slot antenna 346 can be found in U.S. Pat. No. 5,024,716, entitled “Plasma processing apparatus for etching, ashing, and film-formation”; the content of which is herein incorporated by reference in its entirety.

The front view illustrates that the third SWA plasma source 350 can comprise a plurality of protection assemblies (374a, 374b, 374c, and 374d) that can be configured as extensions of the resonator plate 352. For example, the resonator plate 352 and the protection assemblies (374a, 374b, 374c, and 374d) can comprise dielectric materials, such as quartz. Alternatively, the resonator plate 352 and the protection assemblies (374a, 374b, 374c, and 374d) may comprise semiconductor or metallic materials.

The design of the protection assemblies (374a, 374b, 374c, and 374d) can be used to control the spatial uniformity of the plasma in process space 315. For example, the geometry, size, and material of the protection assemblies (374a, 374b, 374c, and 374d) can be factors that can contribute to the spatial uniformity of the plasma formed in the process space 315. Alternatively, the protection assemblies (374a, 374b, 374c, and 374d) may be configured differently or may not be required.

A first positioning subsystem 375a can be coupled to at least one mounting structure 376 and can be coupled to a first plasma-tuning rod 370a. The first positioning subsystem 375a can be used to create first movements 371a in the first plasma-tuning rod 370a within the first tuning space 372a established in the first tuning assembly 373a. The first tuning space 372a and the first tuning assembly 373a can be configured to extend through the outer conductor 342, the slow wave plate 344, the slot antenna 346, and the resonator plate 352, and can extend into the first protection assembly 374a as shown. Alternatively, the first tuning space 372a and the first tuning assembly 373a can be configured differently.

As shown in FIG. 3A, the first plasma-tuning rod 370a can extend through the slow wave plate 344, the slot antenna 346, and the resonator plate 352 and can obtain first tunable EM energy from the slot antenna 346, the slow wave plate 344, and/or the resonator plate 352. The first plasma-tuning rod 370a that can have first movements 371a associated therewith and the first movements 371a can be used to control the tunable EM energy. For example, the first plasma-tuning rod 370a can move 371a in a first (vertical) direction within a first tuning space 372a established in the first tuning assembly 373a. In addition, the first tunable EM energy provided to the process space 315 by the lower portion of the first plasma-tuning rod 370a can include a tunable E-field component, a tunable H-field component, a tunable voltage component, a tunable energy component, or a tunable current component, or any combination thereof.

The first tuning space 372a and the first tuning assembly 373a can be cylindrically shaped, and can have diameters larger than the diameters of the first plasma tuning rods 370a, thereby allowing the first plasma-tuning rod 370a to move freely therein. Alternatively, the number, shape, length, and/or position of first plasma tuning rods 370a may be different.

The first plasma-tuning rod 370a, first tuning space 372a, the first tuning assembly 373a, and the first protection assembly 374a can be aligned at a first x/y plane location (x₁ₐ) in the process space 315, and the first tunable EM energy can be provided by the first plasma-tuning rod 370a at the first x/y plane location (x₁ₐ) in the process space 315. Alternatively, the first plasma-tuning rod 370a, first tuning space 372a, the first tuning assembly 373a, and the first protection assembly 374a may be configured differently.

Still referring to FIG. 3A, the first protection assembly 374a can extend a first insertion length (y₁ₐ) into the process space 315, and the first insertion length (y₁ₐ) can be established relative to the plasma-facing surface 361 of the resonator plate 352. The first insertion length (y₁ₐ) can be wavelength-dependent and may vary from about (λ/20) to about (10λ), or the first insertion length (y₁ₐ) may vary from about 1 mm to about 5 mm.

The first tuning space 372a and the first tuning assembly 373a can extend second insertion lengths (y₂ₐ) into the process space 315, and the second insertion length (y₂ₐ) can be established relative to the plasma-facing surface 361 of the resonator plate 352. The second insertion length (y₂ₐ) can be wavelength-dependent and can vary from about (λ/20) to about (10λ). Alternatively, the second insertion length (y₂ₐ) may vary from about 1 mm to about 5 mm. For example, the first insertion length (y₁ₐ) and the second insertion length (y₂ₐ) can be factors that can contribute to the spatial uniformity of the plasma formed in the process space 315. Alternatively, the first protection assembly 374a may be configured differently or may not be required.

The first plasma-tuning rod 370a can extend a third insertion length (y₃ₐ) into the process space 315, and the third insertion length (y₃ₐ) can be established relative to the plasma-facing surface 361 of the resonator plate 352. The third insertion lengths (y₃ₐ) can be dependent upon the first movements 371a, can be wavelength-dependent, and can vary from about (λ/20) to about (10λ). Alternatively, the third insertion lengths (y₃ₐ) may vary from about 1 mm to about 5 mm. The controller 395 can be coupled 396 to the first positioning subsystem 375a and can control the third insertion lengths (y₃ₐ) using the first positioning subsystem 375a, and the controller 395 can use process recipes to establish, control, and optimize the third insertion lengths (y₃ₐ) in real-time to control the plasma uniformity within the process space 315. For example, the controller 395 can control the first movements 371a of the first plasma-tuning rod 370a in real-time to control the first tunable EM energy and the plasma uniformity within the process space 315.

As shown in FIG. 3A, a second positioning subsystem 375b can be coupled to at least one mounting structure 376 and can be coupled to the second plasma-tuning rod 370b. The second positioning subsystem 375b can be used to create second movements 371b in the second plasma-tuning rod 370b within the second tuning space 372b established in the second tuning assembly 373b. The second tuning space 372b and the second tuning assembly 373b can be configured to extend through the outer conductor 342, the slow wave plate 344, the slot antenna 346, and the resonator plate 352 and can extend into the second protection assembly 374b as shown. Alternatively, the second tuning space 372b and the second tuning assembly 373b can be configured differently.

The second plasma-tuning rod 370b can extend through the slow wave plate 344, the slot antenna 346, and the resonator plate 352 and can obtain second tunable EM energy from the slot antenna 346, the slow wave plate 344, and/or the resonator plate 352. The second plasma-tuning rod 370b that can have second movements 371b associated therewith and the second movements 371b can be used to control the tunable EM energy. For example, the second plasma-tuning rod 370b can move in a second (vertical) direction within a second tuning space 372b established in the second tuning assembly 373b. In addition, the second tunable EM energy provided to the process space 315 by the lower portion of the second plasma-tuning rod 370b can include a tunable E-field component, a tunable H-field component, a tunable voltage component, a tunable energy component, or a tunable current component, or any combination thereof.

The second tuning space 372b and the second tuning assembly 373b can be cylindrically shaped, and can have diameters larger than the diameters of the second plasma tuning rods 370b, thereby allowing the second plasma-tuning rod 370b to move freely therein. Alternatively, the number, shape, length, and/or position of second plasma tuning rods 370b may be different.

The second plasma-tuning rod 370b, second tuning space 372b, the second tuning assembly 373b, and the second protection assembly 374b can be aligned at a second x/y plane location (x_{1b}) in the process space 315, and the second tunable EM energy can be provided by the second plasma-tuning rod 370b at the second x/y plane location (x_{1b}) in the process space 315. Alternatively, the second plasma-tuning rod 370b, second tuning space 372b, the second tuning assembly 373b, and the second protection assembly 374b may be configured differently.

Referring again to FIG. 3A, the second protection assembly 374b can extend a first insertion length (y_{1b}) into the process space 315, and the first insertion length (y_{1b}) can be established relative to the plasma-facing surface 361 of the resonator plate 352. The first insertion length (y_{1b}) can be wavelength-dependent and can vary from about (λ/20) to about (10λ), or the first insertion length (y_{1b}) may vary from about 1 mm to about 5 mm.

The second tuning space 372b and the second tuning assembly 373b can extend second insertion lengths (y_{2b}) into the process space 315, and the second insertion length (y_{2b}) can be established relative to the plasma-facing surface 361 of the resonator plate 352. The second insertion length (y_{2b}) can be wavelength-dependent and can vary from about (λ/20) to about (10λ). Alternatively, the second insertion length (y_{2b}) may vary from about 1 mm to about 5 mm. For example, the first insertion length (y_{1b}) and the second insertion length (y_{2b}) can be factors that can contribute to the spatial uniformity of the plasma formed in the process space 315. Alternatively, the second protection assembly 374b may be configured differently or may not be required.

The second plasma-tuning rod 370b can extend a third insertion length (y_{3b}) into the process space 315, and the third insertion length (y_{3b}) can be established relative to the plasma-facing surface 361 of the resonator plate 352. The third insertion lengths (y_{3b}) can be dependent upon the second movements 371b, can be wavelength-dependent, and can vary from about (λ/20) to about (10λ). Alternatively, the third insertion lengths (y_{3b}) may vary from about 1 mm to about 5 mm. The controller 395 can control the third insertion lengths (y_{3b}) using the second positioning subsystem 375b, and the controller 395 can use process recipes to establish, control, and optimize the third insertion lengths (y_{3b}) in real-time to control the plasma uniformity within the process space 315. For example, the controller 395 can control the second movements 371b of the second plasma-tuning rod 370b in real-time to independently control the second tunable EM energy and the plasma uniformity within the process space 315.

As shown in FIG. 3A, a third positioning subsystem 375c can be coupled to at least one mounting structure 376 and can be coupled to the third plasma-tuning rod 370c. The third positioning subsystem 375c can be used to create third movements 371c in the third plasma-tuning rod 370c within the third tuning space 372c established in the third tuning assembly 373c. The third tuning space 372c and the third tuning assembly 373c can be configured to extend through the outer conductor 342, the slow wave plate 344, the slot antenna 346, and the resonator plate 352, and can extend into the third protection assembly 374c as shown. Alternatively, the third tuning space 372c and the third tuning assembly 373c can be configured differently.

The third plasma-tuning rod 370c can extend through the slow wave plate 344, the slot antenna 346, and the resonator plate 352 and can obtain third tunable EM energy from the slot antenna 346, the slow wave plate 344, and/or the resonator plate 352. The third plasma-tuning rod 370c that can have third movements 371c associated therewith and the third movements 371c can be used to control the tunable EM energy. For example, the third plasma-tuning rod 370c can move 371c in a third (vertical) direction within a third tuning space 372c established in the third tuning assembly 373c. In addition, the third tunable EM energy provided to the process space 315 by the lower portion of the third plasma-tuning rod 370c can include a tunable E-field component, a tunable H-field component, a tunable voltage component, a tunable energy component, or a tunable current component, or any combination thereof.

The third tuning space 372c and the third tuning assembly 373c can be cylindrically shaped, and can have diameters larger than the diameters of the third plasma tuning rods 370c, thereby allowing the third plasma-tuning rod 370c to move freely therein. Alternatively, the number, shape, length, and/or position of third plasma tuning rods 370c may be different.

The third plasma-tuning rod 370c, third tuning space 372c, the third tuning space 373c, and the third protection assembly 374c can be aligned at a third x/y plane location (x_{1c}) in the process space 315, and the third tunable EM energy can be provided by the third plasma-tuning rod 370c at the third x/y plane location (x_{1c}) in the process space 315. Alternatively, the third plasma-tuning rod 370c, third tuning space 372c, the third tuning space 373c, and the third protection assembly 374c may be configured differently.

The third protection assembly 374c can extend a first insertion length (y_{1c}) into the process space 315, and the first insertion length (y_{1c}) can be established relative to the plasma-facing surface 361 of the resonator plate 352. The first insertion length (y_{1c}) can be wavelength-dependent and can vary from about (λ/20) to about (10λ). Alternatively, the first insertion length (y_{1c}) may vary from about 1 mm to about 5 mm.

The third tuning space 372c and the third tuning assembly 373c can extend second insertion lengths (y_{2c}) into the process space 315, and the second insertion length (y_{2c}) can be established relative to the plasma-facing surface 361 of the resonator plate 352. The second insertion length (y_{2c}) can be wavelength-dependent and can vary from about (λ/20) to about (10λ). Alternatively, the second insertion length (y_{2c}) may vary from about 1 mm to about 5 mm. For example, the first insertion length (y_{1c}) and the second insertion length (y_{2c}) can be factors that can contribute to the spatial uniformity of the plasma formed in the process space 315. Alternatively, the third protection assembly 374c may be configured differently or may not be required.

The third plasma-tuning rod 370c can extend a third insertion length (y_{3c}) into the process space 315, and the third insertion length (y_{3c}) can be established relative to the plasma-facing surface 361 of the resonator plate 352. The third insertion lengths (y_{3c}) can be dependent upon the third movements 371c, can be wavelength-dependent, and can vary from about (λ/20) to about (10λ). Alternatively, the third insertion lengths (y_{3c}) may vary from about 1 mm to about 5 mm. The controller 395 can control the third insertion lengths (y_{3c}) using the third positioning subsystem 375c, and the controller 395 can use process recipes to establish, control, and optimize the third insertion lengths (y_{3c}) in real-time to control the plasma uniformity within the process space 315. For example, the controller 395 can control the third movements 371c of the third plasma-tuning rod 370c in real-time to independently control the third tunable EM energy and the plasma uniformity within the process space 315.

As shown in FIG. 3A, a fourth positioning subsystem 375d can be coupled to at least one mounting structure 376 and can be coupled to the fourth plasma-tuning rod 370d. The fourth positioning subsystem 375d can be used to create fourth movements 371d in the fourth plasma-tuning rod 370d within the fourth tuning space 372d established in the fourth tuning assembly 373d. The fourth tuning space 372d and the fourth tuning assembly 373d can be configured to extend through the outer conductor 342, the slow wave plate 344, the slot antenna 346, and the resonator plate 352, and can extend into the fourth protection assembly 374d as shown. Alternatively, the fourth tuning space 372d and the fourth tuning assembly 373d can be configured differently.

As shown in FIG. 3A, the fourth plasma-tuning rod 370d can extend through the slow wave plate 344, the slot antenna 346, and the resonator plate 352 and can obtain fourth tunable EM energy from the slot antenna 346, the slow wave plate 344, and/or the resonator plate 352. The fourth plasma-tuning rod 370d that can have fourth movements 371d associated therewith and the fourth movements 371d can be used to control the tunable EM energy. For example, the fourth plasma-tuning rod 370d can move in a fourth (vertical) direction within a fourth tuning space 372d established in the fourth tuning assembly 373d. In addition, the fourth tunable EM energy provided to the process space 315 by the lower portion of the fourth plasma-tuning rod 370d can include a tunable E-field component, a tunable H-field component, a tunable voltage component, a tunable energy component, or a tunable current component, or any combination thereof.

The fourth tuning space 372d and the fourth tuning assembly 373d can be cylindrically shaped, and can have diameters larger than the diameter of the fourth plasma tuning rods 370d, thereby allowing the fourth plasma-tuning rod 370d to move freely therein. Alternatively, the number, shape, length, and/or position of fourth plasma tuning rods 370d may be different.

The fourth plasma-tuning rod 370d, fourth tuning space 372d, the fourth tuning space 373d, and the fourth protection assembly 374d can be aligned at a fourth x/y plane location (x_{1d}) in the process space 315, and the fourth tunable EM energy can be provided by the fourth plasma-tuning rod 370d at the fourth x/y plane location (x_{1d}) in the process space 315. Alternatively, the fourth plasma-tuning rod 370d, fourth tuning space 372d, the fourth tuning space 373d, and the fourth protection assembly 374d may be configured differently.

The fourth protection assembly 374d can extend a first insertion length (y_{1d}) into the process space 315, and the first insertion length (y_{1d}) can be established relative to the plasma-facing surface 361 of the resonator plate 352. The first insertion length (y_{1d}) can be wavelength-dependent and can vary from about (λ/20) to about (10λ). Alternatively, the first insertion length (y_{1d}) may vary from about 1 mm to about 5 mm.

The fourth tuning space 372d and the fourth tuning assembly 373d can extend second insertion lengths (y_{2d}) into the process space 315, and the second insertion length (y_{2d}) can be established relative to the plasma-facing surface 361 of the resonator plate 352. The second insertion length (y_{2d}) can be wavelength-dependent and can vary from about (λ/20) to about (10λ). Alternatively, the second insertion length (y_{2d}) may vary from about 1 mm to about 5 mm. For example, the first insertion length (y_{1d}) and the second insertion length (y_{2d}) can be factors that can contribute to the spatial uniformity of the plasma formed in the process space 315. Alternatively, the fourth protection assembly 374d may be configured differently or may not be required.

The fourth plasma-tuning rod 370d can extend a third insertion length (y_{3d}) into the process space 315, and the third insertion length (y_{3d}) can be established relative to the plasma-facing surface 361 of the resonator plate 352. The third insertion lengths (y_{3d}) can be dependent upon the fourth movements 371d, can be wavelength-dependent, and can vary from about (λ/20) to about (10λ). Alternatively, the third insertion lengths (y_{3d}) may vary from about 1 mm to about 5 mm. The controller 395 can control the third insertion lengths (y_{3d}) using the fourth positioning subsystem 375d, and the controller 395 can use process recipes to establish, control, and optimize the third insertion lengths (y_{3d}) in real-time to control the plasma uniformity within the process space 315. For example, the controller can independently control the fourth movements 371d of the fourth plasma-tuning rod 370d in real-time to control the fourth tunable EM energy and the plasma uniformity within the process space 315.

The front view illustrates that the third SWA processing system 300 can comprise a plurality of plasma-tuning rods (370e and 370f) and a plurality of protection assemblies (374e and 374f) that can be coupled to a plurality of isolation assemblies (366e and 366f). For example, the plasma-tuning rods (370e and 370f) and the protection assemblies (374e and 3740 can comprise dielectric materials, such as quartz. Alternatively, the plasma-tuning rods (370e and 3700 and the protection assemblies (374e and 3740 may comprise semiconductor or metallic materials. In addition, the isolation assemblies (366e and 3660 can include isolation and movement devices (not shown) and the isolation assemblies (366e and 3660 may comprise dielectric, semiconductor, and/or metallic materials.

The design of the plasma-tuning rods (370e and 3700 and the protection assemblies (374e and 3740 can be used to control the spatial uniformity of the plasma in process space 315. For example, the geometry, size, and material of the plasma-tuning rods (370e and 3700 and/or the protection assemblies (374e and 3740 can be factors that can contribute to the spatial uniformity of the plasma formed in the process space 315. Alternatively, the plasma-tuning rods (370e and 3700 or the protection assemblies (374e and 3740 may be configured differently or may not be required.

Still referring to FIG. 3A, a second portion of the fifth plasma-tuning rod 370e can extend into the fifth isolated tuning space 373e established in the fifth protection assembly 374e at a fifth x/y plane location (y₂ₑ) in the process space 315, and a first portion of the fifth plasma-tuning rod 370e can also extend into the first EM energy tuning space 368a in the first resonant cavity 369a at the fifth x/y plane location (y₂ₑ). A fifth isolation assembly 366e can include movement devices (not shown) that can be used to position and move 371e the fifth plasma-tuning rod 370e the fifth plasma-tuning distances 372e within the fifth isolated tuning space 373e established in the fifth protection assembly 374e. For example, the fifth plasma-tuning distance 372e can vary from about 0.10 mm to about 1 mm, and the fifth plasma-tuning distance 372e can be wavelength-dependent and can vary from about (λ/40) to about (10λ).

A fifth coupling region 365e can be established at a first coupling distance (x₁ₑ) from one or more of the walls of the first resonant cavity 369a, and the first portion of the fifth plasma-tuning rod 370e can extend into the fifth coupling region 365e in the first EM energy tuning space 368a in the first resonant cavity 369a. The first portion of the fifth plasma-tuning rod can obtain fifth tunable EM energy from the fifth coupling region 365e, and the fifth EM energy can be transferred to the process space 315 at the fifth x/y plane location (y₁ₑ) using the second portion of the fifth plasma-tuning rod 370e. The first coupling region 365e can include a tunable E-field region, a tunable H-field region, a maximum field region, a maximum voltage region, maximum energy region, or a maximum current region, or any combination thereof. For example, the first coupling distance (x₁ₑ) can vary from about 0.01 mm to about 10 mm, and the first coupling distance (x₁ₑ) can be wavelength-dependent and can vary from about (λ/4) to about (10λ).

A fifth tuning slab 363e can be coupled to a fifth control assembly 362e and can be used to move 364e the fifth tuning slab 363e a fifth cavity-tuning distance (x₂ₑ) relative to the first portion of the fifth plasma-tuning rod 370e within the first EM energy tuning space 368a in the first resonant cavity 369a. The fifth control assembly 362e and the fifth tuning slab 363e can be used to optimize the EM energy coupled from the fifth coupling region 365e to the second portion of the fifth plasma-tuning rod 370e. For example, the fifth cavity-tuning distance (x₂ₑ) can vary from about 0.01 mm to about 1 mm.

The controller 395 can be coupled 396 to the fifth control assembly 362e and can control the fifth cavity-tuning distance (x₂ₑ) using the fifth control assembly 362e, and the controller 395 can use process recipes to establish, control, and optimize the fifth cavity-tuning distance (x₂ₑ) in real-time to control the plasma uniformity within the process space 315. Alternatively, the controller 395 may independently control the fifth movements 371e of the fifth plasma-tuning rod 370e in real-time to control the fifth tunable EM energy and the plasma uniformity within the process space 315.

The fifth plasma-tuning rod 370e can have a fifth diameter (d_{1c}) associated therewith, and the first diameter (d_{1c}) can vary from about 0.01 mm to about 1 mm. The fifth isolation assembly 374e can have a fifth diameter (D₁ₑ) associated therewith, and the fifth diameter (D₁ₑ) can vary from about 1 mm to about 10 mm.

The second portion of the fifth plasma-tuning rod 370e, the fifth coupling region 365e, the fifth control assembly 362e, and the fifth tuning slab 363e can have a fifth x/y plane offset (y₁ₑ) associated therewith. For example, the fifth x/y plane offset (y₁ₑ) can be established relative to a cavity wall, can be wavelength-dependent, and can vary from about (λ/4) to about (10λ). The fifth control assembly 362e can have a cylindrical configuration and a diameter (d₂ₑ) that can vary from about 1 mm to about 5 mm. The fifth tuning slab 363e can have diameters (D₂ₑ) associated therewith, and the diameters (D₂ₑ) can vary from about 1 mm to about 10 mm.

Referring still to FIG. 3A, a second portion of the sixth plasma-tuning rod 370f is shown extending into the sixth isolated tuning space 373f established in the sixth protection assembly 374f at a sixth x/y plane location (y_{2f}) in the process space 315, and a second portion of the sixth plasma-tuning rod 370f can also extend into the second EM energy tuning space 368b in the second resonant cavity 369b at the sixth x/y plane location (y_{2f}). A sixth isolation assembly 366f can be used to position and move 372f the sixth plasma-tuning rod 370f sixth plasma-tuning distances 372f within the sixth isolated tuning space 373f established in the sixth protection assembly 374f. For example, the sixth plasma-tuning distance 372f can vary from about 0.10 mm to about 1 mm, and the sixth plasma-tuning distance 372f can be wavelength-dependent and can vary from about (λ/40) to about (10λ). A sixth coupling region 365f can be established at a first coupling distance (x_{1f}) from one or more of the walls of the second resonant cavity 369b, and the second portion of the sixth plasma-tuning rod 370f can extend into the sixth coupling region 365f in the second EM energy tuning space 368b in the second resonant cavity 369b. The first portion of the sixth plasma-tuning rod can obtain sixth tunable EM energy from the sixth coupling region 365f, and the sixth EM energy can be transferred to the process space 315 at the sixth x/y plane locations (y_{1f}) using the second portion of the sixth plasma-tuning rod 370f. The sixth coupling region 365f can include a tunable E-field region, a tunable H-field region, a maximum field region, a maximum voltage region, maximum energy region, or a maximum current region, or any combination thereof. The first coupling distance (x_{1f}) can vary from about 0.01 mm to about 10 mm, and the first coupling distance (x_{1f}) can be wavelength-dependent and can vary from about (λ/4) to about (10λ).

A sixth tuning slab 363f can be coupled to a sixth control assembly 362f and can be used to move 364f the sixth tuning slab 363f a sixth cavity-tuning distance (x_{2f}) relative to the second portion of the sixth plasma-tuning rod 370f within the second EM energy tuning space 368b in the second resonant cavity 369b. The sixth control assembly 362f and the sixth tuning slab 363f can be used to optimize the EM energy coupled from the sixth coupling region 365f to the first portion of the sixth plasma-tuning rod 370f. For example, the sixth cavity-tuning distance (x_{2f}) can vary from about 0.01 mm to about 1 mm.

The controller 395 can be coupled 396 to the sixth control assembly 362f and can control the sixth cavity-tuning distance (x_{2f}) using the sixth control assembly 362f, and the controller 395 can use process recipes to establish, control, and optimize the sixth cavity-tuning distance (x_{2f}) in real-time to control the plasma uniformity within the process space 315. Alternatively, the controller 395 may independently control the sixth movements 371f of the sixth plasma-tuning rod 370f in real-time to control the sixth tunable EM energy and the plasma uniformity within the process space 315.

The sixth plasma-tuning rod 370f can have a sixth diameter (d_{1f}) associated therewith, and the sixth diameter (d_{1f}) can vary from about 0.01 mm to about 1 mm. The sixth isolation assembly 374f can have a sixth diameter (D_{1f}) associated therewith, and the sixth diameter (D_{1f}) can vary from about 1 mm to about 10 mm.

The second portion of the sixth plasma-tuning rod 370f, the sixth coupling region 365f, the sixth control assembly 362f, and the sixth tuning slab 363f can have a sixth x/y plane offset (y_{1f}) associated therewith. For example, the sixth x/y plane offset (y_{1f}) can be established relative to a cavity wall, can be wavelength-dependent, and can vary from about (λ/4) to about (10λ). The sixth control assembly 362f can have a cylindrical configuration and a diameter (d_{2f}) that can vary from about 1 mm to about 5 mm. The sixth tuning slab 363f can have diameters (D_{2f}) associated therewith, and the diameter (D_{2f}) can vary from about 1 mm to about 10 mm.

The isolation assemblies (366e and 366f) can be coupled (not shown) to the controller 395, and the controller 395 can use process recipes to establish, control, and optimize the plasma-tuning distances (372e and 3720 and the tuning rod movements (371e and 371f) to control the plasma uniformity within the process space 315.

In some embodiments, the third SWA processing system 300 can be configured to form plasma in the process space 315 as the substrate holder 320 and the substrate are moved through the process space 315. In other embodiments, the third SWA processing system 300 can be configured to form plasma in the process space 315 as the substrate holder 320 and the substrate are positioned within the process space 315.

Referring still to the front view, a controller 395 is shown coupled 396 to the EM source 390, the match network/phase shifter 391, and the tuner network/isolator 392, and the controller 395 can use process recipes to establish, control, and optimize the EM source 390, the match network/phase shifter 391, and the tuner network/isolator 392 to control the plasma uniformity within the process space 315. For example, the EM source 390 can operate at frequencies from about 500 MHz to about 5000 MHz, and the controller 395 can optimize the operating frequencies in real-time. In addition, the controller 395 can be coupled 396 to the process sensors 307, and the controller 395 can use process recipes to establish, control, and optimize the data from the process sensors 307 to control the plasma uniformity within the process space 315.

The controller 395 can be coupled 396 to the additional EM sources (not shown), the additional match network/phase shifters (not shown), and the additional tuner network/isolators (not shown) when they are present. The controller 395 can use process recipes to establish, control, and optimize the additional EM sources (not shown), the additional match network/phase shifters (not shown), and the additional tuner network/isolators (not shown), when they are present, to control the plasma uniformity within the process space 315. For example, to the additional EM sources (not shown), the additional match network/phase shifters (not shown), and the additional tuner network/isolators (not shown), when they are present, can operate at frequencies from about 500 MHz to about 5000 MHz. In addition, the controller 395 can be coupled 396 to the resonant cavities (369a and 369b), and the controller 395 can use process recipes to establish, tune, control, and optimize the data from the resonant cavities (369a and 369b), to control the plasma uniformity within the process space 315.

Some of the third SWA processing systems 300 can include a pressure control system 325 and exhaust port 326 coupled to the third process chamber 310, and configured to evacuate the third process chamber 310, as well as control the pressure within the third process chamber 310. Alternatively, the pressure control system 325 and/or the exhaust port 326 may not be required.

As shown in FIG. 3A, the third SWA processing system 300 can comprise a first gas supply system 380 coupled to one or more first flow elements 381 that can be coupled to the third process chamber 310. The first flow elements 381 can be configured to introduce a first process gas to process space 315, and can include flow control and/or flow measuring devices. In addition, the third SWA processing system 300 can comprise a second gas supply system 382 coupled to one or more second flow elements 383 that can be coupled to the third process chamber 310. The second flow elements 383 can be configured to introduce a second process gas to process space 315, and can include flow control and/or flow measuring devices. Alternatively, the second gas supply system 382 and/or the second flow elements 383 may not be required.

During dry plasma etching, the process gas may comprise an etchant, a passivant, or an inert gas, or a combination of two or more thereof. For example, when plasma etching a dielectric film such as silicon oxide (SiOₓ) or silicon nitride (SiₓN_{y}), the plasma etch gas composition generally includes a fluorocarbon-based chemistry (CₓF_{y}) such as at least one of C₄F₈, C₅F₈, C₃F₆, C₄F₆, CF₄, etc., and/or may include a fluorohydrocarbon-based chemistry (CₓH_{y}F_{z}) such as at least one of CHF₃, CH₂F₂, etc., and can have at least one of an inert gas, oxygen, CO or CO₂. Additionally, for example, when etching polycrystalline silicon (poliesilicon), the plasma etch gas composition generally includes a halogen-containing gas such as HBr, Cl₂, NF₃, or SF₆ or a combination of two or more thereof, and may include fluorohydrocarbon-based chemistry (CₓH_{y}F_{z}) such as at least one of CHF₃, CH₂F₂, etc., and at least one of an inert gas, oxygen, CO or CO₂, or two or more thereof. During plasma-enhanced deposition, the process gas may comprise a film forming precursor, a reduction gas, or an inert gas, or a combination of two or more thereof.

FIG. 3B illustrates a simplified partial bottom view of a resonator plate 352 in the third SWA processing system 300 in accordance with embodiments of the invention. The resonator plate 352 can have a total length (x_{T}) and a total width (z_{T}) associated therewith in the x/z plane. For example, the total length (x_{T}) can vary from about 10 mm to about 1000 mm, and the total width (z_{T}) can vary from about 10 mm to about 1000 mm.

The partial bottom view of resonator plate 352 in the third SWA plasma source 350 includes a bottom (dotted line) view of a first plasma-tuning rod 370a that is shown surrounded by a bottom (dash line) view of the first tuning assembly 373a, and the bottom view of a first tuning assembly 373a is shown surrounded by a bottom view of the first protection assembly 374a.

As shown in FIG. 3B, the first plasma-tuning rod 370a can have first diameters (d₁ₐ) associated therewith, and the first diameters (d₁ₐ) can vary from about 0.01 mm to about 1 mm. The first tuning assembly 373a can have first diameters (D₁ₐ) associated therewith, and the first diameters (D₁ₐ) can vary from about 1 mm to about 10 mm. The first protection assembly 374a can have first lengths (l₁ₐ) associated therewith, and the first lengths (l₁ₐ) can vary from about 1 mm to about 10 mm. The first plasma-tuning rod 370a, the first tuning assembly 373a, and the first protection assembly 374a can have first x/z plane offsets (x₁ₐ) associated therewith, and the first x/z plane offsets (x₁ₐ) can vary from about 2 mm to about 1000 mm. Alternatively, the first plasma-tuning rod 370a, the first tuning assembly 373a, and the first protection assembly 374a may have different first x/z plane offsets (x₁ₐ) associated therewith. The first plasma-tuning rod 370a, the first tuning assembly 373a, and the first protection assembly 374a can have first x/z plane offsets (z₁ₐ) associated therewith, and the first x/z plane offsets (z₁ₐ) can vary from about 10 mm to about 1000 mm. Alternatively, the first plasma-tuning rod 370a, the first tuning assembly 373a, and the first protection assembly 374a may have different first x/z plane offsets (z₁ₐ) associated therewith.

The partial bottom view of resonator plate 352 in the third SWA plasma source 350 includes a bottom (dotted line) view of a second plasma-tuning rod 370b that is shown surrounded by a bottom (dash line) view of the second tuning assembly 373b, and the bottom view of a second tuning assembly 373b is shown surrounded by a bottom view of the second protection assembly 374b.

The second plasma-tuning rod 370b can have a first diameter (d_{1b}) associated therewith, and the first diameter (d_{1b}) can vary from about 0.01 mm to about 1 mm. The second tuning assembly 373b can have a first diameter (D_{1b}) associated therewith, and the first diameter (D_{1b}) can vary from about 1 mm to about 10 mm. The second protection assembly 374b can have a first length (l_{1b}) associated therewith, and the first length (l_{1b}) can vary from about 1 mm to about 10 mm. The second plasma-tuning rod 370b, the second tuning assembly 373b, and the second protection assembly 374b can have first x/z plane offsets (x_{1b}) associated therewith, and the first x/z plane offsets (x_{1b}) can vary from about 10 mm to about 1000 mm. Alternatively, the second plasma-tuning rod 370b, the second tuning assembly 373b, and the second protection assembly 374b may have different first x/z plane offsets (x_{1b}) associated therewith. The second plasma-tuning rod 370b, the second tuning assembly 373b, and the second protection assembly 374b can have first x/z plane offsets (z_{1b}) associated therewith, and the first x/z plane offsets (z_{1b}) can vary from about 10 mm to about 1000 mm. Alternatively, the second plasma-tuning rod 370b, the second tuning assembly 373b, and the second protection assembly 374b may have different first x/z plane offsets (z_{1b}) associated therewith.

Still referring to FIG. 3B, the partial bottom view of resonator plate 352 in the third SWA plasma source 350 includes a bottom (dotted line) view of a third plasma-tuning rod 370c that is shown surrounded by a bottom (dash line) view of the third tuning assembly 373c, and the bottom view of a third tuning assembly 373c is shown surrounded by a bottom view of the third protection assembly 374c.

The third plasma-tuning rod 370c can have a first diameter (d_{1c}) associated therewith, and the first diameter (d_{1c}) can vary from about 0.01 mm to about 1 mm. The third tuning assembly 373c can have a first diameter (D_{1c}) associated therewith, and the first diameter (D_{1c}) can vary from about 1 mm to about 10 mm. The third protection assembly 374c can have a first length (l_{1c}) associated therewith, and the first length (l_{1c}) can vary from about 1 mm to about 10 mm. The third plasma-tuning rod 370c, the third tuning assembly 373c, and the third protection assembly 374c can have first x/z plane offsets (x_{1c}) associated therewith, and the first x/z plane offsets (x_{1c}) can vary from about 10 mm to about 1000 mm. Alternatively, the third plasma-tuning rod 370c, the third tuning assembly 373c, and the third protection assembly 374c may have different first x/z plane offsets (x_{1c}) associated therewith. The third plasma-tuning rod 370c, the third tuning assembly 373c, and the third protection assembly 374c can have first x/z plane offsets (z_{1c}) associated therewith, and the first x/z plane offsets (z_{1c}) can vary from about 10 mm to about 1000 mm. Alternatively, the third plasma-tuning rod 370c, the third tuning assembly 373c, and the third protection assembly 374c may have different first x/z plane offsets (z_{1c}) associated therewith.

The partial bottom view of resonator plate 352 in the third SWA plasma source 350 also includes a bottom (dotted line) view of a fourth plasma-tuning rod 370d that is shown surrounded by a bottom (dash line) view of the fourth tuning assembly 373d, and the bottom view of a fourth tuning assembly 373d is shown surrounded by a bottom view of the fourth protection assembly 374d.

The fourth plasma-tuning rod 370d can have a first diameter (d_{1d}) associated therewith, and the first diameter (d_{1d}) can vary from about 0.01 mm to about 1 mm. The fourth tuning assembly 373d can have a first diameter (D_{1d}) associated therewith, and the first diameter (D_{1d}) can vary from about 1 mm to about 10 mm. The fourth protection assembly 374d can have a first length (l_{1d}) associated therewith, and the first length (l_{1d}) can vary from about 1 mm to about 10 mm. The fourth plasma-tuning rod 370d, the fourth tuning assembly 373d, and the fourth protection assembly 374d can have first x/z plane offsets (x_{1d}) associated therewith, and the first x/z plane offsets (x_{1d}) can vary from about 10 mm to about 1000 mm. Alternatively, the fourth plasma-tuning rod 370d, the fourth tuning assembly 373d, and the fourth protection assembly 374d may have different first x/z plane offsets (x_{1d}) associated therewith. The fourth plasma-tuning rod 370d, the fourth tuning assembly 373d, and the fourth protection assembly 374d can have first z-plane offsets (z_{1d}) associated therewith, and the first x/z plane offsets (z_{1d}) can vary from about 10 mm to about 1000 mm. Alternatively, the fourth plasma-tuning rod 370d, the fourth tuning assembly 373d, and the fourth protection assembly 374d may have different first x/z plane offsets (z_{1d}) associated therewith.

FIG. 3B illustrates that in some embodiments, the third EM source 390 can include a partial bottom view of a first resonant cavity 369a coupled to a partial bottom view of a chamber wall 312a and can include a partial bottom view of a second resonant cavity 369b coupled to a partial bottom view of another chamber wall 312b.

The bottom view shows that a second portion of the fifth plasma-tuning rod 370e can extend into the fifth isolated tuning space 373e established in the fifth protection assembly 374e at a fifth x/z plane location (z₁ₑ) in the process space 315, and a second portion of the fifth plasma-tuning rod 370e can also extend into the first EM energy tuning space 368a in the first resonant cavity 369a at the fifth x/z plane location (z₁ₑ). A fifth isolation assembly 366e can be used to position and move 371e the fifth plasma-tuning rod 370e fifth plasma-tuning distances 372e within the fifth isolated tuning space 373e established in the fifth protection assembly 374e. For example, the fifth plasma-tuning distance 372e can vary from about 0.10 mm to about 1 mm, and the fifth plasma-tuning distance 372e can be wavelength-dependent and can vary from about (λ/40) to about (10λ).

FIG. 3B shows that a fifth coupling region 365e can be established at a first x/z plane coupling distance (z₂ₑ) from one or more of the walls of the first resonant cavity 369a, and the first portion of the fifth plasma-tuning rod 370e can extend into the fifth coupling region 365e. The first portion of the fifth plasma-tuning rod can obtain fifth tunable EM energy from the fifth coupling region 365e, and the fifth EM energy can be transferred to the process space 315 at the fifth x/z plane location (z₁ₑ) using the second portion of the fifth plasma-tuning rod 370e. The first coupling region 365e can include a tunable E-field region, a tunable H-field region, a maximum field region, a maximum voltage region, maximum energy region, or a maximum current region, or any combination thereof. The first coupling distance (x₁ₑ) can vary from about 0.01 mm to about 10 mm, and the first coupling distance (x₁ₑ) can be wavelength-dependent and can vary from about (λ/4) to about (10λ).

A fifth tuning slab 363e can be coupled to a fifth control assembly 362e and can be used to move 364e the fifth tuning slab 363e a fifth cavity-tuning distance (x₂ₑ) relative to the first portion of the fifth plasma-tuning rod 370e within the first EM energy tuning space 368a in the first resonant cavity 369a. The fifth control assembly 362e and the fifth tuning slab 363e can be used to optimize the EM energy coupled from the fifth coupling region 365e to the second portion of the fifth plasma-tuning rod 370e. For example, the fifth cavity-tuning distance (x₂ₑ) can vary from about 0.01 mm to about 1 mm.

The fifth control assembly 362e can have lengths (x₅ₑ) associated therewith, and the lengths (x₅ₑ) can vary from about 1 mm to about 10 mm. The fifth tuning slab 363e can have thicknesses (x₆ₑ) associated therewith, and the thicknesses (x₆ₑ) can vary from about 0.01 mm to about 1 mm. The first resonant cavity 369a can have lengths (x₇ₑ) associated therewith, and the lengths (x₇ₑ) can vary from about 2 mm to about 20 mm. The first resonant cavity 369a can have widths (z₃ₑ) associated therewith, and the widths (z₃ₑ) can vary from about 2 mm to about 20 mm. For example, the fifth cavity x/z plane offset (z₄ₑ) can be established relative to one or more edges of the resonator plate 352, can be wavelength-dependent, and can vary from about (λ/4) to about (10λ).

The fifth plasma-tuning rod 370e can have a diameter (d_{1c}) associated therewith, and the diameter (d_{1c}) can vary from about 0.01 mm to about 1 mm. The fifth isolation assembly 374e and the fifth isolation assembly 366e can have fifth diameters (D₁ₑ) associated therewith, and the fifth diameters (D₁ₑ) can vary from about 1 mm to about 10 mm.

The second portion of the fifth plasma-tuning rod 370e, the fifth coupling region 365e, the fifth control assembly 362e, and the fifth tuning slab 363e can have fifth x/z plane offset (z₁ₑ) associated therewith. For example, the fifth x/z plane offset (z₁ₑ) can be established relative to one or more edges of the resonator plate 352, can be wavelength-dependent, and can vary from about (λ/4) to about (10λ). The fifth control assembly 362e can have a cylindrical configuration and diameters (d₂ₑ) that can vary from about 1 mm to about 5 mm. The fifth tuning slab 363e can be circular and can have diameters (D₂ₑ) associated therewith, and the diameters (D₂ₑ) can vary from about 1 mm to about 10 mm.

Still referring to FIG. 3B, the bottom view shows that a second portion of the sixth plasma-tuning rod 370f can extend into the sixth isolated tuning space 373f established in the sixth protection assembly 374f at a sixth x/z plane location (z_{1f}) in the process space 315, and a first portion of the sixth plasma-tuning rod 370f can also extend into the second EM energy tuning space 368b in the second resonant cavity 369b at the sixth x/z plane location (z_{1f}). A sixth isolation assembly 366f can be used to position and move 371f the sixth plasma-tuning rod 370f sixth plasma-tuning distances 372f within the sixth isolated tuning space 373f established in the sixth protection assembly 374f. For example, the sixth plasma-tuning distance 372f can vary from about 0.10 mm to about 1 mm, and the sixth plasma-tuning distance 372f can be wavelength-dependent and can vary from about (λ/40) to about (10λ).

FIG. 3B shows that a sixth coupling region 365f can be established at a first x/z plane coupling distance (z_{2f}) from one or more of the walls of the second resonant cavity 369b, and the first portion of the sixth plasma-tuning rod 370f can extend into the sixth coupling region 365f. The first portion of the sixth plasma-tuning rod can obtain sixth tunable EM energy from the sixth coupling region 365f, and the sixth EM energy can be transferred to the process space 315 at the sixth x/z plane location (z_{1f}) using the second portion of the sixth plasma-tuning rod 370f. The sixth coupling region 365f can include a tunable E-field region, a tunable H-field region, a maximum field region, a maximum voltage region, maximum energy region, or a maximum current region, or any combination thereof. For example, the first coupling distance (x₁ₑ) can vary from about 0.01 mm to about 10 mm, and the first coupling distance (x₁ₑ) can be wavelength-dependent and can vary from about (λ/4) to about (10λ).

A sixth tuning slab 363f can be coupled to a sixth control assembly 362f and can be used to move 364f the sixth tuning slab 363f a sixth cavity-tuning distance (x_{2f}) relative to the first portion of the sixth plasma-tuning rod 370f within the second EM energy tuning space 368b in the second resonant cavity 369b. The sixth control assembly 362f and the sixth tuning slab 363f can be used to optimize the EM energy coupled from the sixth coupling region 365f to the second portion of the sixth plasma-tuning rod 370f. For example, the sixth cavity-tuning distance (x_{2f}) can vary from about 0.01 mm to about 1 mm.

The sixth control assembly 362f can have lengths (x_{5f}) associated therewith, and the lengths (x_{5f}) can vary from about 1 mm to about 10 mm. The sixth tuning slab 363f can have thicknesses (x_{6f}) associated therewith, and the thicknesses (x_{6f}) can vary from about 0.01 mm to about 1 mm. The second resonant cavity 369b can have lengths (x_{7f}) associated therewith, and the lengths (x_{7f}) can vary from about 2 mm to about 20 mm. The second resonant cavity 369b can have widths (z_{3f}) associated therewith, and the widths (z_{3f}) can vary from about 2 mm to about 20 mm. For example, the sixth cavity x/z plane offset (z_{4f}) can be established relative to one or more edges of the resonator plate 352, can be wavelength-dependent, and can vary from about (λ/4) to about (10λ).

The sixth plasma-tuning rod 370f can have a diameter (d_{1f}) associated therewith, and the diameter (d_{1f}) can vary from about 0.01 mm to about 1 mm. The sixth isolation assembly 374f and the sixth isolation assembly 366f can have sixth diameters (D_{1f}) associated therewith, which can vary from about 1 mm to about 10 mm.

The second portion of the sixth plasma-tuning rod 370f, the sixth coupling region 365f, the sixth control assembly 362f, and the sixth tuning slab 363f can have sixth x/z plane offset (z_{1f}) associated therewith. For example, the sixth x/z plane offset (z_{1f}) can be established relative to one or more edges of the resonator plate 352, can be wavelength-dependent, and can vary from about (λ/4) to about (10λ). The sixth control assembly 362f can have a cylindrical configuration and diameters (d_{2f}) that can vary from about 1 mm to about 5 mm. The sixth tuning slab 363f can be circular and can have diameters (D_{2f}) associated therewith, and the diameters (D_{2f}) can vary from about 1 mm to about 10 mm.

FIG. 3C illustrates a side view of a third SWA processing system in accordance with embodiments of the invention. The side view can include a y/z plane view of the third SWA processing system 300.

The third SWA processing system 300 can comprise a third process chamber 310 configured to define a process space 315 in the y/z plane. The side view shows a y/z plane view of a third process chamber 310 that can be configured using a resonator plate 352 and a plurality of chamber walls (312, 312a, and 312b) coupled to each other and to the resonator plate 352. For example, the chamber walls 312 can have wall thicknesses (t) associated therewith, and the wall thicknesses (t) can vary from about 1 mm to about 5 mm. The resonator plate 352 have a cover plate thickness associated therewith, and the cover plate thickness can vary from about 1 mm to about 10 mm.

The side view of the third process chamber 310 includes a side view of the substrate holder 320 configured to support a substrate 305. The substrate 305 can be exposed to plasma and/or process chemistry in process space 315. The third SWA processing system 300 can comprise a second SWA plasma source 350 coupled to the third process chamber 310, and configured to form plasma in the process space 315.

FIG. 3C illustrates that one or more EM sources 390 can be coupled to the third SWA plasma source 350, and the EM energy generated by the EM source 390 can flow through a match network/phase shifter 391 to a tuner network/isolator 392 for absorbing EM energy reflected back to the EM source 390. The EM energy can be converted to a TEM (transverse electromagnetic) mode via the tuner network/isolator 392. A tuner may be employed for impedance matching, and improved power transfer. For example, the EM source 390, the match network/phase shifter 391, and the tuner network/isolator 392 can operate from about 500 MHz to about 5000 MHz.

The third SWA plasma source 350 can comprise a feed assembly 340 having an inner conductor 341, an outer conductor 342, an insulator 343, and a slot antenna 346 having a plurality of first slots 348 and a plurality of second slots 349 coupled between the inner conductor 341 and the outer conductor 342. The plurality of slots (348 and 349) permit the coupling of EM energy from a first region above the slot antenna 346 to a second region below the slot antenna 346.

The design of the slot antenna can be used to control the spatial uniformity of the plasma in process space 315. For example, the number, geometry, size, and distribution of the slots (348, and 349) in the y/z plane are all factors that can contribute to the spatial uniformity of the plasma formed in the process space 315.

Some exemplary third SWA plasma sources 350 can comprise a slow wave plate 344, and the design of the slow wave plate 344 can be used to control the spatial uniformity of the plasma in process space 315. For example, the geometry, size, and plate thickness can be factors in the y/z plane that can contribute to the spatial uniformity of the plasma formed in the process space 315. Alternatively, the slow wave plate 344 may be configured differently or may not be required.

Other exemplary third SWA plasma sources 350 can comprise a resonator plate 352, and the design of the resonator plate 352 can be used to control the spatial uniformity of the plasma in process space 315. For example, the geometry, size, and the resonator plate thickness can be factors in the y/z plane that can contribute to the spatial uniformity of the plasma formed in the process space 315. Alternatively, the resonator plate 352 may be configured differently or may not be required.

Other additional exemplary third SWA plasma sources 350 can comprise one or more fluid channels 356 that can be configured to flow a temperature control fluid for temperature control of the third SWA plasma source 350. The design of the fluid channels 356 in the y/z plane can be used to control the spatial uniformity of the plasma in process space 315. For example, the geometry, size, and flow rate of the fluid channels 356 can be factors that can contribute to the spatial uniformity of the plasma formed in the process space 315. Alternatively, the fluid channels 356 may be configured differently or may not be required. The EM energy can be coupled to the third SWA plasma source 350 via the feed assembly 340, and one or more mode changes can occur in the feed assembly 340.

FIG. 3C illustrates that the third SWA plasma source 350 can comprise a first set of protection assemblies (374a-374d) that can be configured as extensions of the resonator plate 352. For example, the resonator plate 352 and the first set of protection assemblies (374a-374d) can comprise a dielectric material, such as quartz. The design of the first set of protection assemblies (374a-374d) can be used to control the spatial uniformity of the plasma in process space 315. In addition, the geometry, size, and material of the first set of protection assemblies (374a-374d) can be factors that can contribute to the spatial uniformity of the plasma formed in the process space 315. Alternatively, the first set of protection assemblies (374a-374d) may be configured differently or may not be required.

A first set of positioning subsystems (375a-375d) can be coupled to at least one mounting structure 376 and can be coupled to the first set of plasma-tuning rods (370a-370d). The first set of positioning subsystems (375a-375d) can be used to create the first set of movements (371a-371d) in the first set of plasma-tuning rods (370a-370d) within the first set of tuning spaces (372a-172d) established in the first set of tuning assemblies (373a-373d). The first set of tuning spaces (372a-372d) and the first set of tuning spaces (372a-372d) can be configured to extend through the outer conductor 342, the slow wave plate 344, the slot antenna 346, and the resonator plate 352, and can extend into the first set of protection assemblies (374a-374d). Alternatively, the first set of tuning spaces (372a-372d), and the first set of tuning assemblies (373a-373d) can be configured differently.

The first set of tuning spaces (372a-372d) and the first set of tuning assemblies (373a-373d) can be cylindrically shaped, and can have diameters (d_{1a-d}) larger than the diameters (l_{1a-d}) of the first set of plasma-tuning rods (370a-370d), thereby allowing the first set of plasma-tuning rods (370a-370d) to move freely therein. Alternatively, the number, shape, length, and/or position of first set of plasma-tuning rods (370a-370d) may be different.

The first set of plasma-tuning rods (370a-370d), the first set of tuning spaces (372a-372d), the first set of tuning assemblies (373a-373d), and the first set of protection assemblies (374a-374d) can be aligned at first y/z plane locations (z_{1a-d}) in the process space 315, and the first set of tunable EM energies can be provided by the first set of plasma-tuning rods (370a-370d) at the first y/z plane locations (z_{1a-d}) in the process space 315. Alternatively, the first set of plasma-tuning rods (370a-370d), first set of tuning spaces (372a-372d), the first set of tuning assemblies (373a-373d), and the first set of protection assemblies (374a-374d) may be configured differently.

The first set of protection assemblies (374a-374d) can extend first insertion lengths (y_{1a-d}) into the process space 315, and the set of first insertion lengths (y_{1a-d}) can be established relative to the plasma-facing surface 361 of the resonator plate 352. The set of first insertion lengths (y_{1a-d}) can be wavelength-dependent and may vary from about (λ/20) to about (10λ). Alternatively, the set of first insertion lengths (y_{1a-d}) may vary from about 1 mm to about 5 mm.

The first set of tuning spaces (372a-372d) and the first set of tuning assemblies (373a-373d) can extend second insertion lengths (y_{2a-d}) into the process space 315, and the set of second insertion lengths (y_{2a-d}) can be established relative to the plasma-facing surface 361 of the resonator plate 352. The set of second insertion lengths (y_{2a-d}) can be wavelength-dependent and can vary from about (λ/20) to about (10λ). Alternatively, the set of second insertion lengths (y_{2a-d}) may vary from about 1 mm to about 5 mm. For example, the set of first insertion lengths (y_{1a-d}) and the set of second insertion lengths (y_{2a-d}) can be factors that can contribute to the spatial uniformity of the plasma formed in the process space 315. Alternatively, the first set of protection assemblies (374a-374d) may be configured differently or may not be required.

The first set of plasma-tuning rods (370a-370d) can extend third insertion lengths (y_{3a-d}) into the process space 315, and the set of third insertion lengths (y_{3a-d}) can be established relative to the plasma-facing surface 361 of the resonator plate 352. The set of third insertion lengths (y_{3a-d}) can be dependent upon the first set of movements (371a-371d), can be wavelength-dependent, and can vary from about (λ/20) to about (10λ). Alternatively, the set of third insertion lengths (y_{3a-d}) may vary from about 1 mm to about 5 mm. The controller 395 can control the set of third insertion lengths (y_{3a-d}) using the first set positioning subsystems (375a-375d), and the controller 395 can use process recipes to establish, control, and optimize the set of third insertion lengths (y_{3a-d}) in real-time to control the plasma uniformity within the process space 315. For example, the controller can control the first set of movements (371a-371d) of the first set of plasma-tuning rods (370a-370d) in real-time to control the first tunable EM energy and the plasma uniformity within the process space 315.

In some embodiments, the third SWA processing system 300 can be configured to form plasma in the process space 315 as the substrate holder 320 and the substrate are moved through the process space 315. In other embodiments, the third SWA processing system 300 can be configured to form plasma in the process space 315 as the substrate holder 320 and the substrate are positioned within the process space 315.

The controller 395 can be coupled 396 to the third EM source 390, the match network/phase shifter 391, and the tuner network/isolator 392, and the controller 395 can use process recipes to establish, control, and optimize the third EM source 390, the match network/phase shifter 391, and the tuner network/isolator 392 to control the plasma uniformity within the process space 315. For example, the EM source 390 can operate at frequencies from about 500 MHz to about 5000 MHz. In addition, the controller 395 can be coupled 396 to the process sensors 307, and the controller 395 can use process recipes to establish, control, and optimize the data from the process sensors 307 to control the plasma uniformity within the process space 315.

Some of the third SWA processing systems 300 can include a pressure control system 325 and exhaust port 326 coupled to the third process chamber 310, and configured to evacuate the third process chamber 310, as well as control the pressure within the third process chamber 310. Alternatively, the pressure control system 325 and/or the exhaust port 326 may not be required.

As shown in FIG. 3C, the third SWA processing system 300 can comprise a first gas supply system 380 coupled to one or more first flow elements 381 that can be coupled to the third process chamber 310. The first flow elements 381 can be configured to introduce a first process gas to process space 315, and can include flow control and/or flow measuring devices. In addition, the third SWA processing system 300 can comprise a second gas supply system 382 coupled to one or more second flow elements 383 that can be coupled to the third process chamber 310. The second flow elements 383 can be configured to introduce a second process gas to process space 315, and can include flow control and/or flow measuring devices. Alternatively, the second gas supply system 382 and/or the second flow elements 383 may not be required.

During dry plasma etching, the process gas may comprise an etchant, a passivant, or an inert gas, or a combination of two or more thereof. For example, when plasma etching a dielectric film such as silicon oxide (SiOₓ) or silicon nitride (SiₓN_{y}), the plasma etch gas composition generally includes a fluorocarbon-based chemistry (CₓF_{y}) such as at least one of C₄F₈, C₅F₈, C₃F₆, C₄F₆, CF₄, etc., and/or may include a fluorohydrocarbon-based chemistry (CₓH_{y}F_{z}) such as at least one of CHF₃, CH₂F₂, etc., and can have at least one of an inert gas, oxygen, CO or CO₂. Additionally, for example, when etching polycrystalline silicon (poliesilicon), the plasma etch gas composition generally includes a halogen-containing gas such as HBr, Cl₂, NF₃, or SF₆ or a combination of two or more thereof, and may include fluorohydrocarbon-based chemistry (CₓH_{y}F_{z}) such as at least one of CHF₃, CH₂F₂, etc., and at least one of an inert gas, oxygen, CO or CO₂, or two or more thereof. During plasma-enhanced deposition, the process gas may comprise a film forming precursor, a reduction gas, or an inert gas, or a combination of two or more thereof.

With reference to FIG. 3A and FIG. 3C, various views of a substrate holder 320, and a lower electrode 321 are shown. When present, the lower electrode 321 can be used to couple Radio Frequency (RF) power to plasma in process space 315. For example, lower electrode 321 can be electrically biased at an RF voltage via the transmission of RF power from RF generator 330 through impedance match network 332 and RF sensor 335 to lower electrode 321. The RF bias can serve to heat electrons to form and/or maintain the plasma. A typical frequency for the RF bias can range from 1 MHz to 100 MHz and is preferably 13.56 MHz. Alternatively, RF power may be applied to the lower electrode 321 at multiple frequencies. Furthermore, impedance match network 332 can serve to maximize the transfer of RF power to the plasma in third process chamber 310 by minimizing the reflected power. Various match network topologies and automatic control methods can be utilized. The RF sensor 335 can measure the power levels and/or frequencies associated with the fundamental signals, harmonic signals, and/or intermodulation signals. In addition, the controller 395 can be coupled 396 to the RF generator 330, the impedance match network 332, and the RF sensor 335, and the controller 395 can use process recipes to establish, control, and optimize the data to and from the RF generator 330, the impedance match network 332, and the RF sensor 335 to control the plasma uniformity within the process space 315.

In some embodiments, the third EM source 390 can be coupled to a first resonant cavity 369a and a second resonant cavity 369b. Alternatively, one or more separate EM sources (not shown) may be coupled to the first resonant cavity 369a and/or to the second resonant cavity 369b. One or more EM sources 390 can be coupled to the match network/phase shifter 391 that can be coupled to a tuner network/isolator 392. The tuner network/isolator 392 can be coupled to a first coupling (matching) network 393a and to a second coupling (matching) network 393b. Alternatively, a plurality of matching networks (not shown) or a plurality of coupling networks (not shown) may be used. The first coupling (matching) network 393a can be removably coupled to the first resonant cavity 369a and can be used to provide first EM energy to the first resonant cavity 369a. The second coupling (matching) network 393b can be removably coupled to the second resonant cavity 369b and can be used to provide second EM energy to the second resonant cavity 369b. Alternatively, other coupling configurations may be used.

The side view of the third SWA processing system 300 shows a side (dotted line) view of a fifth plasma-tuning rod 370e that is shown surrounded by a side (dotted line) view of the fifth protection assembly 374e, and the side view of the fifth protection assembly 374e is shown surrounded by a side view of the fifth tuning slab 363e.

The fifth plasma-tuning rod 370e can have diameters (d_{1c}) associated therewith, and the diameters (d₁ₑ) can vary from about 0.01 mm to about 1 mm. The fifth protection assembly 374e can have diameters (D₁ₑ) associated therewith, and the diameters (D₁ₑ) can vary from about 1 mm to about 10 mm.

The fifth control assembly 362e can have a cylindrical configuration and a diameter (d₂ₑ) that can vary from about 1 mm to about 5 mm. The fifth tuning slab 363e can have diameters (D₂ₑ) associated therewith, which can vary from about 1 mm to about 10 mm.

The side view of the third SWA processing system 300 shows a side (dotted line) view of a sixth plasma-tuning rod 370f that is shown surrounded by a side (dotted line) view of the sixth protection assembly 374f, and the side view of the sixth protection assembly 374f is shown surrounded by a side view of the sixth tuning slab 363f.

The sixth plasma-tuning rod 370f can have diameters (d_{1f}) associated therewith, and the diameters (d_{1f}) can vary from about 0.01 mm to about 1 mm. The sixth protection assembly 374f can have diameters (D_{1f}) associated therewith, and the diameters (D_{1f}) can vary from about 1 mm to about 10 mm.

The sixth control assembly 362f can have a cylindrical configuration and a diameter (d₂ₑ) that can vary from about 1 mm to about 5 mm. The fifth tuning slab 363e can have diameters (D₂ₑ) associated therewith, which can vary from about 1 mm to about 10 mm.

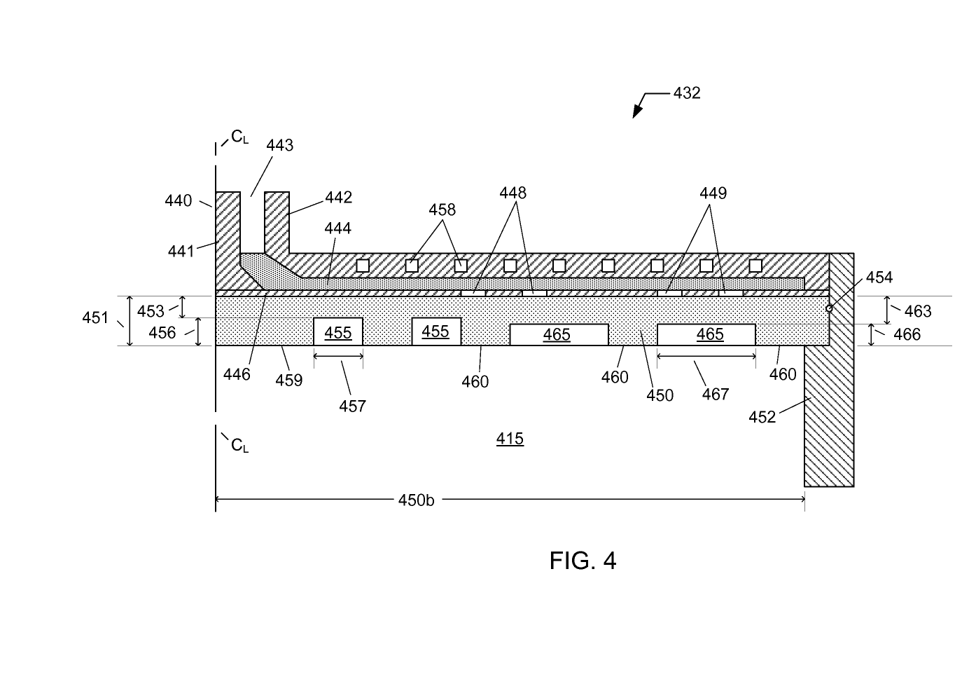

FIG. 4 illustrates an exemplary EM wave launcher 432 according to embodiments of the invention. In some SWA processing systems, the EM wave launcher 432 can be fabricated with a plurality of first recesses 455 configured in a first pattern formed in a plasma-facing surface 460 and a plurality of second recesses 465 configured in a second pattern formed in the plasma-facing surface 460.

Each of the first recesses 455 can comprise a unique indentation or dimple formed within the plasma-facing surface 460. For example, one or more of the first recesses 455 may comprise a cylindrical geometry, a spherical geometry, an aspherical geometry, a rectangular geometry, or any arbitrary shape. The first recesses 455 may include recesses characterized by a first size (e.g., latitudinal dimension (or width), and/or longitudinal dimension (or depth)).

Each of the second recesses 465 may also comprise a unique indentation or dimple formed within the plasma-facing surface 460. For example, one or more of the second recesses 465 may comprise a cylindrical geometry, a spherical geometry, an aspherical geometry, a rectangular geometry, or any arbitrary shape. The second recesses 465 may include recesses characterized by a second size (e.g., latitudinal dimension (or width), and/or longitudinal dimension (or depth)). The first size may or may not be the same as the second size. For instance, the second size may be smaller than the first size.

The number, geometry, size, and distribution of the first and second recesses (455 and 465) can contribute to the spatial uniformity of the plasma formed in process space (115, FIGS. 1A-C), or process space (215, FIGS. 2A-C), or plasma space (315, FIGS. 3A-C). Thus, the design of the first and second recesses (455 and 465) may be used to control the spatial uniformity of the plasma in process space (115, FIGS. 1A-C), or process space (215, FIGS. 2A-C), or plasma space (315, FIGS. 3A-C).

As shown in FIG. 4, the EM wave launcher 432 can comprise a feed assembly 440 having an inner conductor 441, an outer conductor 442, an insulator 443, and a slot antenna 446 having a plurality of first slots 448 and a plurality of second slots 449 coupled between the inner conductor 441 and the outer conductor 442. The plurality of slots (448 and 449) permit the coupling of EM energy from a first region above the slot antenna 446 to a second region below the slot antenna 446. The design of the slot antenna 346 can be used to control the spatial uniformity of the plasma in process space 415. For example, the number, geometry, size, and distribution of the slots (448, and 449) are all factors that can contribute to the spatial uniformity of the plasma formed in the process space 415.

Some exemplary EM wave launchers 432 can comprise a slow wave plate 444, and the design of the slow wave plate 444 can be used to control the spatial uniformity of the plasma in process space 415. For example, the geometry, size, and plate material can be factors that can contribute to the spatial uniformity of the plasma formed in the process space 415. Alternatively, the slow wave plate 444 may be configured differently or may not be required.

Other exemplary EM wave launchers 432 can comprise one or more fluid channels 458 that can be configured to flow a temperature control fluid for temperature control of the EM wave launchers 432. The design of the fluid channels 458 can be used to control the spatial uniformity of the plasma in process space 415. For example, the geometry, size, and flow rate of the fluid channels 458 can be factors that can contribute to the spatial uniformity of the plasma formed in the process space 415. Alternatively, the fluid channels 458 may be configured differently or may not be required.

As shown in FIG. 4, the EM wave launcher 432 can also comprise a resonator plate 450 that may include a dielectric plate having a plate thickness 451 and a partial plate length 450b. In addition, the plasma-facing surface 460 on resonator plate 450 can comprise a planar surface within which the plurality of first recesses 455 and the plurality of second recesses 465 are formed. Alternatively, the resonator plate 450 may comprise an arbitrary geometry that may include concave, and/or convex surfaces.

The propagation of EM energy in the resonator plate 450 may be characterized by an effective wavelength (λ) for a given frequency of EM energy and dielectric constant for the resonator plate 450. The plate thickness may be an integer number of quarter wavelengths (nλ/4, where n is an integer greater than zero) or an integer number of half wavelengths (mλ/2, where m is an integer greater than zero). For instance, the plate thickness 451 may be about half the effective wavelength (λ/2) or greater than half the effective wavelength (>λ/2). Alternatively, the plate thickness 451 may range from about 25 mm (millimeters) to about 45 mm.

As an example, the first recesses 455 can comprise one or more rectangular recesses, and each of the first recesses 455 can be characterized by a first depth 456 and a first length 457. As shown in FIG. 4, one or more of the second recesses 465 can be located near an inner region of the plasma-facing surface 460.

The first length 457 may be an integer number of quarter wavelengths (nλ/4, where n is an integer greater than zero) or an integer number of half wavelengths (mλ/2, where m is an integer greater than zero). Additionally, a first difference 453 between the plate thickness 451 and the first depth 456 may be an integer number of quarter wavelengths (nλ/4, where n is an integer greater than zero) or an integer number of half wavelengths (mλ/2, where m is an integer greater than zero). For instance, the first length 457 may be about half the effective wavelength (λ/2), and the first difference 453 between the plate thickness 451 and the first depth 456 may be about half the effective wavelength (λ/2) or about quarter the effective wavelength (λ/4). The plate thickness 451 may be about half the effective wavelength (λ/2) or greater than half the effective wavelength (>λ/2).

Alternatively, the first length 457 may range from about 25 mm to about 35 mm, and the first difference 453 between the plate thickness 451 and the first depth 456 may range from about 10 mm to about 35 mm. Alternatively yet, the first length 457 may range from about 30 mm to about 35 mm, and the first difference 453 may range from about 10 mm to about 20 mm.

In the first recesses 455, rounds and/or fillets (i.e., surface/corner radius) may be utilized to affect smooth surface transitions between adjacent surfaces. In a rectangular recess, a surface radius may be disposed at the corner between the rectangle's sidewall and the bottom of the recess. Additionally, in a rectangular recess, a surface radius may be disposed at the corner between the rectangle's sidewall and the plasma-facing surface 460. For example, the surface radius may range from about 1 mm to about 3 mm.

In addition, the second recesses 465 may comprise a second plurality of rectangular recesses, each of the second plurality of rectangular recesses being characterized by a second depth 466 and a second length 467. As shown in FIG. 4, one or more of the second recesses 465 can be located near an outer region of the plasma-facing surface 460.

The second length 467 may be an integer number of quarter wavelengths (nλ/4, where n is an integer greater than zero) or an integer number of half wavelengths (mλ/2, where m is an integer greater than zero). Additionally, a second difference 463 between the plate thickness 451 and the second depth 466 may be an integer number of quarter wavelengths (nλ/4, where n is an integer greater than zero) or an integer number of half wavelengths (mλ/2, where m is an integer greater than zero). For instance, the second length 467 may be about half the effective wavelength (λ/2) or quarter the effective wavelength (λ/4), and a second difference 463 between the plate thickness 451 and the second depth 466 may be about half the effective wavelength (λ/2) or about quarter the effective wavelength (λ/4). In addition, the resonator plate can be coupled to a chamber wall 452 using at least on sealing element 454.

Alternatively, the second diameter 467 may range from about 25 mm (millimeters) to about 35 mm, and the second difference 463 between the plate thickness and the second depth 466 may range from about 10 mm to about 35 mm. Alternatively yet, the second diameter 467 may range from about 30 mm to about 35 mm, and the second difference 463 may range from about 10 mm to about 20 mm.

In the second recesses 465, rounds and/or fillets (i.e., surface/corner radius) may be utilized to affect smooth surface transitions between adjacent surfaces. In a cylindrical recess, a surface radius may be disposed at the corner between the cylindrical sidewall and the bottom of the recess. Additionally, in a cylindrical recess, a surface radius may be disposed at the corner between the cylindrical sidewall and the plasma-facing surface 460. For example, the surface radius may range from about 1 mm to about 3 mm.

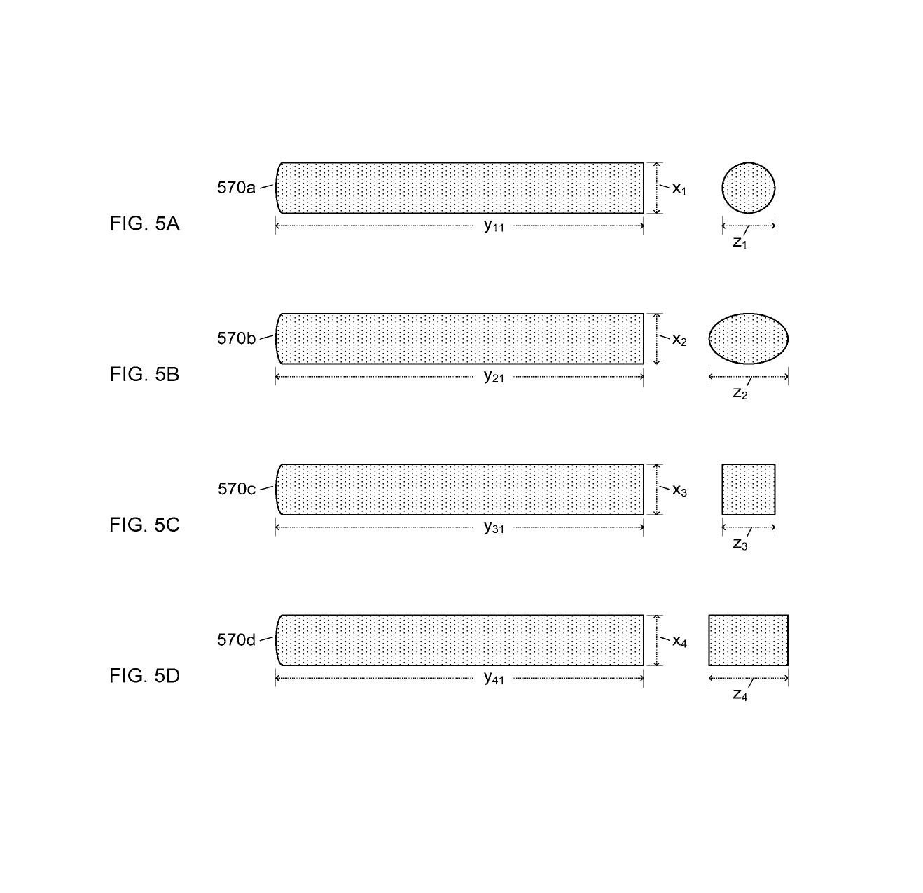

FIGS. 5A-5D show different views of exemplary plasma-tuning rods in accordance with embodiments of the invention. FIG. 5A shows a front view and a side view of a first exemplary plasma-tuning rod 570a. The first plasma-tuning rod 570a can have first lengths (y₁₁) associated therewith, and the first lengths (y₁₁) can vary from about 1 mm to about 400 mm. The first plasma-tuning rod 570a can have first heights (x₁) associated therewith, and the first heights (x₁) can vary from about 0.1 mm to about 10 mm. The first plasma-tuning rod 570a can have first widths (z₁) associated therewith, and the first widths (z₁) can vary from about 0.1 mm to about 10 mm.

FIG. 5B shows a front view and a side view of a second exemplary plasma-tuning rod 570b. The second plasma-tuning rod 570b can have second lengths (y₂₁) associated therewith, and the second lengths (y₂₁) can vary from about 1 mm to about 400 mm. The second plasma-tuning rod 570b can have second heights (x₂) associated therewith, and the second heights (x₂) can vary from about 0.1 mm to about 10 mm. The second plasma-tuning rod 570b can have second widths (z₂) associated therewith, and the second widths (z₂) can vary from about 0.1 mm to about 10 mm.

FIG. 5C shows a front view and a side view of a third exemplary plasma-tuning rod 570c. The third plasma-tuning rod 570c can have third lengths (y₃₁) associated therewith, and the third lengths (y₃₁) can vary from about 1 mm to about 400 mm. The third plasma-tuning portion 570c can have third heights (x₃) associated therewith, and the third heights (x₃) can vary from about 0.1 mm to about 10 mm. The third plasma-tuning rod 570c can have third widths (z₃) associated therewith, and the third widths (z₃) can vary from about 0.1 mm to about 10 mm.

FIG. 5D shows a front view and a side view of a fourth exemplary plasma-tuning rod 570d. The fourth plasma-tuning rod 570d can have fourth length (y₄₁) associated therewith, and the fourth lengths (y₄₁) can vary from about 1 mm to about 400 mm. The fourth plasma-tuning rod 570d can have fourth heights (x₄) associated therewith, and the fourth heights (x₄) can vary from about 0.1 mm to about 10 mm. The fourth plasma-tuning rod 570d can have fourth widths (z₄) associated therewith, and the fourth widths (z₄) can vary from about 0.1 mm to about 10 mm.

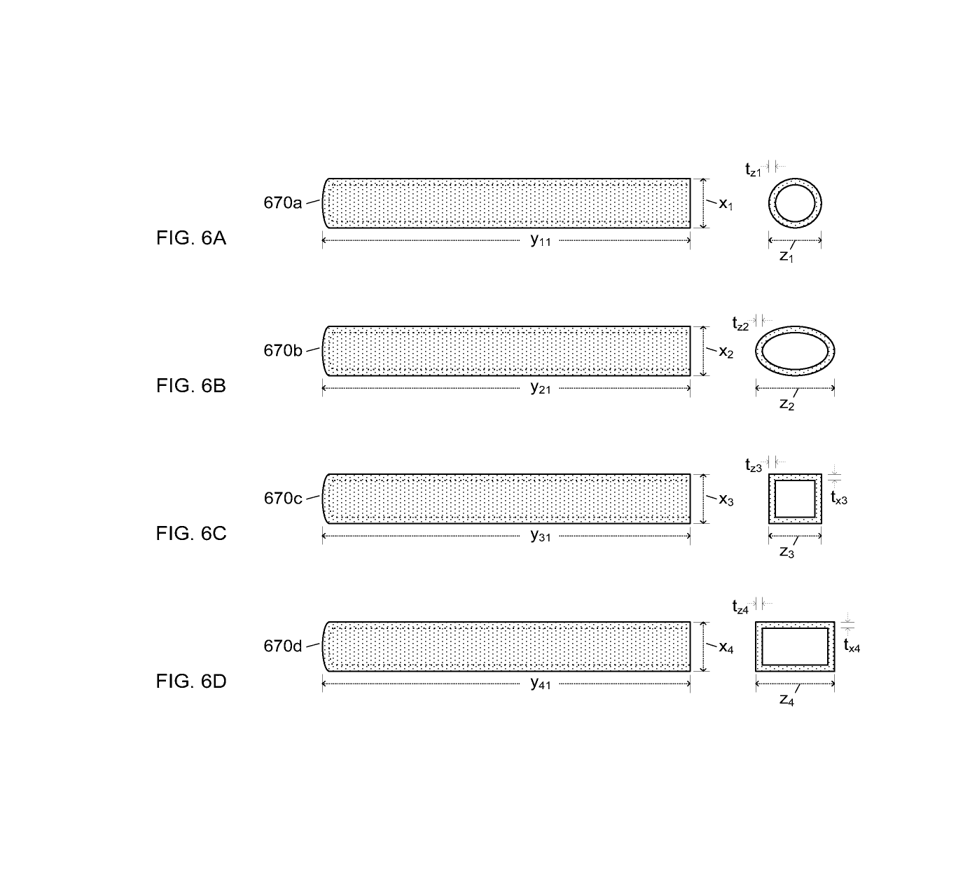

FIGS. 6A-6D show different views of exemplary plasma-tuning rods in accordance with embodiments of the invention. FIG. 6A shows a front view and a side view of a first exemplary plasma-tuning rod 670a. The first plasma-tuning rod 670a can have first lengths (y₁₁) associated therewith, and the first lengths (y₁₁) can vary from about 1 mm to about 400 mm. The first plasma-tuning rod 670a can have first heights (x₁) associated therewith, and the first heights (x₁) can vary from about 0.1 mm to about 10 mm. The first plasma-tuning rod 670a can have first widths (z₁) associated therewith, and the first widths (z₁) can vary from about 0.1 mm to about 10 mm. The first plasma-tuning rod 670a can have first thicknesses (t_{z1}) associated therewith, and the first thicknesses (t_{z1}) can vary from about 0.01 mm to about 1 mm.

FIG. 6B shows a front view and a side view of a second exemplary plasma-tuning rod 670b. The second plasma-tuning rod 670b can have first lengths (y₂₁) associated therewith, and the first lengths (y₂₁) can vary from about 1 mm to about 400 mm. The second plasma-tuning rod 670b can have second heights (x₂) associated therewith, and the second heights (x₂) can vary from about 0.1 mm to about 10 mm. The second plasma-tuning rod 670b can have second widths (z₂) associated therewith, and the second widths (z₂) can vary from about 0.1 mm to about 10 mm. The second plasma-tuning rod 670b can have second thicknesses (t_{z2}) associated therewith, and the second thicknesses (t_{z2}) can vary from about 0.01 mm to about 1 mm.

FIG. 6C shows a front view and a side view of a third exemplary plasma-tuning rod 670c. The third plasma-tuning rod 670c can have third lengths (y₃₁) associated therewith, and the third lengths (y₃₁) can vary from about 1 mm to about 400 mm. The third plasma-tuning rod 670c can have third heights (x₃) associated therewith, and the third heights (x₃) can vary from about 0.1 mm to about 10 mm. The third plasma-tuning rod 670c can have third widths (z₃) associated therewith, and the third widths (z₃) can vary from about 0.1 mm to about 10 mm. The third plasma-tuning rod 670c can have third thicknesses (t_{z3} and tₓ₃) associated therewith, which can vary from about 0.01 mm to about 1 mm.

FIG. 6D shows a front view and a side view of a fourth exemplary plasma-tuning rod 670d. The fourth plasma-tuning rod 670d can have fourth lengths (y₄₁) associated therewith, and the fourth lengths (y₄₁) can vary from about 1 mm to about 400 mm. The fourth plasma-tuning rod 670d can have fourth heights (x₄) associated therewith, and the fourth heights (x₄) can vary from about 0.1 mm to about 10 mm. The fourth plasma-tuning rod 670d can have fourth widths (z₄) associated therewith, and the fourth widths (z₄) can vary from about 0.1 mm to about 10 mm. The fourth plasma-tuning rod 670d can have fourth thicknesses (t_{z4} and tₓ₄) associated therewith, and the fourth thicknesses (t_{z4} and tₓ₄) can vary from about 0.01 mm to about 1 mm.

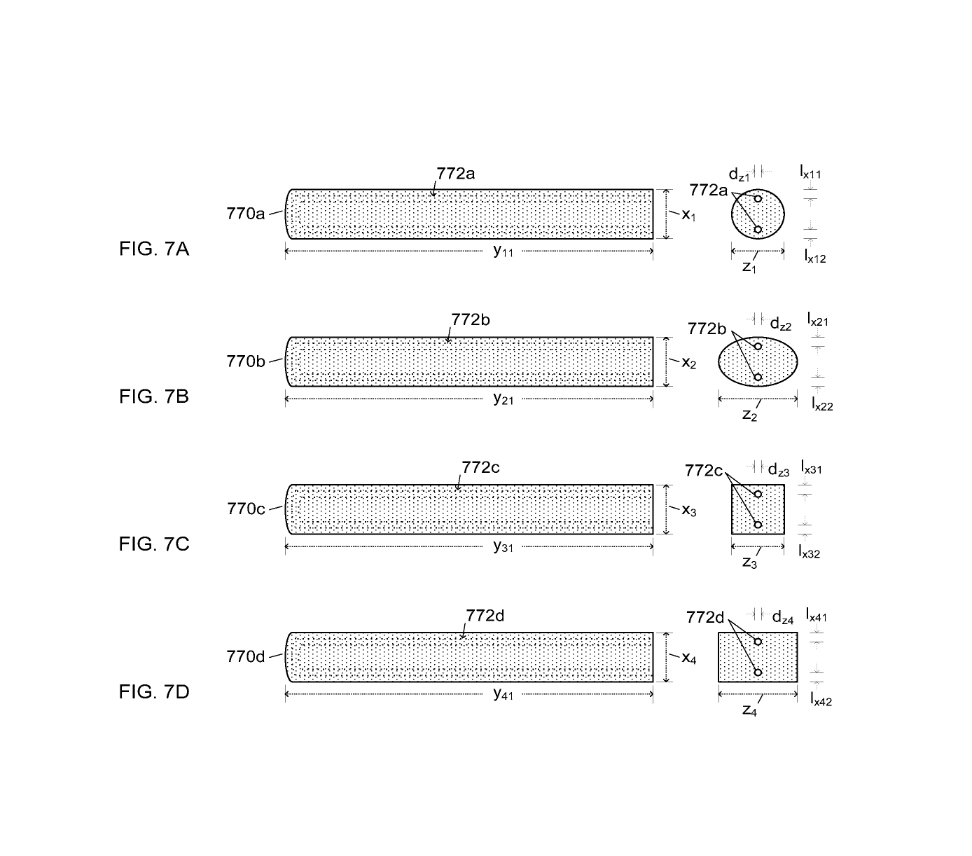

FIGS. 7A-7D show different views of exemplary plasma-tuning rods in accordance with embodiments of the invention. FIG. 7A shows a front view and a side view of a first exemplary plasma-tuning rod 770a. The first plasma-tuning rod 770a can have first lengths (y₁₁) associated therewith, and the first lengths (y₁₁) can vary from about 1 mm to about 400 mm. The first plasma-tuning rod 770a can have first heights (x₁) associated therewith, and the first heights (x₁) can vary from about 0.1 mm to about 10 mm. The first plasma-tuning rod 770a can have first width (z₁) associated therewith, and the first widths (z₁) can vary from about 0.1 mm to about 10 mm. A first temperature control loop 772a can be configured within the first exemplary plasma-tuning rod 770a. For example, a temperature control fluid and/or gas can flow through the first temperature control loop 772a to control the temperature of the first exemplary plasma-tuning rod 770a. The first temperature control loop 772a can have first diameters (d_{z1}) associated therewith, and the first diameters (d_{z1}) can vary from about 0.001 mm to about 0.1 mm. In addition, the first temperature control loop 772a have first offsets (lₓ₁₁ and lₓ₁₂) associated therewith, and the first offsets (lₓ₁₁ and lₓ₁₂) can vary from about 0.01 mm to about 0.1 mm.

FIG. 7B shows a front view and a side view of a second exemplary plasma-tuning rod 770b. The second plasma-tuning rod 770b can have first lengths (y₂₁) associated therewith, and the first lengths (y₂₁) can vary from about 1 mm to about 400 mm. The second plasma-tuning rod 770b can have second heights (x₂) associated therewith, and the second heights (x₂) can vary from about 0.1 mm to about 10 mm. The second plasma-tuning rod 770b can have second widths (z₂) associated therewith, and the second widths (z₂) can vary from about 0.1 mm to about 10 mm. A second temperature control loop 772b can be configured within the second exemplary plasma-tuning rod 770b. For example, a temperature control fluid and/or gas can flow through the second temperature control loop 772b to control the temperature of the second exemplary plasma-tuning rod 770b. The second temperature control loop 772b can have second diameters (d_{z2}) associated therewith, and the second diameters (d_{z2}) can vary from about 0.001 mm to about 0.1 mm. In addition, the second temperature control loop 772b can have second offsets (lₓ₂₁ and lₓ₂₂) associated therewith, which can vary from about 0.01 mm to about 0.1 mm.

FIG. 7C shows a front view and a side view of a third exemplary plasma-tuning rod 770c. The third plasma-tuning rod 770c can have third lengths (y₃₁) associated therewith, and the third lengths (y₃₁) can vary from about 1 mm to about 400 mm. The third plasma-tuning rod 770c can have third heights (x₃) associated therewith, and the third heights (x₃) can vary from about 0.1 mm to about 10 mm. The third plasma-tuning rod 770c can have third widths (z₃) associated therewith, and the third widths (z₃) can vary from about 0.1 mm to about 10 mm. A third temperature control loop 772c can be configured within the third exemplary plasma-tuning rod 770c. For example, a temperature control fluid and/or gas can flow through the third temperature control loop 772c to control the temperature of the third exemplary plasma-tuning rod 770c. The third temperature control loop 772c can have third diameters (d_{z3}) associated therewith, and the third diameters (d_{z3}) can vary from about 0.001 mm to about 0.1 mm. In addition, the third temperature control loop 772c have third offsets (lₓ₃₁ and lₓ₃₂) associated therewith, and the third offsets (lₓ₃₁ and lₓ₃₂) can vary from about 0.01 mm to about 0.1 mm.

FIG. 7D shows a front view and a side view of a fourth exemplary plasma-tuning rod 770d. The fourth plasma-tuning rod 770d can have fourth lengths (y₄₁) associated therewith, and the fourth lengths (y₄₁) can vary from about 1 mm to about 400 mm. The fourth plasma-tuning rod 770d can have fourth heights (x₄) associated therewith, and the fourth heights (x₄) can vary from about 0.1 mm to about 10 mm. The fourth plasma-tuning rod 770d can have fourth widths (z₄) associated therewith, and the fourth widths (z₄) can vary from about 0.1 mm to about 10 mm. A fourth temperature control loop 772d can be configured within the fourth exemplary plasma-tuning rod 770d. For example, a temperature control fluid and/or gas can flow through the fourth temperature control loop 772d to control the temperature of the fourth exemplary plasma-tuning rod 770d. The fourth temperature control loop 772d can have fourth diameters (d_{z4}) associated therewith, and the fourth diameters (d_{z4}) can vary from about 0.001 mm to about 0.1 mm. In addition, the fourth temperature control loop 772d have fourth offsets (lₓ₄₁ and lₓ₄₂) associated therewith, and the fourth offsets (lₓ₄₁ and lₓ₄₂) can vary from about 0.01 mm to about 0.1 mm.

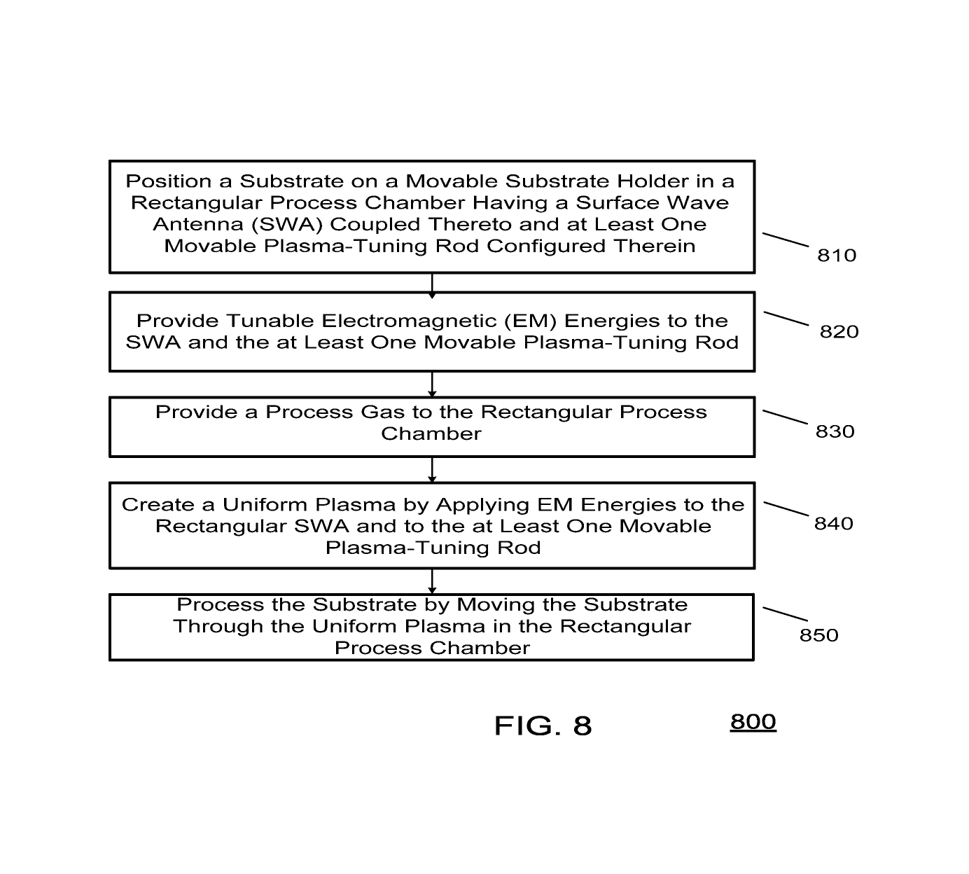

FIG. 8 illustrates a flow diagram for an exemplary operating procedure for a SWA processing system in accordance with embodiments of the invention. A multi-step procedure 800 is shown in FIG. 8. Alternatively, other steps may be included.

In 810, a substrate (105, 205, or 305) can be positioned on a substrate holder (120, 220, or 320) in a rectangular process chamber (110, 210, or 310), and one or more SWA plasma sources (150, 250, or 350) can be coupled to the process chamber (110, 210, or 310). In some examples, the first SWA plasma source (150, FIGS. 1A-C) can have a first set of plasma-tuning rods (170a-170d, FIGS. 1A-C) that can be coupled the process chamber (110, FIGS. 1A-C) using the cover plate (160, FIGS. 1A-C). In other examples, the second SWA plasma source (250, FIGS. 2A-C) can be coupled the second process chamber (210, FIGS. 2A-C) using the second cover plate (260, FIGS. 2A-C), and the second process chamber (210, FIGS. 2A-C) can have a second set of plasma-tuning rods (270a-270b, FIGS. 2A-C) therein. In still other examples, the third SWA plasma source (350, FIGS. 3A-C) with the third set of plasma-tuning rods (370a-370d, FIGS. 3A-C) therein can be coupled the third process chamber (310, FIGS. 3A-C) using the third resonator plate (352, FIGS. 3A-C), and the third process chamber (310, FIGS. 3A-C) can have an additional set of plasma-tuning rods (370e-370f, FIGS. 3A-C) therein. Alternatively, other configurations may be used.

In 820, tunable EM energies can be provided to one or more rectangular process chambers (110, 210, or 310) using one or more SWA plasma sources (150, 250, or 350).

For example, the controller can control the first movements 171a and the third insertion lengths (y₃ₐ) associated with the first plasma-tuning rod 170a in real-time to control the first plasma-tuning EM energy provided to the process space 115 by the first plasma-tuning rod 170a.

In some embodiments, one or more EM sources 190 can be coupled to the first SWA plasma source (150, FIGS. 1A-C) that can comprise a rectangular slot antenna (146, FIGS. 1A-C) coupled to a resonator plate (152, FIGS. 1A-C). The first set of plasma-tuning rods (170a-170d, FIGS. 1A-C) can extend through and can be electrically-coupled to the slot antenna (146, FIGS. 1A-C) and/or the resonator plate (152, FIGS. 1A-C). The first set of plasma-tuning rods (170a-170d, FIGS. 1A-C) can have movements (171a-171d, FIGS. 1A-C) and third insertion lengths (y_{3a-d}, FIGS. 1A-C) associated therewith. For example, the controller can control the first movements (171a-171d, FIGS. 1A-C) and the third insertion lengths (y_{3a-d}, FIGS. 1A-C) in real-time to control the first, second, third, and/or fourth plasma-tuning EM energies provided to the process space 115 by the lower portions of the first set of plasma-tuning rods (170a-170d, FIGS. 1A-C).

In other embodiments, one or more EM sources 290 can be coupled to the second SWA plasma source (250, FIGS. 2A-C) that can comprise a rectangular slot antenna (246, FIGS. 2A-C) coupled to a resonator plate (252, FIGS. 2A-C) and that can be coupled to the second process chamber (210, FIGS. 2A-C). A plurality of resonant cavities (269a-269b, FIGS. 2A-C) can include a plurality of coupling regions (265a-265b, FIGS. 2A-C) in a plurality of EM energy tuning spaces (268a-268b, FIGS. 2A-C) and can be coupled to the second process chamber (210, FIGS. 2A-C). The second set of plasma-tuning rods (270a-270b, FIGS. 2A-C) can extend into the coupling regions (265a-265b, FIGS. 2A-C) in the EM energy tuning spaces (268a-268b, FIGS. 2A-C), can obtain plasma-tuning energies therefrom, and can provide some of the plasma-tuning energies to the process space (215, FIGS. 2A-C) in the second process chamber (210, FIGS. 2A-C). The second set of plasma-tuning rods (270a-270b, FIGS. 2A-C) can have movements (271a-271b, FIGS. 2A-C) and plasma-tuning distances (272a-272b, FIGS. 2A-C) associated therewith. For example, the controller can control the movements (271a-271b, FIGS. 2A-C) and plasma-tuning distances (272a-272b, FIGS. 2A-C) in real-time to control the first and/or second plasma-tuning EM energies provided to the second process chamber (210, FIGS. 2A-C) by the second portions of the second set of plasma-tuning rods (270a-270b, FIGS. 2A-C).

In still other embodiments, one or more EM sources 390 can be coupled to the third SWA plasma source (350, FIGS. 3A-C) that can comprise a rectangular slot antenna (346, FIGS. 3A-C) coupled to a resonator plate (352, FIGS. 3A-C) and that can be coupled to the third process chamber (310, FIGS. 3A-C). The third set of plasma-tuning rods (370a-370d, FIGS. 3A-C) can extend through and can be electrically-coupled to the rectangular slot antenna (346, FIGS. 3A-C) and/or the resonator plate (352, FIGS. 3A-C). The third set of plasma-tuning rods (370a-370d, FIGS. 3A-C) can have movements (371a-371d, FIGS. 3A-C) and third insertion lengths (y_{3a-d}, FIGS. 3A-C) associated therewith. For example, the controller can control the movements (371a-371d, FIGS. 3A-C) and the third insertion lengths (y_{3a-d}, FIGS. 3A-C) in real-time to control the first, second, third, and/or fourth plasma-tuning EM energies provided to the third process space 315 by the lower portions of the third set of plasma-tuning rods (370a-370d, FIGS. 3A-C).

In addition, a plurality of resonant cavities (369a-369b, FIGS. 3A-C) can include a plurality of EM energy tuning spaces (368a-368b, FIGS. 3A-C) in a plurality of coupling regions (365e-365f, FIGS. 3A-C) and can be coupled to the third process chamber (310, FIGS. 3A-C). An additional set of plasma-tuning rods (370e-370f, FIGS. 3A-C) can extend into the coupling regions (365e-365f, FIGS. 3A-C) in the EM energy tuning spaces (368a-368b, FIGS. 3A-C), can obtain plasma-tuning energies therefrom, and can provide some additional plasma-tuning energies to the process space (315, FIGS. 3A-C) in the third process chamber (310, FIGS. 3A-C). The additional set of plasma-tuning rods (370e-370f, FIGS. 3A-C) can have additional movements (371e-371f, FIGS. 3A-C) and additional plasma-tuning distances (372e-372f, FIGS. 3A-C) associated therewith. For example, the controller can control the additional movements (371e-371f, FIGS. 3A-C) and additional plasma-tuning distances (372e-372f, FIGS. 3A-C) in real-time to control the additional plasma-tuning EM energies provided to the third process chamber (310, FIGS. 3A-C) by the second portions of the additional set of plasma-tuning rods (370e-370f, FIGS. 3A-C).

In 830, process gas can be supplied into the process chamber (110, 210, or 310) around the plasma-tuning rods. During dry plasma etching, the process gas may comprise an etchant, a passivant, or an inert gas, or a combination of two or more thereof. For example, when plasma etching a dielectric film such as silicon oxide (SiOₓ) or silicon nitride (SiₓN_{y}), the plasma etch gas composition generally includes a fluorocarbon-based chemistry (CₓF_{y}) such as at least one of C₄F₈, C₅F₈, C₃F₆, C₄F₆, CF₄, etc., and/or may include a fluorohydrocarbon-based chemistry (CₓH_{y}F_{z}) such as at least one of CHF₃, CH₂F₂, etc., and can have at least one of an inert gas, oxygen, CO or CO₂. Additionally, for example, when etching polycrystalline silicon (polisilicon), the plasma etch gas composition generally includes a halogen-containing gas such as HBr, Cl₂, NF₃, or SF₆ or a combination of two or more thereof, and may include fluorohydrocarbon-based chemistry (CₓH_{y}F_{z}) such as at least one of CHF₃, CH₂F₂, etc., and at least one of an inert gas, oxygen, CO or CO₂, or two or more thereof. During plasma-enhanced deposition, the process gas may comprise a film forming precursor, a reduction gas, or an inert gas, or a combination of two or more thereof.

In 840, uniform plasma can be created by applying tunable EM signals to the rectangular SWA and to the plasma-tuning rods.

In some embodiments, one or more EM sources 190 can be coupled to the first SWA plasma source (150, FIGS. 1A-C) that can comprise a rectangular slot antenna (146, FIGS. 1A-C) coupled to a resonator plate (152, FIGS. 1A-C). The first set of plasma-tuning rods (170a-170d, FIGS. 1A-C) can extend through and can be electrically-coupled to the rectangular slot antenna (146, FIGS. 1A-C) and/or the resonator plate (152, FIGS. 1A-C). The first set of plasma-tuning rods (170a-170d, FIGS. 1A-C) can have movements (171a-171d, FIGS. 1A-C) and third insertion lengths (y_{3a-d}, FIGS. 1A-C) associated therewith. For example, the controller (195, FIGS. 1A-C) can control the first movements (171a-171d, FIGS. 1A-C) and the third insertion lengths (y_{3a-d}, FIGS. 1A-C) in real-time to control the first, second, third, and/or fourth plasma-tuning EM energies provided to the process space (115, FIGS. 1A-C) by the lower portions of the first set of plasma-tuning rods (170a-170d, FIGS. 1A-C), thereby creating a uniform plasma in the process space (115, FIGS. 1A-C).

In other embodiments, one or more EM sources 290 can be coupled to the second SWA plasma source (250, FIGS. 2A-C) that can comprise a rectangular slot antenna (246, FIGS. 2A-C) coupled to a resonator plate (252, FIGS. 2A-C) and that can be coupled to the second process chamber (210, FIGS. 2A-C). A plurality of resonant cavities (269a-269b, FIGS. 2A-C) can include a plurality of coupling regions (265a-265b, FIGS. 2A-C) and can be coupled to the second process chamber (210, FIGS. 2A-C). The second set of plasma-tuning rods (270a-270b, FIGS. 2A-C) can extend into the coupling regions (265a-265b, FIGS. 2A-C), can obtain plasma-tuning energies therefrom, and can provide some of the plasma-tuning energies to the process space (215, FIGS. 2A-C) in the second process chamber (210, FIGS. 2A-C). The second set of plasma-tuning rods (270a-270b, FIGS. 2A-C) can have movements (271a-271b, FIGS. 2A-C) and plasma-tuning distances (272a-272b, FIGS. 2A-C) associated therewith. For example, the controller can control the movements (271a-271b, FIGS. 2A-C) and plasma-tuning distances (272a-272b, FIG. 2) in real-time to control the first and/or second plasma-tuning EM energies provided to the second process chamber (210, FIGS. 2A-C) by the second portions of the second set of plasma-tuning rods (270a-270b, FIGS. 2A-C), thereby creating a uniform plasma in the second process chamber (210, FIGS. 2A-C).

In still other embodiments, one or more EM sources 390 can be coupled to the third SWA plasma source (350, FIGS. 3A-C) that can comprise a rectangular slot antenna (346, FIGS. 3A-C) coupled to a resonator plate (352, FIGS. 3A-C) and that can be coupled to the third process chamber (310, FIGS. 3A-C). The third set of plasma-tuning rods (370a-370d, FIGS. 3A-C) can extend through and can be electrically-coupled to the slot antenna (346, FIGS. 3A-C) and/or the resonator plate (352, FIGS. 3A-C). The third set of plasma-tuning rods (370a-370d, FIGS. 3A-C) can have movements (371a-371d, FIGS. 3A-C) and third insertion lengths (y_{3a-d}, FIGS. 3A-C) associated therewith. For example, the controller can control the movements (371a-371d, FIGS. 3A-C) and the third insertion lengths (y_{3a-d}, FIGS. 3A-C) in real-time to control the first, second, third, and/or fourth plasma-tuning EM energies provided to the third process space 315 by the lower portions of the third set of plasma-tuning rods (370a-370d, FIGS. 3A-C), thereby creating a uniform plasma in the third process chamber (310, FIGS. 3A-C).

In addition, a plurality of resonant cavities (369a-369b, FIGS. 3A-C) can include a plurality of coupling regions (365e-365f, FIGS. 3A-C) and can be coupled to the third process chamber (310, FIGS. 3A-C). An additional set of plasma-tuning rods (370e-370f, FIGS. 3A-C) can extend into the coupling regions (365e-365f, FIGS. 3A-C), can obtain additional plasma-tuning energies therefrom, and can provide some additional plasma-tuning energies to the process space (315, FIGS. 3A-C) in the third process chamber (310, FIGS. 3A-C). The additional set of plasma-tuning rods (370e-370f, FIGS. 3A-C) can have additional movements (371e-371f, FIGS. 3A-C) and additional plasma-tuning distances (372e-372f, FIGS. 3A-C) associated therewith. For example, the controller can control the additional movements (371e-371f, FIGS. 3A-C) and additional plasma-tuning distances (372e-372f, FIGS. 3A-C) in real-time to control the additional plasma-tuning EM energies provided to the third process chamber (310, FIGS. 3A-C) by the second portions of the additional set of plasma-tuning rods (370e-370f, FIGS. 3A-C)), thereby creating a uniform plasma in the third process chamber (310, FIGS. 3A-C).

In addition, one or more controllers (195, FIGS. 1A-C) can be coupled to the EM source (190, FIGS. 1A-C), the match network/phase shifter (191, FIGS. 1A-C), and the tuner network/isolator (192, FIGS. 1A-C), and at least one controller (195, FIGS. 1A-C) can use process recipes to establish, control, and optimize the EM source (190, FIGS. 1A-C), the match network/phase shifter (191, FIGS. 1A-C), and the tuner network/isolator (192, FIGS. 1A-C) to control the microwave plasma uniformity within the process space (115, FIGS. 1A-C).

In additional embodiments, the controller (295, FIGS. 2A-C) can be coupled (296, FIGS. 2A-C) to the RF generator (230, FIGS. 2A-C), the impedance match network (232, FIGS. 2A-C), and the RF sensor (235, FIGS. 2A-C), and the controller (295, FIGS. 2A-C) can use process recipes to establish, control, and optimize the data to and from the RF generator (230, FIGS. 2A-C), the impedance match network (232, FIGS. 2A-C), and the RF sensor (235, FIGS. 2A-C) to control and optimize the plasma uniformity within the process space (215, FIGS. 2A-C).

In other additional embodiments, the controller (395, FIGS. 3A-C) can be coupled (396, FIGS. 3A-C) to the RF generator (330, FIGS. 3A-C), the impedance match network (332, FIGS. 3A-C), and the RF sensor (335, FIGS. 3A-C), and the controller (395, FIGS. 3A-C) can use process recipes to establish, control, and optimize the data to and from the RF generator (330, FIGS. 3A-C), the impedance match network (332, FIGS. 3A-C), and the RF sensor (335, FIGS. 3A-C) to control the plasma uniformity within the process space (315, FIGS. 3A-C).

In 850, the substrate can be processed by exposing the substrate to and/or moving the substrate through the uniform plasma in the rectangular process chamber (110, FIGS. 1A-C), (210, FIGS. 2A-C), or (310, FIGS. 3A-C).

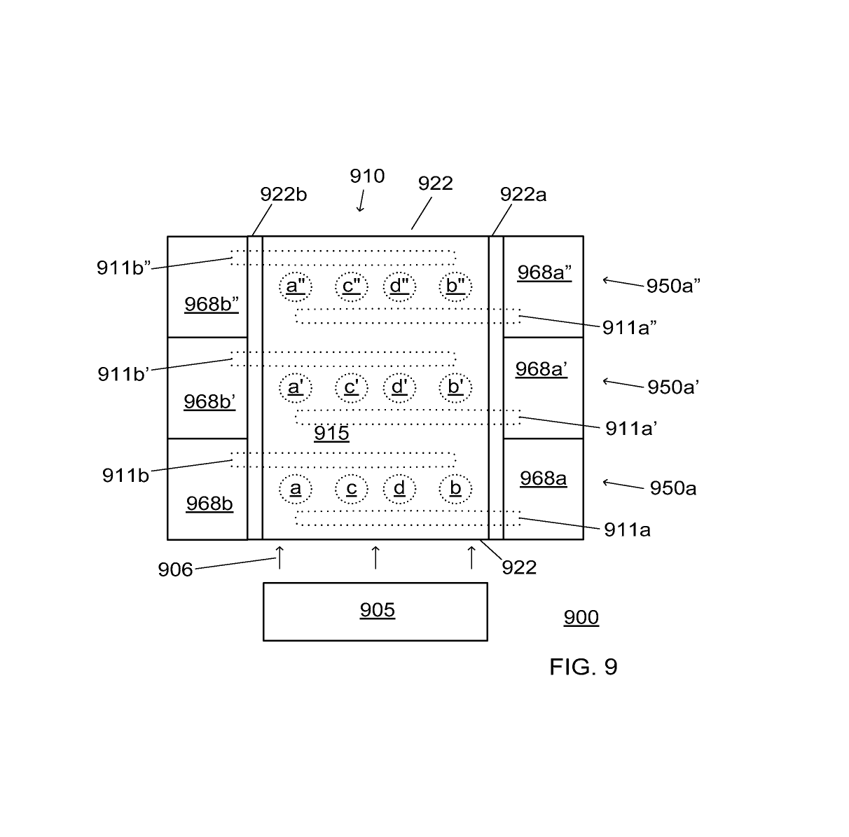

FIG. 9 illustrates another SWA processing system 900 according to embodiments of the invention. The SWA processing system 900 may comprise a dry plasma etching system or a plasma enhanced deposition system.

The SWA processing system 900 can comprise a non-circular process chamber 910 having a plurality of chamber walls (922, 922a, and 922b) configured to define a process space 915. The SWA processing system 900 comprises a substrate holder (not shown) configured to support and/or move 906 the substrate 905 through the process space 915. The substrate 905 can be exposed to uniform plasma or uniform process chemistry in process space 915.

The SWA processing system 900 can comprise a first SWA assembly 950a having a plurality of vertical plasma-tuning rods (a, b, c, and d), a first resonant cavity 968a having at least one first horizontal plasma-tuning rod 911a coupled therein, and a second resonant cavity 968b having at least one second horizontal plasma-tuning rod 911b coupled therein. The SWA processing system 900 can comprise a second SWA assembly 950a′ having a plurality of additional vertical plasma-tuning rods (a′, b′, c′, and d′), an additional first resonant cavity 968a′ having at least one additional first horizontal plasma-tuning rod 911a′ coupled therein, and an additional second resonant cavity 968b′ having at least one additional second horizontal plasma-tuning rod 911b′ coupled therein. The SWA processing system 900 can also comprise a third SWA assembly 950a″ having a plurality of other additional vertical plasma-tuning rods (a″, b″, c″, and d″), another additional first resonant cavity 968a″ having at least one other additional first horizontal plasma-tuning rod 911a″ coupled therein, and another additional second resonant cavity 968b″ having at least one other additional second horizontal plasma-tuning rod 911b″ coupled therein. For example, the SWA assemblies (950a, 950a′, and 950a″) can be configured as shown in SWA processing systems (100, 200, or 300) described herein.

Although only certain embodiments of this invention have been described in detail above, those skilled in the art will readily appreciate that many modifications are possible in the embodiments without materially departing from the novel teachings and advantages of this invention. Accordingly, all such modifications are intended to be included within the scope of this invention.

Thus, the description is not intended to limit the invention and the configuration, operation, and behavior of the present invention has been described with the understanding that modifications and variations of the embodiments are possible, given the level of detail present herein. Accordingly, the preceding detailed description is not mean or intended to, in any way, limit the invention—rather the scope of the invention is defined by the appended claims.

What is claimed is:

1. A Surface Wave Antenna (SWA) processing system for processing a substrate comprising:
a process chamber comprising a process space having a movable substrate holder therein;
a SWA plasma source coupled to the process chamber, wherein the SWA plasma source comprises a non-circular slot antenna and a non-circular resonator plate coupled to the non-circular slot antenna;
a plurality of protection assemblies coupled to the non-circular resonator plate, each protection assembly extending a first distance into the process space;
a plurality of positioning subsystems coupled to at least one mounting structure;
a plurality of tuning assemblies extending through the non-circular slot antenna, extending through the non-circular resonator plate, and extending into the plurality of protection assemblies, wherein each tuning assembly has a tuning space therein that extends a second distance into the process space;
a plurality of plasma-tuning rods coupled to the positioning subsystems, wherein at least one plasma-tuning rod is coupled to a separate positioning subsystem and is configured within a separate tuning space, the separate positioning subsystem being configured to move each plasma-tuning rod within the separate tuning space, the plasma-tuning rods extending third distances into the process space; and
a controller coupled to the tuning assemblies and configured to control the third distances, thereby controlling plasma uniformity in the process space.

2. The SWA processing system of claim 1, further comprising:
a tuner network/isolator coupled to the non-circular slot antenna;
a match network/phase shifter coupled to the tuner network/isolator; and
an electromagnetic (EM) source coupled to the match network/phase shifter, wherein the EM source is configured to operate in a frequency range from 500 MHz to 5000 MHz.

3. The SWA processing system of claim 1, wherein the protection assemblies are configured as extensions of the non-circular resonator plate and extend through holes in a cover plate coupled to the non-circular resonator plate.

4. The SWA processing system of claim 1, further comprising:
a first gas supply system coupled to one or more first flow elements coupled to the process chamber, wherein the first flow elements are configured to introduce a first process gas to the process space.

5. The SWA processing system of claim 4, wherein the first process gas comprises one or more of C₄F₈, C₅F₈, C₃F₆, C₄F₆, CF₄, CHF₃, CH₂F₂, an inert gas, oxygen, CO, and CO₂.

6. The SWA processing system of claim 4, wherein the first process gas comprises one or more of HBr, Cl₂, NF₃, SF₆, CHF₃, CH₂F₂, an inert gas, oxygen, CO, and CO₂.

7. The SWA processing system of claim 2, further comprising:
a first resonant cavity coupled to a first chamber wall, wherein a first coupling region is established at a first coupling distance from at least one wall of the first resonant cavity, and a first portion of a first additional plasma-tuning rod extends into the first coupling region at a first additional location;
a first isolation assembly coupled through the first chamber wall and coupled to the first additional plasma-tuning rod;
a first protection assembly coupled to the first isolation assembly, wherein a second portion of the first additional plasma-tuning rod extends into a first additional isolated tuning space established in the first protection assembly at the first additional location in the process space;
a second resonant cavity coupled to a second chamber wall, wherein a second coupling region is established at a second coupling distance from at least one wall of the second resonant cavity, and the first portion of a second additional plasma-tuning rod extends into the second coupling region at a second additional location;
a second isolation assembly coupled through the second chamber wall and coupled to the second additional plasma-tuning rod;
a second protection assembly coupled to the second isolation assembly, wherein a second portion of the second additional plasma-tuning rod extends into a second additional isolated tuning space established in the second protection assembly at the second additional location in the process space;
a first matching network coupled to the tuner network/isolator and the first resonant cavity, the first matching network being configured to provide first additional EM energy to the first resonant cavity; and
a second matching network coupled to the tuner network/isolator and the second resonant cavity, the second matching network being configured to provide second additional EM energy to the second resonant cavity.

8. The SWA processing system of claim 7, further comprising:
a first control assembly coupled through at least one first cavity wall;
a first tuning slab coupled to the first control assembly and configured to move the first tuning slab a first cavity-tuning distance relative to the first portion of the first additional plasma-tuning rod within the first resonant cavity, thereby optimizing a first additional plasma-tuning energy coupled from the first coupling region to the second portion of the first additional plasma-tuning rod;
a second control assembly coupled through at least one second cavity wall; and
a second tuning slab coupled to the second control assembly and configured to move the second tuning slab a second cavity-tuning distance relative to the first portion of the second additional plasma-tuning rod within the second resonant cavity, thereby optimizing a second additional plasma-tuning energy coupled from the second coupling region to the second portion of the second additional plasma-tuning rod.

9. A Surface Wave Antenna (SWA) processing system for processing a substrate comprising:
a process chamber comprising a process space having a movable substrate holder therein;
a SWA plasma source coupled to the process chamber, wherein the SWA plasma source comprises a non-circular slot antenna and a non-circular resonator plate coupled to the non-circular slot antenna;
a first resonant cavity coupled to a first chamber wall, wherein a first coupling region is established at a first coupling distance from at least one wall of the first resonant cavity, and a first portion of a first plasma-tuning rod extends into the first coupling region at a first location;
a first isolation assembly coupled through the first chamber wall and coupled to the first plasma-tuning rod;
a first protection assembly coupled to the first isolation assembly, wherein a second portion of the first plasma-tuning rod extends into a first isolated tuning space established in the first protection assembly at the first location in the process space;
a second resonant cavity coupled to a second chamber wall, wherein a second coupling region is established at a second coupling distance from at least one wall of the second resonant cavity, and the first portion of a second plasma-tuning rod extends into the second coupling region at a second location;
a second isolation assembly coupled through the second chamber wall and coupled to the second plasma-tuning rod;
a second protection assembly coupled to the second isolation assembly, wherein a second portion of the second plasma-tuning rod extends into a second additional isolated tuning space established in the second protection assembly at the second location in the process space;
an electromagnetic (EM) source;
a first matching network coupled to the EM source and the first resonant cavity, the first matching network being configured to provide first EM energy to the first resonant cavity;
a second matching network coupled to the EM source and the second resonant cavity, the second matching network being configured to provide second EM energy to the second resonant cavity, wherein the EM source is configured to operate in a frequency range from 500 MHz to 5000 MHz; and.
a controller coupled to the first resonant cavity, the second resonant cavity, and the EM source, the controller being configured to control plasma uniformity in the process space.

10. The SWA processing system of claim 9, further comprising:
a first control assembly coupled through at least one first cavity wall, wherein the controller is coupled to the first control assembly;
a first tuning slab coupled to the first control assembly that is configured to move the first tuning slab a first cavity-tuning distance relative to the first portion of the first plasma-tuning rod within the first resonant cavity, thereby optimizing a first plasma-tuning energy coupled from the first coupling region to the second portion of the first plasma-tuning rod;
a second control assembly coupled through at least one second cavity wall, wherein the controller is coupled to the second control assembly; and
a second tuning slab coupled to the second control assembly that is configured to move the second tuning slab a second cavity-tuning distance relative to the first portion of the second plasma-tuning rod within the second resonant cavity, thereby optimizing a second plasma-tuning energy coupled from the second coupling region to the second portion of the second plasma-tuning rod.

11. A method of processing a substrate using a Surface Wave Antenna (SWA) processing system comprising:
positioning a substrate on a movable substrate holder within a process space in a rectangular process chamber;
positioning a plurality of movable plasma-tuning rods through a rectangular SWA into the rectangular process chamber coupled to the rectangular SWA;
providing process gas to the rectangular process chamber;
creating a uniform plasma by applying electromagnetic (EM) energies to the rectangular SWA and to the movable plasma-tuning rods using an EM source; and
processing the substrate by moving the substrate through the uniform plasma.

12. The method of claim 11, wherein positioning the movable plasma-tuning rods further comprises:
establishing the SWA using a rectangular slot antenna and a rectangular resonator plate coupled to the rectangular slot antenna, wherein a plurality of protection assemblies are configured as extensions of the rectangular resonator plate, each protection assembly extending a first distance into the process space;
establishing at least one mounting structure having a plurality of positioning subsystems coupled thereto;
positioning a plurality of tuning assemblies, each tuning assembly extending through the rectangular slot antenna, extending through the rectangular resonator plate and extending into the protection assemblies, wherein the tuning assembly has a tuning space therein that extends a second distance into the process space; and
positioning the movable plasma-tuning rods using the positioning subsystems, wherein each movable plasma-tuning rod is coupled to a separate positioning subsystem and is configured within a separate tuning space, the separate positioning subsystem being configured to move the movable plasma-tuning rod within the separate tuning space, the movable plasma-tuning rods extending third distances into the process space.

13. The method of claim 11, wherein providing the process gas further comprises:
coupling a gas supply system to the rectangular process chamber using one or more flow elements coupled to the rectangular process chamber, wherein the flow elements are configured to introduce the process gas to the process space.

14. The method of claim 13, wherein the process gas comprises one or more of C₄F₈, C₅F₈, C₃F₆, C₄F₆, CF₄, CHF₃, CH₂F₂, an inert gas, oxygen, CO, and CO₂.

15. The method of claim 13, wherein the process gas comprises one or more of HBr, Cl₂, NF₃, SF₆, CHF₃, CH₂F₂, an inert gas, oxygen, CO, and CO₂.

16. The method of claim 11, further comprising:
coupling a first resonant cavity to a first chamber wall, wherein a first coupling region is established at a first coupling distance from at least one wall of the first resonant cavity, and a first portion of a first plasma-tuning rod extends into the first coupling region at a first location;
configuring a first isolation assembly, wherein the first isolation assembly is coupled through the first chamber wall and is coupled to the first plasma-tuning rod;
coupling a first protection assembly to the first isolation assembly, wherein a second portion of the first plasma-tuning rod extends into a first isolated tuning space established in the first protection assembly at the first location in the process space;
coupling a second resonant cavity to a second chamber wall, wherein a second coupling region is established at a second coupling distance from at least one wall of the second resonant cavity, and the first portion of a second plasma-tuning rod extends into the second coupling region at a second location;
configuring a second isolation assembly, wherein the second isolation assembly is coupled through the second chamber wall and is coupled to the second plasma-tuning rod;
coupling a second protection assembly to the second isolation assembly, wherein a second portion of the second plasma-tuning rod extends into a second additional isolated tuning space established in the second protection assembly at the second location in the process space;
coupling a first matching network to the EM source and the first resonant cavity, the first matching network being configured to provide first EM energy to the first resonant cavity;
coupling a second matching network to the EM source and the second resonant cavity, the second matching network being configured to provide second EM energy to the second resonant cavity, wherein the EM source is configured to operate in a frequency range from 500 MHz to 5000 MHz; and
controlling the first EM energy, the second EM energy, and the EM source to maintain plasma uniformity in the process space in real-time.

17. The method of claim 16, further comprising:
coupling a first control assembly through at least one first cavity wall, wherein a controller is coupled to the first control assembly;
coupling a first tuning slab to the first control assembly that is configured to move the first tuning slab a first cavity-tuning distance relative to the first portion of the first plasma-tuning rod within the first resonant cavity, thereby optimizing a first plasma-tuning energy coupled from the first coupling region to the second portion of the first plasma-tuning rod;
coupling a second control assembly through at least one second cavity wall, wherein the controller is coupled to the second control assembly; and
coupling a second tuning slab to the second control assembly that is configured to move the second tuning slab a second cavity-tuning distance relative to the first portion of the second plasma-tuning rod within the second resonant cavity, thereby optimizing a second plasma-tuning energy coupled from the second coupling region to the second portion of the second plasma-tuning rod.

18. A method of processing a substrate using a Surface Wave Antenna (SWA) processing system comprising:
positioning a substrate on a movable substrate holder within a process space in a rectangular process chamber, wherein a rectangular SWA is coupled to the rectangular process chamber;
positioning a plurality of movable plasma-tuning rods through a plurality of chamber walls and into the process space in the rectangular process chamber;
providing process gas to the rectangular process chamber;
creating a uniform plasma by applying electromagnetic (EM) energies to the rectangular SWA and to the movable plasma-tuning rods using an EM source; and
processing the substrate by moving the substrate through the uniform plasma.

19. The method of claim 18, further comprising:
coupling a first resonant cavity to a first chamber wall, wherein a first coupling region is established at a first coupling distance from at least one wall of the first resonant cavity, and a first portion of a first plasma-tuning rod extends into the first coupling region at a first location;
configuring a first isolation assembly, wherein the first isolation assembly is coupled through the first chamber wall and is coupled to the first plasma-tuning rod;
coupling a first protection assembly to the first isolation assembly, wherein a second portion of the first plasma-tuning rod extends into a first isolated tuning space established in the first protection assembly at the first location in the process space;
coupling a second resonant cavity to a second chamber wall, wherein a second coupling region is established at a second coupling distance from at least one wall of the second resonant cavity, and the first portion of a second plasma-tuning rod extends into the second coupling region at a second location;
configuring a second isolation assembly, wherein the second isolation assembly is coupled through the second chamber wall and is coupled to the second plasma-tuning rod;
coupling a second protection assembly to the second isolation assembly, wherein a second portion of the second plasma-tuning rod extends into a second additional isolated tuning space established in the second protection assembly at the second location in the process space;
coupling a first matching network to the EM source and the first resonant cavity, the first matching network being configured to provide first EM energy to the first resonant cavity;
coupling a second matching network to the EM source and the second resonant cavity, the second matching network being configured to provide second EM energy to the second resonant cavity, wherein the EM source is configured to operate in a frequency range from 500 MHz to 5000 MHz; and
controlling the first EM energy, the second EM energy, and the EM source to maintain plasma uniformity in the process space in real-time.

20. The method of claim 19, further comprising:
coupling a first control assembly through at least one first cavity wall, wherein a controller is coupled to the first control assembly;
coupling a first tuning slab to the first control assembly that is configured to move the first tuning slab a first cavity-tuning distance relative to the first portion of the first plasma-tuning rod within the first resonant cavity, thereby optimizing a first plasma-tuning energy coupled from the first coupling region to the second portion of the first plasma-tuning rod;
coupling a second control assembly through at least one second cavity wall, wherein the controller is coupled to the second control assembly; and
coupling a second tuning slab to the second control assembly that is configured to move the second tuning slab a second cavity-tuning distance relative to the first portion of the second plasma-tuning rod within the second resonant cavity, thereby optimizing a second plasma-tuning energy coupled from the second coupling region to the second portion of the second plasma-tuning rod.
